(19) United States
(12) Patent Application Publication
(10) Pub. No.: US 2015/0248054 A1
(43) Pub. Date: Sep. 3, 2015

(54) PATTERN FORMING METHOD, ACTINIC RAY-SENSITIVE OR RADIATION-SENSITIVE RESIN COMPOSITION, RESIST FILM, METHOD OF MANUFACTURING ELECTRONIC DEVICE, AND ELECTRONIC DEVICE

(71) Applicant: FUJIFILM CORPORATION, Tokyo (JP)

(72) Inventor: TOMOKI MATSUDA, SHIZUOKA (JP)

(21) Appl. No.: 14/698,863

(22) Filed: Apr. 29, 2015

Related U.S. Application Data
(63) Continuation of application No. PCT/JP2013/079167, filed on Oct. 28, 2013.

(30) Foreign Application Priority Data
Oct. 31, 2012 (JP) 2012-240415

(51) Int. Cl. G03F 7/038

(52) U.S. Cl. CPC G03F 7/038

(57) ABSTRACT

There is provided a pattern forming method including:
(a) forming a film from an actinic ray-sensitive or radiation-sensitive resin composition containing:
   (A) a resin containing a repeating unit (a0) having a —SO₂— group and a repeating unit (a1) having a group which decomposes by the action of an acid to generate a polar group, in which a molar average of C log P values of the respective monomers corresponding to repeating units except for the repeating unit (a0) is 2.0 or more; and
   (B) a compound capable of generating an acid upon irradiation with an actinic ray or radiation;
(b) exposing the film; and
(c) developing the film exposed by using a developer including an organic solvent to form a negative pattern.

### CROSS REFERENCE TO RELATED APPLICATION(S)

This is a continuation of International Application No. PCT/JP2013/079167 filed on Oct. 28, 2013, and claims priority from Japanese Patent Application No. 2012-240415 filed on Oct. 31, 2012, the entire disclosures of which are incorporated herein by reference.

### BACKGROUND

1. Technical Field

The present invention relates to a pattern forming method, an actinic ray-sensitive or radiation-sensitive resin composition and a resist film used therefor, a method of manufacturing an electronic device, and an electronic device. More specifically, the present invention relates to a pattern forming method suitable for a manufacturing process of a semiconductor such as an IC, a manufacture of a liquid crystal and a circuit board such as a thermal head, and furthermore, other lithography processes of photofabrication, an actinic ray-sensitive or radiation-sensitive resin composition and a resist film used for the pattern forming method, a method of manufacturing an electronic device, and an electronic device. In particular, the present invention relates to a pattern forming method suitable for exposure in an ArF exposure apparatus and an ArF liquid immersion projection exposure apparatus which uses far-ultraviolet rays having a wavelength of 300 nm or less as a light source, or an EUV exposure apparatus, an actinic ray-sensitive or radiation-sensitive resin composition and a resist film used for the pattern forming method, a method of manufacturing an electronic device, and an electronic device.

2. Background Art

Since a resist for a KrF excimer laser (248 nm) was developed, a pattern forming method using chemical amplification has been used in order to complement desensitization caused by light absorption. For example, in a positive-type chemical amplification method, first, a photoacid-generating agent included in an exposed portion decomposes upon irradiation with light and generates an acid. Thereafter, in a process such as post exposure bake (PEB), and the like, an alkali-insoluble group included in the photosensitive composition is changed to an alkali-soluble group by the catalytic action of the generated acid. Subsequently, development is performed using, for example, an alkaline solution. Accordingly, the exposed portion is removed, so that a desired pattern is obtained.

In the above method, various alkaline developers have been suggested as an alkaline developer. For example, as the alkaline developer, a water-based alkaline developer with 2.38% by mass of TMAH (tetramethylammonium hydroxide aqueous solution) is universally used.

Further, in order to make semiconductor elements finer, a wavelength of an exposure light source has been shortened and a projection lens with a high numerical aperture (high NA) has been used, and thus an exposure machine using an ArF excimer laser having a wavelength of 193 nm as a light source has been currently developed. As a technique for further improving resolution, a method (that is, a liquid immersion method) of filling a liquid having a high refractive index (hereinafter, also referred to as a “liquid for liquid immersion”) between a projection lens and a sample has been proposed. In addition, EUV lithography that performs exposure with ultraviolet rays having a shorter wavelength (13.5 nm) has also been proposed.

However, in such a positive-type image forming method, an isolated line or dot pattern may be satisfactorily formed, but in a case of forming an isolated space or a fine pattern, the shape of the pattern is easy to deteriorate.

Therefore, for a request for a finer pattern, a technique of resolving not only a positive-type pattern, which is a currently mainstream, but also a negative-type pattern of a resist film obtained by a chemical amplification resist composition, using an organic developer, has recently been known. As for such a technique, for example, a method of forming a negative-type pattern by an organic developer using a resin having a cyclic group containing a —SO₂— group, has been known (see, for example, Japanese Patent Laid-Open Publication No. 2011-191727 and Japanese Patent Laid-Open Publication No. 2012-73565).

However, since the resin having a cyclic group containing a —SO₂— group has a low solubility in an organic solvent (for example, n-butyl acetate) contained in the organic developer, the developability tends to deteriorate.

Further, a good pattern shape has been obtained by a conventional pattern forming method using a developer containing an organic solvent, for example, but, in recent years, for example, a need for miniaturization of hole patterns has increased dramatically, and even for the resist composition, further performance improvement has been demanded.

The present invention has been made in consideration of the background and an object thereof is to provide, in forming a fine pattern such as a hole pattern having a hole diameter of 75 nm or less (preferably a hole diameter of 45 nm or less) by an organic developer, a pattern forming method having excellent uniformity of a local pattern dimension (Local CDU, nm) and circularity, an actinic ray-sensitive or radiation-sensitive resin composition used therefor, a resist film, a method of manufacturing an electronic device using the same, and an electronic device.

### SUMMARY OF INVENTION

The present invention has the following configuration, and the object of the present invention is accordingly achieved.

[1] A pattern forming method including:

(a) forming a film from an actinic ray-sensitive or radiation-sensitive resin composition containing:
(A) a resin containing a repeating unit (a0) having a —SO₂— group and a repeating unit (a1) having a group which decomposes by the action of an acid to generate a polar group, in which a molar average of C log P values of the respective monomers corresponding to repeating units except for the repeating unit (a0) is 2.0 or more; and
(B) a compound capable of generating an acid upon irradiation with an actinic ray or radiation;

(b) exposing the film; and

(c) developing the film exposed by using a developer including an organic solvent to form a negative pattern.

[2] The pattern forming method according to [1],

wherein a content of the repeating unit (a1) having a group which decomposes by the action of an acid to generate a polar group is 50 mol % or more based on total repeating units of the resin (A).

[3] The pattern forming method according to [1] or [2],

wherein a content of the repeating unit (a0) having a —SO₂— group is 1 to 20 mol % based on total repeating units of the resin A.

[4] The pattern forming method according to any one of [1] to [3],

wherein the resin (A) further contains a repeating unit (a2) having a non-acid-decomposable aliphatic hydrocarbon group.

[5] The pattern forming method according to [4],

wherein the repeating unit (a2) is a repeating unit having no alcoholic hydroxyl group.

[6] The pattern forming method according to any one of [1] to [5],

wherein the compound (B) capable of generating an acid upon irradiation with an actinic ray or radiation is represented by Formula (b3′) or (b5′):

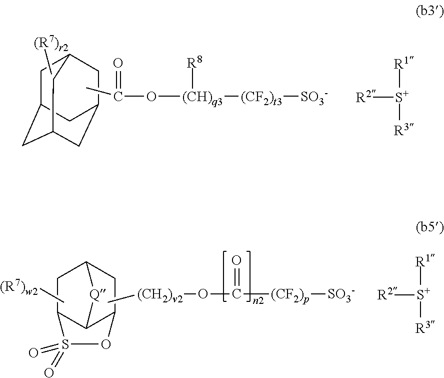

wherein, in Formulas (b3′) and (b5′), each of R^{1″} to R^{3″} independently represents an aryl group, and any two of R^{1″} to R^{3″} may be bonded to each other to form a ring together with a sulfur atom in the formulas (b3′) and (b5′),

in Formula (b3′), q3 is an integer of 1 to 12, r2 is an integer of 0 to 3, t3 is an integer of 1 to 3, R⁷ is a substituent, and R⁸ is a hydrogen atom or an alkyl group, and

in Formula (b5′), p is an integer of 1 to 3, R⁷ is a substituent, Q″ is an alkylene group which may contain an oxygen atom or a sulfur atom, an oxygen atom, or a sulfur atom, n2 is 0 or 1, v2 is an integer of 0 to 3, and w2 is an integer of 0 to 3.

[7] The pattern forming method according to any one of [1] to [6],

wherein the repeating unit (a0) is a repeating unit having a —SO₂—O— group.

[8] The pattern forming method according to [7],

wherein the repeating unit (a0) is a repeating unit having a cyclic group containing a —SO₂—O— group.

[9] An actinic ray-sensitive or radiation-sensitive resin composition provided in the pattern forming method according to any one of [1] to [8].

[10] A resist film formed from the actinic ray-sensitive or radiation-sensitive resin composition according to [9].

[11] A method of manufacturing an electronic device including the pattern forming method according to any one of [1] to [8].

[12] An electronic device manufactured by the method according to [11].

It is also preferred that the present invention has the following configuration.

[13] The pattern forming method described in any one of [1] to [8], wherein the repeating unit (a0) having a —SO₂— group is a (meth)acrylate repeating unit.

[14] The pattern forming method described in any one of [1] to [8], wherein the repeating unit (a0) having a —SO₂— group is a repeating unit represented by the following Formula (I):

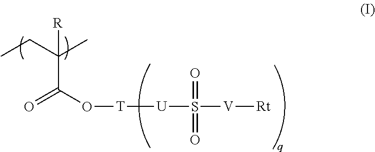

In Formula (I),

R represents a hydrogen atom or an alkyl group.

T represents a single bond or a (q+1)-valent linking group.

q represents an integer of 1 to 3.

Each of U and V independently represents an oxygen atom, an NH group, or a single bond.

Rt represents an alkyl group, a cycloalkyl group, or an aryl group.

The cycloalkyl group for Rt may have a nitrogen atom or an oxygen atom as a ring member.

[15] The pattern forming method described in any one of the above [1] to [8], [13], and [14], wherein the developer is a developer containing at least one organic solvent selected from the group consisting of a ketone-based solvent, an ester-based solvent, an alcohol-based solvent, an amide-based solvent, and an ether-based solvent.

[16] The pattern forming method described in any one of the above [1] to [8] and [13] to [15], further comprising (d) a process of cleaning with a rinse liquid containing an organic solvent.

[17] The pattern forming method described in any one of the above [1] to [8] and [13] to [16], wherein the exposure in the process (b) is a liquid immersion exposure.

[18] The pattern forming method described in any one of the above [1] to [8] and [13] to [17], wherein the exposure in process (b) is an ArF exposure.

[19] The actinic ray-sensitive or radiation-sensitive resin composition described in [9], which is a chemical amplification resist composition for organic solvent development.

[20] The actinic ray-sensitive or radiation-sensitive resin composition described in [9] or [19], for liquid immersion exposure.

According to the present invention, in forming a fine pattern such as a hole pattern having a hole diameter of 75 nm or less (preferably a hole diameter of 45 nm or less) by an organic developer, a pattern forming method having excellent uniformity of a local pattern dimension (Local CDU, nm) and circularity, an actinic ray-sensitive or radiation-sensitive resin composition used therefor, a resist film, a method of manufacturing an electronic device using the same, and an electronic device, may be provided.

### DETAILED DESCRIPTION OF EXEMPLARY EMBODIMENTS

Hereinafter, embodiments of the present invention will be described in detail.

In the notation of a group (atomic group) in the present specification, the representation which does not describe the substitution and unsubstitution includes a representation having a substituent along with a representation having no substituent. For example, “an alkyl group” includes not only an alkyl group having no substituent (an unsubstituted alkyl group) but also an alkyl group having a substituent (a substituted alkyl group).

The term “actinic ray” or “radiation” in the present specification refers to, for example, a bright line spectrum of a mercury lamp and the like, far-ultraviolet rays represented by an excimer laser, extreme ultraviolet rays (EUV light), X-rays, an electron beam (EB) and the like. Further, the term “light” in the present invention refers to an actinic ray or radiation.

In addition, unless otherwise specifically indicated, the term “exposure” in the present specification includes not only the exposure performed using a mercury lamp, far-ultraviolet rays represented by an excimer laser, extreme-ultraviolet rays, X-rays, EUV light and the like, but also drawing performed by a particle beam such as an electron beam, an ion beam and the like.

The pattern forming method of the present invention includes:

(a) a process of forming a film by an actinic ray-sensitive or radiation-sensitive resin composition containing the following resin (A) and the following compound (B):
(A) a resin containing a repeating unit (a0) having a —SO₂— group and a repeating unit (a1) having a group which decomposes by the action of an acid to generate a polar group, in which a molar average of C log P values of the respective monomers corresponding to the respective repeating units except for the repeating unit (a0) is 2.0 or more, and
(B) a compound capable of generating an acid upon irradiation with an actinic ray or radiation;

(b) a process of exposing the film; and

(c) a process of developing the exposed film using a developer including an organic solvent to form a negative-type pattern.

The reason that, in forming a fine pattern such as a hole pattern having a hole diameter of 75 nm or less (preferably a hole diameter of 45 nm or less) by an organic developer, the pattern forming method of the present invention has excellent uniformity of a local pattern dimension (Local CDU, nm) and circularity, is not clear, but is estimated as follows.

As described above, since the conventional resin having a cyclic group containing a —SO₂— group has a low solubility in an organic solvent contained in the organic developer (for example, n-butyl acetate) due to a high polarity, the developability tends to deteriorate.

In this regard, in the present invention, it is considered that the solubility in the organic solvent as the whole resin (A) may be enhanced by enhancing the solubility of each repeating unit other than the repeating unit (a0) having a —SO₂— group contained in the resin (A) in the organic solvent, specifically, by setting a molar average of C log P values of the respective monomers corresponding to the respective repeating units except for the repeating unit (a0) to 2.0 or more, thereby enhancing the developability. As a result, in forming a fine pattern such as a hole pattern having a hole diameter of 75 nm or less using the organic developer, the uniformity of the local pattern dimension and the circularity may be excellent.

However, as described above, in a case where a fine hole pattern is formed by a positive-type image forming method, the shape of the pattern is likely to deteriorate, and it is practically impossible to form a fine (for example, a hole diameter of 75 nm or less) pattern. The reason is that, when such a fine pattern is formed by the positive-type image forming method, a region where a hole portion is formed becomes an exposing portion, but it is optically substantially impossible to expose and resolve the fine region.

An exposure light source in the process (b) of exposing the film is not particularly limited, but an ArF excimer laser, an EUV light, an electron ray, and KrF excimer laser may be applicable, and particularly, it is preferred to expose using an ArF excimer laser or an EUV light for minute pattern formation, and it is more preferred to expose using an ArF excimer laser. Further, higher resolution pattern formation may be performed by properly combining a so-called liquid immersion exposure technique.

In the pattern forming method of the present invention, the developer is preferably a developer containing at least one organic solvent selected from the group consisting of a ketone-based solvent, an ester-based solvent, an alcohol-based solvent, an amide-based solvent, and an ether-based solvent.

The pattern forming method of the present invention preferably further includes (d) a process of cleaning with a rinse liquid containing an organic solvent.

The rinse liquid is preferably a rinse liquid containing at least one organic solvent selected from the group consisting of a hydrocarbon-based solvent, a ketone-based solvent, an ester-based solvent, an alcohol-based solvent, an amide-based solvent, and an ether-based solvent.

The pattern forming method of the present invention preferably includes (e) a heating process after (b) the exposure process.

In the pattern forming method of the present invention, the resin (A) is a resin capable of increasing the polarity by the action of an acid to increase the solubility in the alkali developer, and the method may further include (f) a process of developing the film using the alkali developer.

The pattern forming method of the present invention may include (b) the exposure process plurality of times.

The pattern forming method of the present invention may include (e) the heating process plurality of times.

The resist film of the present invention is a film formed by the actinic ray-sensitive or radiation-sensitive resin composition, and for example, a film formed by applying the actinic ray-sensitive or radiation-sensitive resin composition on a substrate.

Hereinafter, an actinic ray-sensitive or radiation-sensitive resin composition that may be used in the present invention will be described.

Further, the present invention also relates to the actinic ray-sensitive or radiation-sensitive resin composition which will be described below.

The actinic ray-sensitive or radiation-sensitive resin composition according to the present invention is used in a negative-type development (development in which when a resist film is exposed, the solubility thereof in the developer is decreased, and thus the exposed portion remains as a pattern and the unexposed portion is removed), for example, in a case where a pattern having a fine hole diameter (for example, a hole diameter of 75 nm or less, and preferably 45 nm or less) is formed on a resist film. That is, the actinic ray-sensitive or radiation-sensitive resin composition according to the present invention may be used as an actinic ray-sensitive or radiation-sensitive resin composition for organic solvent development, which is used for development using a developer including an organic solvent. Here, the term ‘for organic solvent development’ refers to a use that is provided in a process of developing a film using a developer including at least an organic solvent.

It is preferred that the actinic ray-sensitive or radiation-sensitive resin composition of the present invention is typically a resist composition and a negative-type resist composition (that is, a resist composition for organic solvent development), because a particularly good effect may be obtained. In addition, the composition according to the present invention is typically a chemical amplification resist composition.

<(A) Resin containing a repeating unit (a0) having a —SO₂— group and a repeating unit (a1) having a group which decomposes by the action of an acid to generate a polar group, in which a molar average of C log P values of the respective monomers corresponding to the respective repeating units except for the repeating unit (a0) is 2.0 or more.

In the resin (A), a molar average of C log P values of the respective monomers corresponding to the respective repeating units except for the repeating unit (a0) is 2.0 or more.

As the C log P value of the resin (A) is higher, particularly, by setting the molar average of C log P values of the respective monomers corresponding to the respective repeating units except for the repeating unit (a0) to 2.0 or more, the solubility in the solvent is excellent, and thus, the CDU and circularity of the pattern may be enhanced.

Here, the C log P value refers to a common logarithm value of a 1-octanol/water partition coefficient P representing a ratio between equilibrium concentrations of a monomer (compound) in 1-octanol and in water.

In the resin (A), the molar average of C log P values of the respective monomers corresponding to the respective repeating units except for the repeating unit (a0) is preferably 2.5 or more, more preferably 3.0 or more, and still more preferably 3.5 or more, from the viewpoint as described above.

Further, the upper limit of the molar average of C log P values of the respective monomers corresponding to the respective repeating units except for the repeating unit (a0) is not particularly limited, but is preferably 10.0 or less, more preferably 8.0 or less, and still more preferably 6.0 or less.

In the present invention, the molar average of C log P values of the respective monomers corresponding to the respective repeating units except for the repeating unit (a0) may be calculated as follows.

In a case where the resin (A) is constituted by repeating units D1, D2, . . . , Dx, . . . , Dn, C log P values of monomers corresponding to the repeating units D1, D2, . . . , Dx, . . . , Dn are assumed as C log P1, C log P2, . . . , C log Px . . . , C log Pn, respectively, and mole fractions of the repeating units D1, D2, . . . , Dx, . . . , Dn in the resin (A) are assumed as ω1, ω2, . . . , ωx, . . . , ωn, respectively, the molar average of C log P values of the respective monomers corresponding to the respective repeating units except for the repeating unit (a0) may be calculated by the following equation.

Molar average of C log P values of the respective monomers corresponding to the respective repeating units except for the repeating unit (a0)=Σ[(ω1×C log P1)+(ω2×C log P2)+ . . . +(ωx×C log Px)+ . . . +(ωn×C log Pn)]

Further, the C log P values (C log P1, C log P2, . . . , C log Px . . . , C log Pn) of the monomers corresponding to the repeating units D1, D2, . . . , Dx, . . . , Dn may be calculated using ChemBioDraw 12.0 manufactured by Cambridge Soft.

Specific examples of the respective repeating units which may constitute the resin A and C log P values of the monomers corresponding to the repeating units are described below, but the present invention is not limited thereto.

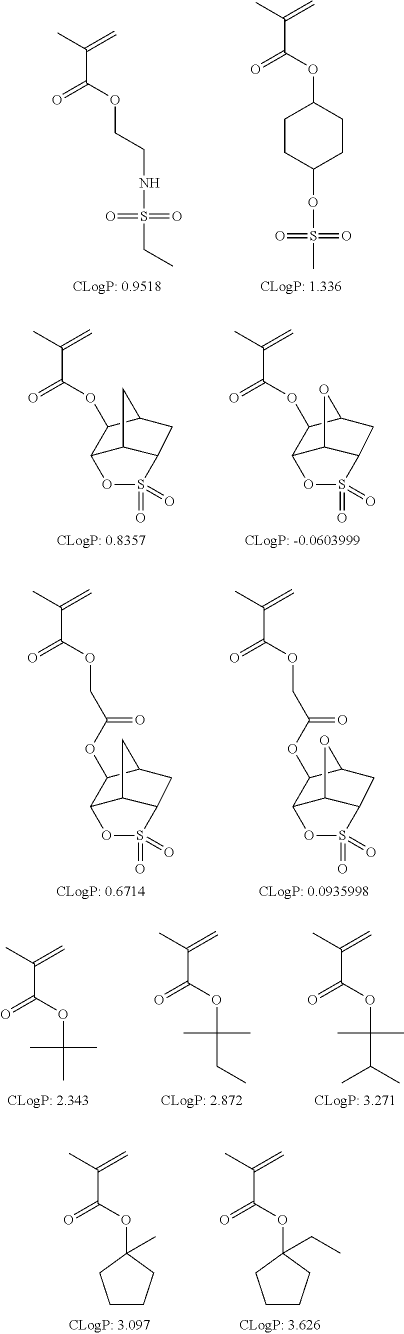

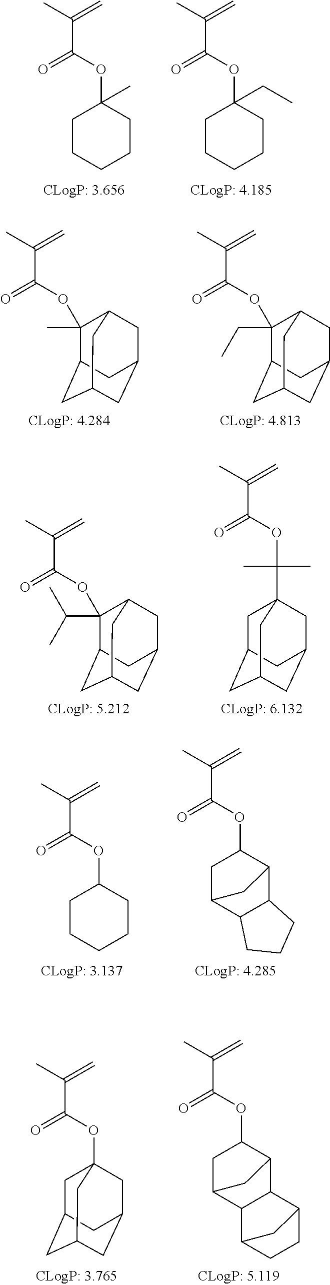

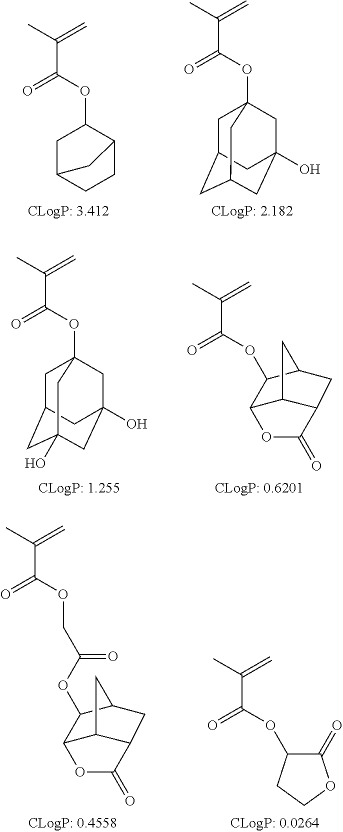

(Repeating Unit (a0) Having a —SO₂— Group)

The resin A contains a repeating unit (a0) having a —SO₂— group.

The repeating unit (a0) having a —SO₂— group is particularly preferably a repeating unit (a0) having a —SO₂—O— group.

Further, the repeating unit (a0) having a —SO₂— group is preferably a (meth)acrylate repeating unit.

The repeating unit (a0) having a —SO₂— group is preferably represented by the following Formula (I).

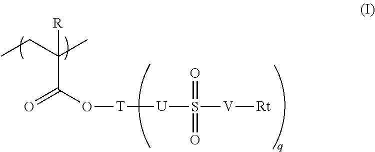

In Formula (I),

R represents a hydrogen atom or an alkyl group.

T represents a single bond or a (q+1)-valent linking group.

Q represents an integer of 1 to 3.

Each of U's and V's independently represents an oxygen atom, an NH group, or a single bond.

Rt represents an alkyl group, a cycloalkyl group or an aryl group.

The cyclo alkyl group for Rt may have a nitrogen atom or an oxygen atom as a ring member.

The alkyl group for R may have a substituent and is an alkyl group having 1 to 5 carbon atoms, and the substituent may include a halogen atom.

The (q+1)-valent linking group for T may include an alkylene group, a cycloalkylene group, and, when q is 2 to 3, a group formed by subtracting (q−1) hydrogen atoms from an alkylene group or a cycloalkylene group, and the cycloalkylene group may include a nitrogen atom or an oxygen atom as a ring member.

q is preferably 1 or 2, and more preferably 1.

Any one of U and V is preferably an oxygen atom, and in that case, the other is preferably is an NH group or a single bond.

The alkyl group for Rt may have a substituent and is preferably an alkyl group having 1 to 5 carbon atoms.

The cycloalkyl group for Rt may have a substituent and is preferably a cycloalkyl group having 1 to 5 carbon atoms.

The aryl group for Rt may have a substituent and is preferably an aryl group having 6 to 20 carbon atoms.

The substituent may include a halogen atom.

Specific examples of the repeating unit (a0) having a —SO₂— group may include the following structures, but the present invention is not limited thereto.

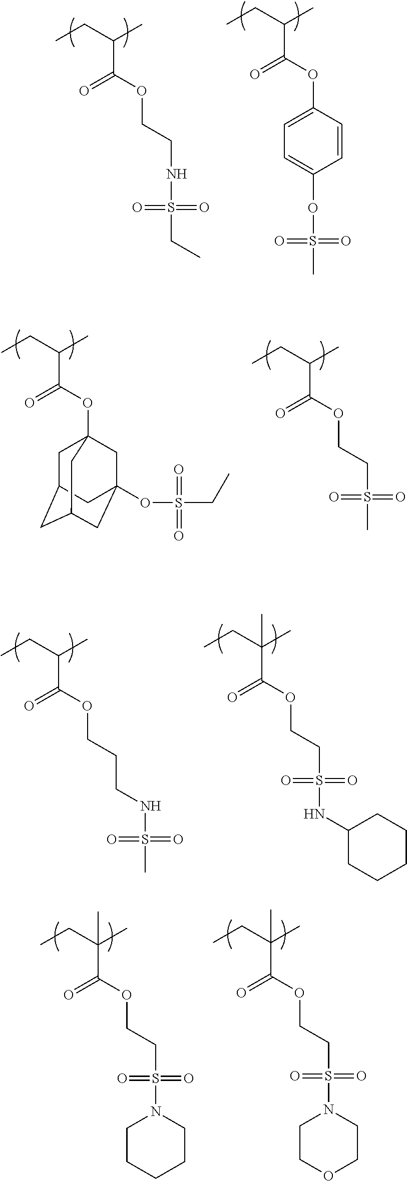

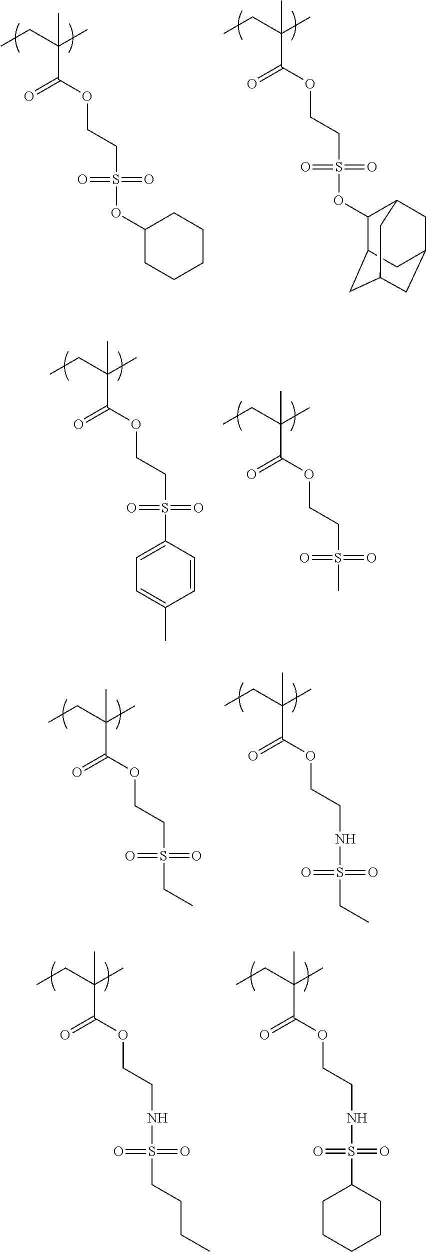

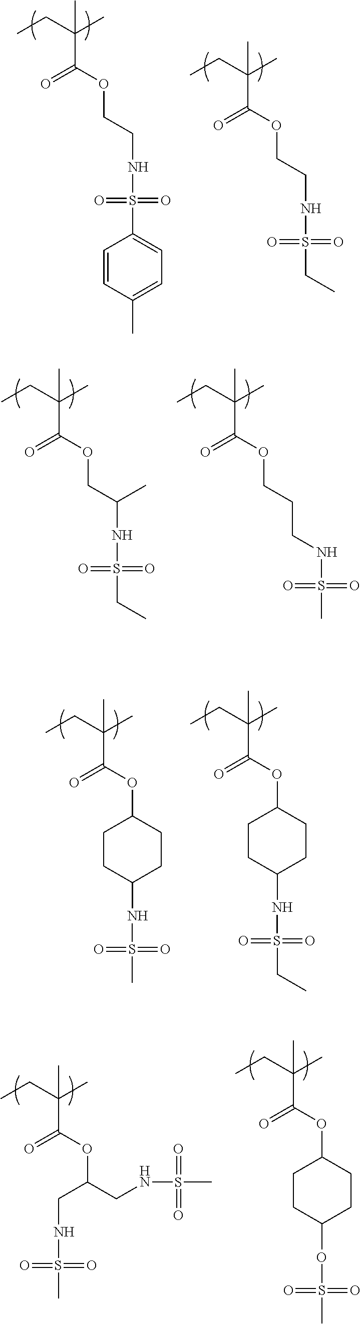

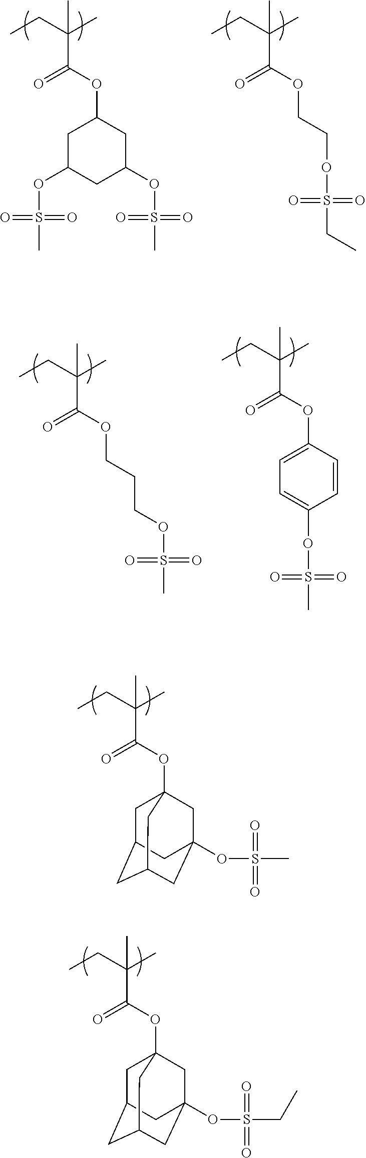

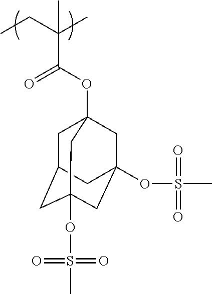

Furthermore, the repeating unit having a —SO₂— group is preferably a repeating unit having a cyclic group containing a —SO₂— group (hereinafter, simply referred to as a —SO₂— group-containing cyclic group). When the ring is counted as the first ring, if the cyclic group has only the ring, it is referred to as a monocyclic group, and if the cyclic group has other ring structures, it is referred to as a polycyclic group regardless of the structure. The cyclic group may be a monocyclic group or a polycyclic group.

Particularly, the cyclic group containing a —SO₂— group is preferably a cyclic group containing a —SO₂—O— group in its ring structure, that is, a sultone ring in which —S—O— in —SO₂—O— forms a part of the ring structure.

The cyclic group containing a —SO₂— group preferably has 3 to 30 carbon atoms, preferably 4 to 20 carbon atoms, more preferably 4 to 15 carbon atoms, and particularly preferably 4 to 12 carbon atoms. However, the number of carbon atoms is the number of carbon atoms constituting the ring structure and excludes the number of carbon atoms in the substituent.

The cyclic group containing a —SO₂— group may be a —SO₂— group-containing aliphatic cyclic group or a —SO₂— group-containing aromatic cyclic group. The —SO₂— group-containing aliphatic cyclic group is preferred.

The —SO₂— group-containing aliphatic cyclic group may include a group formed by subtracting at least one hydrogen atom from an aliphatic hydrocarbon ring in which a part of carbon atoms constituting the ring structure is substituted by a —SO₂— group or a —SO₂—O— group. More particularly, examples thereof may include a group formed by subtracting at least one hydrogen atom from an aliphatic hydrocarbon ring in which —CH₂— constituting the ring structure is substituted by a —SO₂— group, and a group formed by subtracting at least one hydrogen atom from an aliphatic hydrocarbon ring in which —CH₂—CH₂— constituting the ring structure is substituted by a —SO₂—O— group.

The alicyclic hydrocarbon group preferably has 3 to 20 carbon atoms, and more preferably 3 to 12 carbon atoms.

The alicyclic hydrocarbon group may be polycyclic or monocyclic. The monocyclic alicyclic hydrocarbon group is preferably a group formed by subtracting two hydrogen atoms from monocycloalkane having 3 to 6 carbon atoms, and examples of the monocycloalkane may include cyclopentane and cyclohexane. The polycyclic alicyclic hydrocarbon group is preferably a group formed by subtracting two hydrogen atoms from polycycloalkane having 7 to 12 carbon atoms, and specific examples of the polycycloalkane may include adamantane, norbornane, isobornane, tricyclodecane, and tetracyclododecane.

The —SO₂— group-containing cyclic group may have a substituent. Examples of the substituent may include an alkyl group, an alkoxy group, a halogen atom, a halogenated alkyl group, a hydroxyl group, an oxygen atom (═O), —COOR″, —OC(═O)R″ (R″ represents a hydrogen atom or an alkyl group), a hydroxyalkyl group, and a cyano group.

The alkyl group as the substituent is preferably an alkyl group having 1 to 6 carbon atoms. The alkyl group is preferably straight or branched. Specific examples thereof may include a methyl group, an ethyl group, a propyl group, an isopropyl group, a n-butyl group, an isobutyl group, a tert-butyl group, pentyl group, isopentyl group, neopentyl group, and hexyl group. Among those, a methyl group or an ethyl group is preferred, and a methyl group is particularly preferred.

The alkoxy group as the substituent is preferably an alkoxy group having 1 to 6 carbon atoms. The alkoxy group is preferably straight or branched. Specific examples thereof may include a group in which an oxygen atom (—O—) is bonded to the alkyl group exemplified as the alkyl group as the substituent.

The halogen atom as the substituent may include a fluorine atom, a chlorine atom, a bromine atom, and an iodine atom, and preferably a fluorine atom.

The halogenated alkyl group as the substituent may include a group in which some or all hydrogen atoms of the alkyl group are substituted with the halogen atoms.

The halogenated alkyl group as the substituent may include a group in which some or all hydrogen atoms of the alkyl group exemplified as the alkyl group as the substituent, are substituted with the halogen atoms. The halogenated alkyl group is preferably a fluorinated alkyl group, and particularly preferably a perfluoroalkyl group.

R″ in both of —COOR″ and —OC(═O)R″ is preferably a hydrogen atom or a straight, branched, or cyclic alkyl group having 1 to 15 carbon atoms.

When R″ is a straight or branched alkyl group, a group having 1 to 10 carbon atoms is preferred, a group having 1 to 5 carbon atoms is more preferred, and a methyl group or an ethyl group is particularly preferred.

When R″ is a cyclic alkyl group, a group having 3 to 15 carbon atoms is preferred, a group having 4 to 12 carbon atoms is more preferred, and a group having 5 to 10 carbon atoms is most preferred. Specific examples thereof may include a group formed by subtracting one or more hydrogen atom from monocycloalkane or polycycloalkane such as bicycloalkane, tricycloalkane, or tetracycloalkane, which may be unsubstituted or substituted with a fluorine atom or a fluorinated alkyl group. More specific examples may include a group formed by subtracting one or more hydrogen atom from monocycloalkane such as cyclopentane or cyclohexane, or polycycloalkane such as adamantane, norbornane, isobornane, tricyclodecane, or tetracyclododecane.

The hydroxyalkyl group as the substituent is preferably a group having 1 to 6 carbon atoms, and specific examples thereof may include a group in which at least one hydrogen atom of the alkyl group exemplified as the alkyl group as the substitutent, are substituted with hydroxyl groups.

More specific examples of the —SO₂— group-containing cyclic group may include groups represented by the following Formulas (3-1) to (3-4).

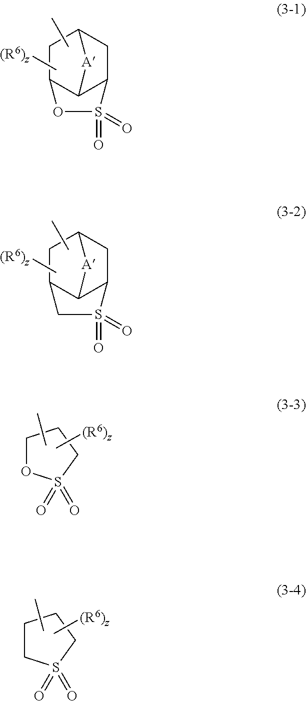

[In the formulas, A′ is an alkylene group having 1 to 5 carbon atoms which may contain an oxygen atom or a sulfur atom, an oxygen atom or a sulfur atom, z is an integer of 0 to 2, R⁶ is an alkyl group, an alkoxy group, a halogenated alkyl group, a hydroxyl group, —COOR″, —OC(═O)R″, a hydroxyalkyl group, or a cyano group, and R″ is a hydrogen atom or an alkyl group.]

In Formulas (3-1) to (3-4), A′ is an alkylene group having 1 to 5 carbon atoms which may contain an oxygen atom (—O—) or a sulfur atom (—S—), an oxygen atom or a sulfur atom.

The alkylene group having 1 to 5 carbon atoms in A′ is preferably a straight or branched alkylene group, and examples thereof may include a methylene group, an ethylene group, a n-propylene group, and an isopropylene group.

When the alkylene group contains an oxygen atom or a sulfur atom, specific examples thereof may include a group intervened by —O— or —S— at an end of the alkylene group or between carbon atoms, for example, —O—CH₂—, —CH₂—O—CH₂—, —S—CH₂—, and —CH₂—S—CH₂—.

A′ is preferably an alkylene group having 1 to 5 carbon atoms or —O—, more preferably an alkylene group having 1 to 5 carbon atoms, and most preferably a methylene group.

z may be any one of 0 to 2, and most preferably 0.

When z is 2, R⁶'s may be same or different.

The alkyl group, the alkoxy group, the halogenated alkyl group, —COOR″, —OC(═O)R″, and the hydroxyalkyl group in R⁶ may be the same as the alkyl group, the alkoxy group, the halogenated alkyl group, —COOR″, —OC(═O) R″, and the hydroxyalkyl group exemplified as a substituent which may be possessed by the —SO₂— group-containing cyclic group, respectively.

Hereinafter, specific cyclic groups represented by Formulas (3-1) to (3-4) will be exemplified. Further, ‘Ac’ in the formulas represents an acetyl group.

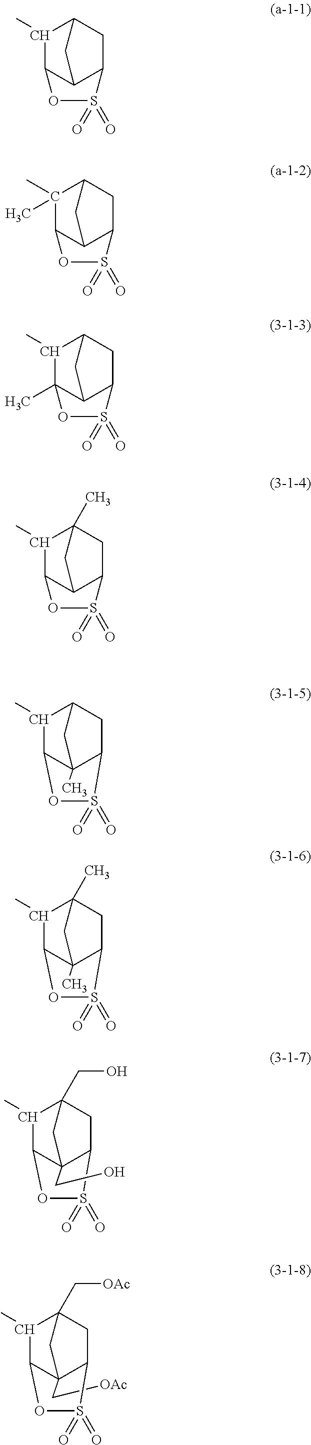

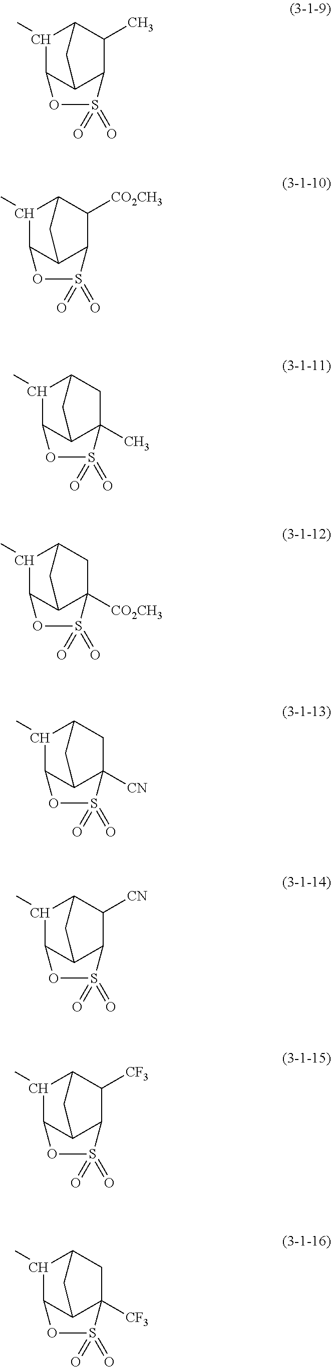

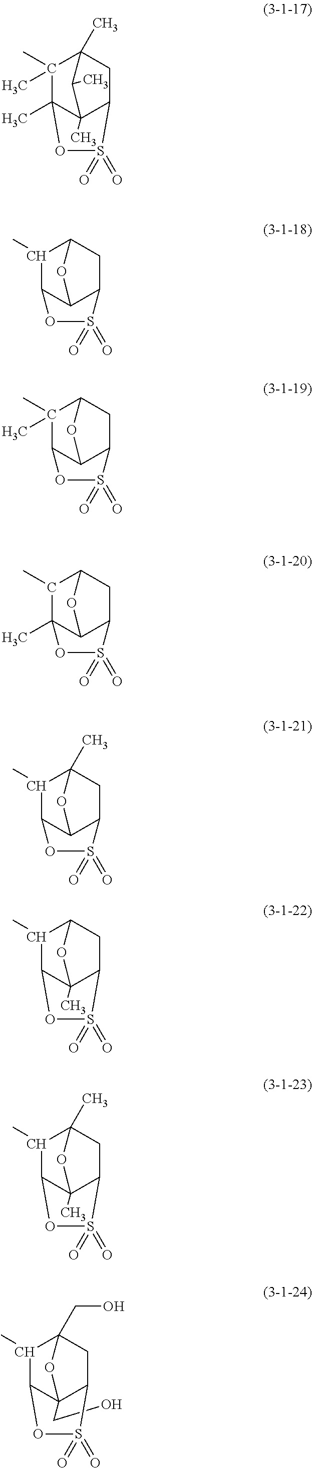

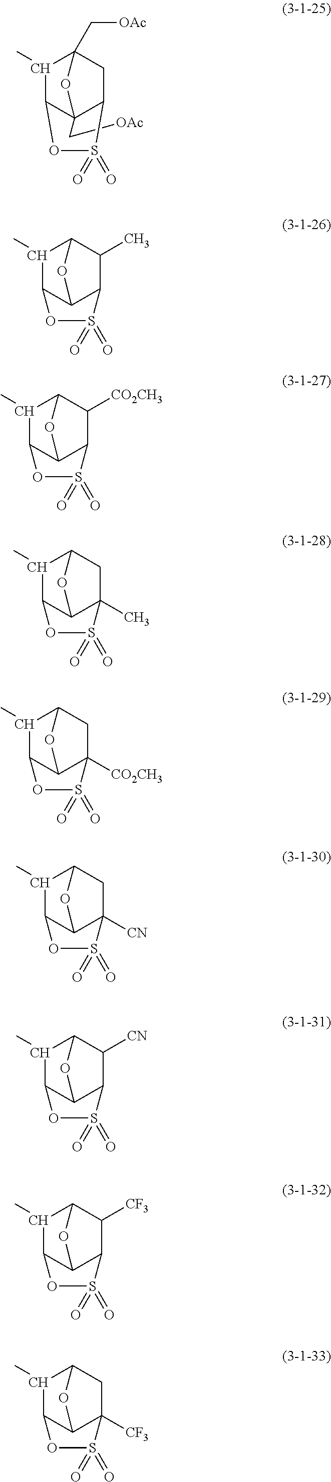

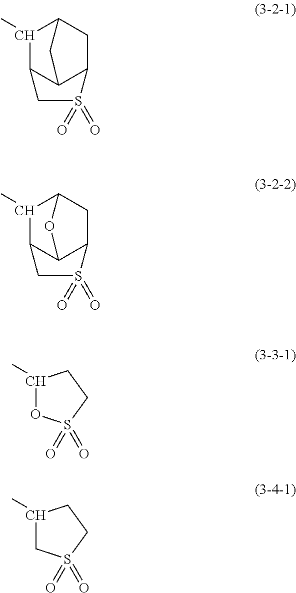

Among those, the —SO₂— group-containing cyclic group is preferably a group represented by Formula (3-1), more preferably at least one selected from the group consisting of groups represented by Formulas (3-1-1), (3-1-18), (3-3-1) and (3-4-1), and most preferably a group represented by Formula (3-1-1).

More specific examples of the repeating unit (a0) may include a repeating unit represented by Formula (a0-1).

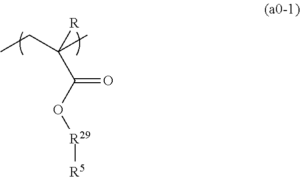

[In the formula, R is a hydrogen atom or an alkyl group, R⁵ is a —SO₂— group-containing cyclic group, R²⁹ is a single bond or a divalent linking group.]

In Formula (a0-1), R is the same as those described above with respect to Formula (I).

R⁵ is the same as the —SO₂— group-containing cyclic group exemplified above.

R²⁹ may be any one of a single bond and a divalent linking group. Since the effect of the present invention is excellent, a divalent linking group is preferred.

The divalent linking group in R²⁹ is not particularly limited, but preferably contains an alkylene group or an ester bond (—C(═O)—O—).

The alkylene group is preferably a straight or branched alkylene group.

The divalent linking group containing an ester bond is particularly preferably a group represented by Formula: —R⁴—C(═O)—O— [in the formula, R⁴ is a divalent linking group]. That is, the repeating unit (a0) is preferably a repeating unit represented by the following Formula (a0-11).

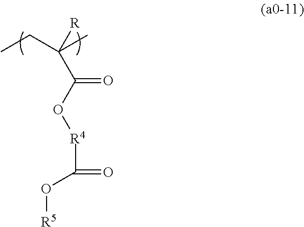

[In the formula, R and R⁵ are the same as those described above, and R⁴ is a divalent linking group.]

The divalent linking group in R⁴ is preferably a straight or branched alkylene group, a divalent alicyclic hydrocarbon group, or a divalent linking group containing a heteroatom.

The straight or branched alkylene group, the divalent alicyclic hydrocarbon group, or the divalent linking group containing a heteroatom is preferably a straight or branched alkylene group, or a divalent linking group containing an oxygen atom as a heteroatom.

The straight alkylene group is preferably a methylene group or an ethylene group, and particularly preferably a methylene group.

The branched alkylene group is preferably an alkylmethylene group or an alkylethylene group, and particularly preferably —CH(CH₃)—, —C(CH₃)₂— or —C(CH₃)₂CH₂—.

The divalent linking group containing an oxygen atom is preferably a divalent linking group containing an ether bond or an ester bond, and particularly preferably a group represented by —(CH₂)c-C(═O)—O—(CH₂)_{d}—. c is an integer of 1 to 5, and preferably 1 or 2. d is an integer of 1 to 5, and preferably 1 or 2.

The repeating unit (a0) is particularly preferably a repeating unit represented by the following Formula (a0-21) or (a0-22), and more preferably a repeating unit represented by Formula (a0-22).

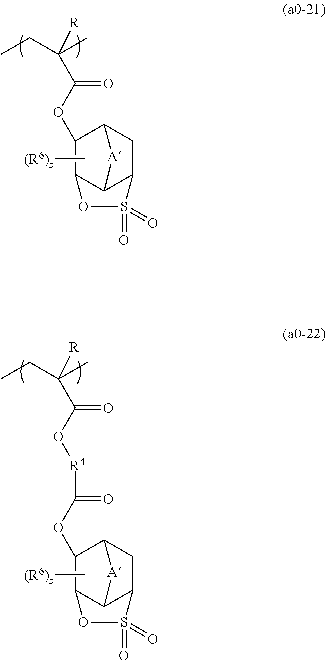

[In the formulas, R, A′, R⁶, z and R⁴ are the same as those described above.]

In Formula (a0-21), A′ is preferably a methylene group, an oxygen atom (—O—) or a sulfur atom (—S—).

R⁴ is preferably a straight or branched alkylene group, or a divalent linking group containing an oxygen atom. The straight or branched alkylene group, and the divalent linking group containing an oxygen atom in R⁴ may include the same straight or branched alkylene group, and the same divalent linking group containing an oxygen atom as those exemplified above, respectively.

The repeating unit represented by Formula (a0-22) is particularly preferably a repeating unit represented by the following Formula (a0-22a) or (a0-22b).

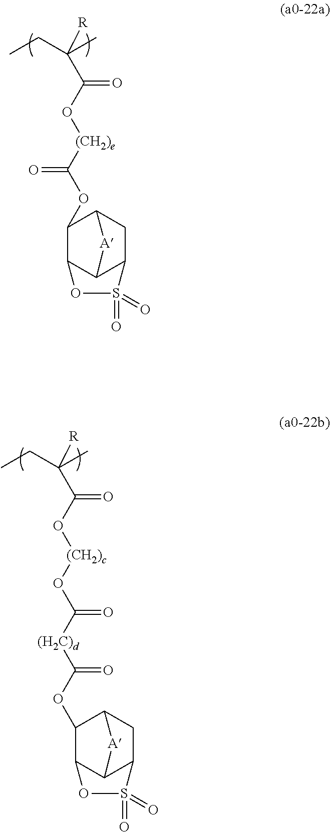

[In the formulas, R and A′ are the same as those described above, and each of c to e independently represents an integer of 1 to 3.]

The repeating unit (a0) contained in the resin (A) may be used either alone or in mixture of two or more thereof.

In the resin (A), a content of the repeating unit (a0) is preferably 1 mol % to 50 mol %, more preferably 1 mol % to 30 mol %, and still more preferably 1 mol % to 20 mol % based on the total of the entire repeating units constituting the resin (A).

(Repeating Unit (a1) Having a Group which Decomposes by the Action of an Acid to Generate a Polar Group (Hereinafter, also Referred to as an ‘Acid-Decomposable Group’))

The resin (A) contains a repeating unit (a1) having an acid-decomposable group.

Here, in the present specification and claims, the ‘acid-decomposable group’ is a group having acid-decomposability in which at least a part of bonds in the structure of the acid-decomposable group is capable of cleaving by the action of an acid (an acid generated from the compound (B) by exposure).

The polar group is not particularly limited as long as it is sparingly soluble or insoluble in a developer containing an organic solvent, but examples thereof may include a carboxyl group, a hydroxyl group, an amino group, and a sulfo group (—SO₃H). Among those, a carboxyl group or a hydroxyl group is preferred, and a carboxyl group is particularly preferred.

More specific examples of the acid-decomposable group may include a group in which a hydrogen atom of the polar group is substituted with an acid-dissociable group.

The ‘acid-dissociable group’ is a group having acid-dissociability in which at least a bond between the acid-dissociable group and an atom adjacent to the acid-dissociable group is capable of cleaving by the action of an acid (an acid generated from the compound (B) by exposure). In the present invention, the acid-dissociable group is preferably a group having a polarity lower than that of a polar group generated by dissociation of the acid-dissociable group, and thus, in the group in which a hydrogen atom of the polar group is substituted with an acid-dissociable group, when the acid-dissociable group is dissociated, the polar group is generated, thereby increasing the polarity. As a result, the hydrophilicity of the entire resin (A) increases and the solubility in an organic developer relatively decreases.

The acid-dissociable group is not particularly limited, and a group which has been suggested so far as an acid-dissociable group of a base resin for chemical amplification resist may be used. Generally, a group forming a cyclic or chained tertiary alkyl ester with a carboxyl group in (meth)acrylic acid; and an acetal type acid-dissociable group such as an alkoxyalkyl group, have been widely known. Further, a “(meth)acrylic acid ester” means one or both of an acrylic acid ester in which a hydrogen atom is bonded at α-position and a methacrylic acid ester in which a methyl group is bonded at α-position.

Here, a “tertiary alkyl ester” means a structure in which the hydrogen atom of a carboxyl group is substituted with a chained or cyclic alkyl group to form an ester, and the tertiary carbon atom of the chained or cyclic alkyl group is bonded to the oxygen atom at the end of the carbonyloxy group (—C(O)—O—). In this tertiary alkyl ester, the bond between the oxygen atom and the tertiary carbon atom is cleaved by the action of an acid.

The chained or cyclic alkyl group may have a substituent.

Hereinafter, a group which becomes acid-dissociable by constituting a tertiary alkyl ester with a carboxyl group is referred to as a “tertiary alkyl ester type acid-dissociable group” for convenience.

The tertiary alkyl ester type acid-dissociable group may include an aliphatic branched acid-dissociable group and an acid-dissociable group containing an aliphatic cyclic group.

Here, the “aliphatic branched” refers to as having a branched structure which does not have aromaticity. The structure of the “aliphatic branched acid-dissociable group” is not limited to a group constituted with carbon and hydrogen (hydrocarbon group), but is preferably a hydrocarbon group. Further, the “hydrocarbon group” may be either saturated or unsaturated, but, in general, is preferably saturated.

Examples of the aliphatic branched acid-dissociable group may include a group represented by —C(R⁷¹)(R⁷²)(R⁷³). In the formula, each of R⁷¹ to R⁷³ independently represents a straight alkyl group having 1 to 5 carbon atoms. The group represented by —C(R⁷¹)(R⁷²)(R⁷³) is preferably a group having 4 to 8 carbon atoms, and specific examples thereof may include a tert-butyl group, 2-methyl-2-butyl group, 2-methyl-2-pentyl group, and 3-methyl-3-pentyl group. Particularly, a tert-butyl group is preferred.

The “aliphatic cyclic group” refers to a monocyclic or polycyclic group which does not have aromaticity.

The aliphatic cyclic group in the “acid-dissociable group containing an aliphatic cyclic group” may or may not have a substituent. Examples of the substituent may include an alkyl group having 1 to 5 carbon atoms, an alkoxy group having 1 to 5 carbon atoms, a fluorine atom, a fluorinated alkyl group having 1 to 5 carbon atoms which is substituted with a fluorine atom, and an oxygen atom (═O).

A basic ring structure of the aliphatic cyclic group excluding a substituent is not limited to a group constituted with carbon and hydrogen (hydrocarbon group), but is preferably a hydrocarbon group. Further, the hydrocarbon group may be either saturated or unsaturated, but, in general, is preferably saturated.

The aliphatic cyclic group may be either monocyclic or polycyclic.

Examples of the aliphatic cyclic group may include a group formed by subtracting one or more hydrogen atom from monocycloalkane which may or may not be substituted with an alkyl group having 1 to 5 carbon atoms, fluorine atom or a fluorinated alkyl group, and a group formed by subtracting one or more hydrogen atoms from polycycloalkane such as bicycloalkane, tricycloalkane, and teteracycloalkane. More specific examples thereof may include an alicyclic hydrocarbon group such as a group formed by subtracting one or more hydrogen atom from monocycloalkane such as cyclopentane or cyclohexane, or a group formed by subtracting one or more hydrogen atom from polycycloalkane such as adamantane, norbornane, isobornane, tricyclodecane, or tetracyclododecane. Further, a part of carbon atoms constituting the ring of the alicyclic hydrocarbon group may be substituted with an ether group (—O—).

Examples of the acid-dissociable group containing an aliphatic cyclic group may include

(i) a group in which a substituent (an atom or a group other than a hydrogen atom) is bonded to a carbon atom binding with an atom (for example, —O— in —C(═O)—O—) adjacent to the acid-dissociable group, on a ring structure of a monovalent aliphatic cyclic group, to form a tertiary carbon atom; and

(ii) a group having a monovalent aliphatic cyclic group, and branched alkylene having a tertiary carbon atom bonded thereto.

In the group of (i), examples of the substituent which is bonded to a carbon atom binding with an atom adjacent to the acid-dissociable group, on a ring structure of an aliphatic cyclic group, may include an alkyl group. Examples of the alkyl group may include the same group as R¹⁴ in Formulas (1-1) to (1-9) to be described later.

Specific examples of the group of (i) may include groups represented by the following Formulas (1-1) to (1-9).

Specific examples of the group of (ii) may include groups represented by the following Formula (2-1) to (2-6).

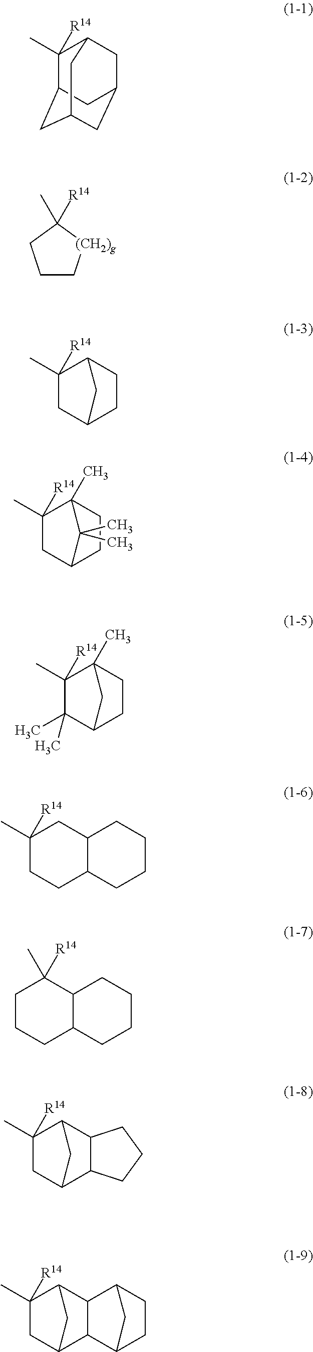

[In the formulas, R¹⁴ is an alkyl group, and g is an integer of 0 to 8.]

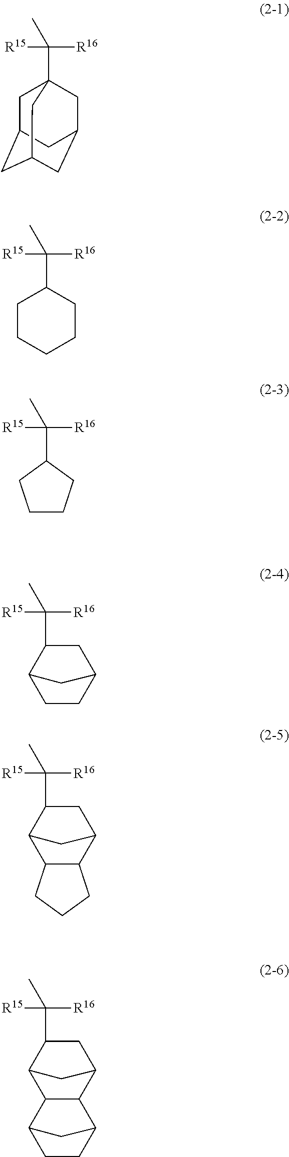

[In formulas, each of R¹⁵ and R¹⁶ independently represents an alkyl group.]

In Formulas (1-1) to (1-9), the alkyl group in R¹⁴ may be straight, branched, or cyclic, and is preferably straight or branched.

The straight alkyl group has preferably 1 to 5 carbon atoms, more preferably 1 to 4 carbon atoms, and still more preferably 1 or 2 carbon atoms. Specific examples thereof may include a methyl group, an ethyl group, a n-propyl group, a n-butyl group, and a n-pentyl group. Among those, a methyl group, ethyl group or n-butyl group is preferred, and a methyl group or ethyl group is more preferred.

The branched alkyl group has preferably 3 to 10 carbon atoms, and more preferably 3 to 5 carbon atoms. Specific examples thereof may include an isopropyl group, an isobutyl group, a tert-butyl group, an isopentyl group, and a neopentyl group, and most preferably an isopropyl group.

g is preferably an integer of 0 to 3, more preferably an integer of 1 to 3, and still more preferably 1 or 2.

In Formulas (2-1) to (2-6), the alkyl group of R¹⁵ to R¹⁶ may be the same as the alkyl group of R¹⁴.

In Formulas (1-1) to (1-9), and (2-1) to (2-6), a part of carbon atoms constituting the ring may be substituted with an ethereal oxygen atom (—O—).

Further, in Formulas (1-1) to (1-9), and (2-1) to (2-6), a hydrogen atom bonded to a carbon atom constituting the ring may be substituted with a substituent. Examples of the substituent may include an alkyl group having 1 to 5 carbon atoms, a fluorine atom, a fluorinated alkyl group.

More specific examples of the repeating unit (a1) may include a repeating unit represented by the following Formula (a1-0-1).

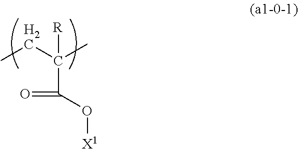

[In the formula, R is a hydrogen atom or an alkyl group; and X¹ is an acid-dissociable group.]

In Formula (a1-0-1), the alkyl group of R may have a substituent, and is preferably an alkyl group having 1 to 5 carbon atoms. Examples of the substituent may include a halogen atom. R is preferably a hydrogen atom, an alkyl group having 1 to 5 carbon atoms or a fluorinated alkyl group having 1 to 5 carbon atoms, and most preferably a hydrogen atom or a methyl group.

X¹ is not particularly limited as long as it is an acid-dissociable group, and examples thereof may include the above-mentioned tertiary alkyl ester type acid-dissociable group and acetal type acid-dissociable group, and preferably a tertiary alkyl ester type acid-dissociable group.

Specific examples of the repeating unit having an acid-decomposable group are shown below.

In the specific examples, Rx represents a hydrogen atom, CH₃, CF₃, or CH₂OH. Each of Rxa and Rxb represents an alkyl group having 1 to 4 carbon atoms. Z represents a substituent, and when a plurality of Z's is present, Z's may be the same or different. p represents 0 or a positive integer. Specific examples and preferred examples of Z are the same as the specific examples and preferred examples of the substituent which may be possessed by each of the above-described groups such as an aliphatic cyclic group.

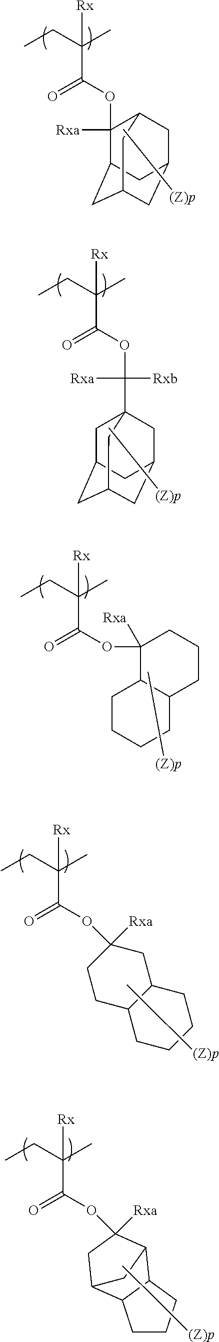

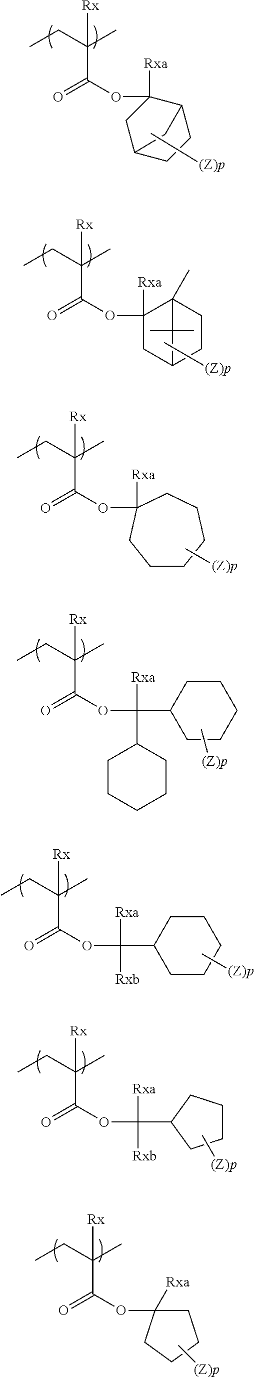

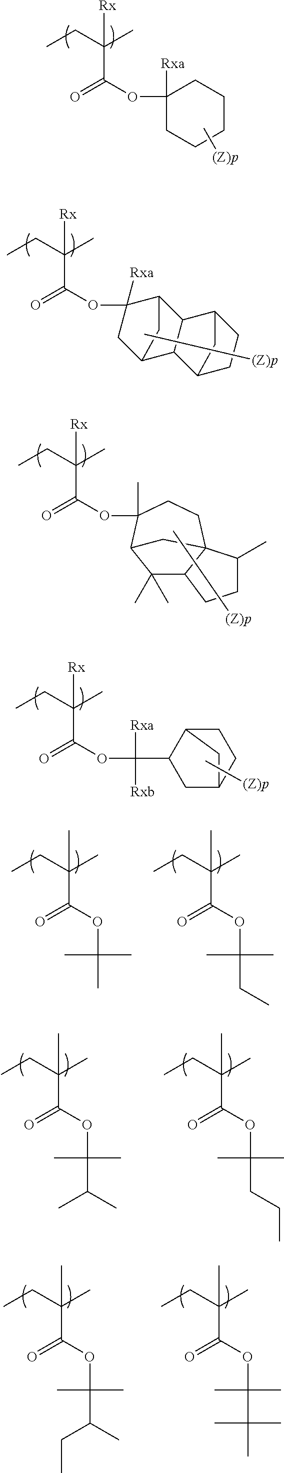

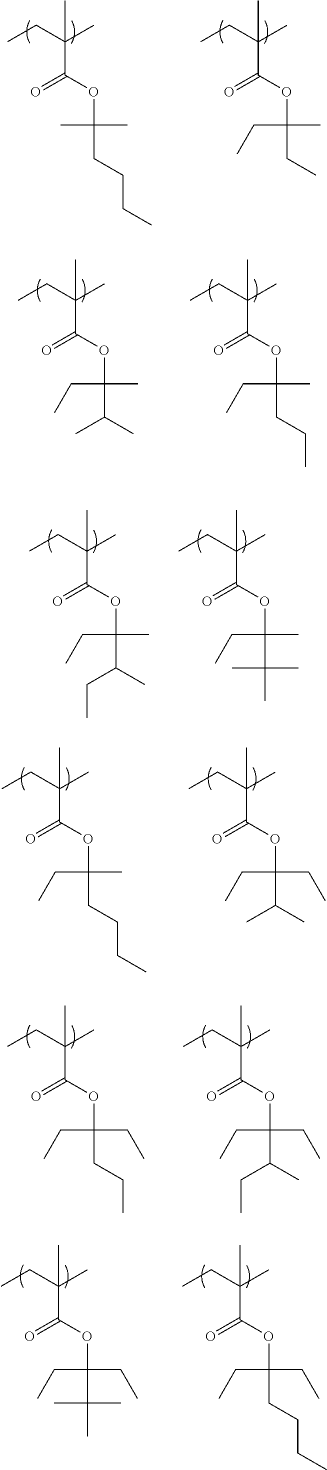

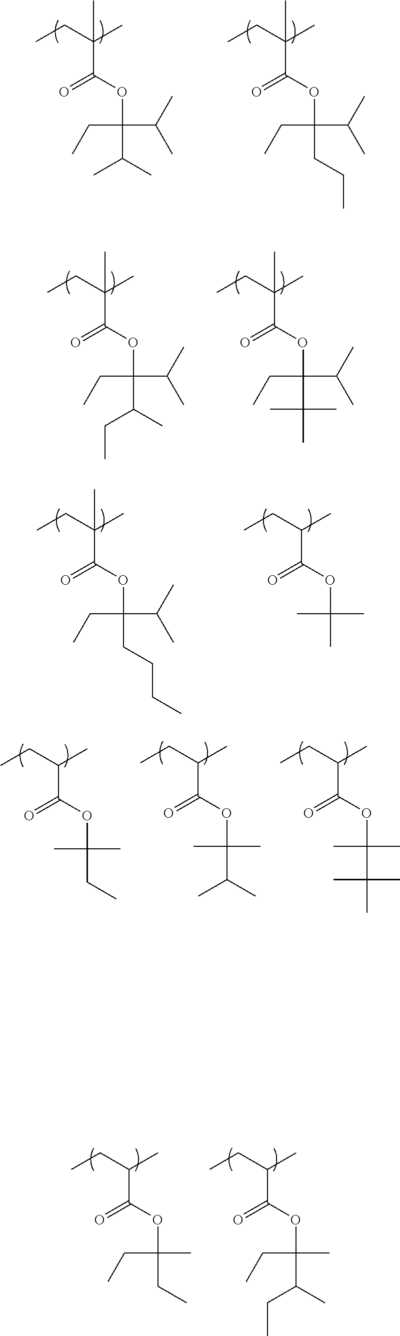

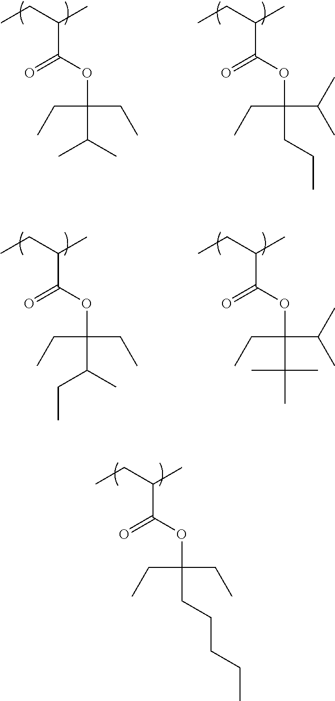

Among those, the repeating unit having an acid-decomposable group is preferably a repeating unit represented by the following Formula (a1-1-02) or (a1-1-02′).

In each formula, h is preferably 1 or 2.

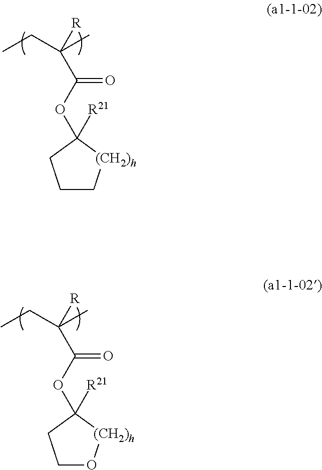

[In the formulas, R is the same as that described above, R²¹ is an alkyl group, and h is an integer of 1 to 3.]

Specific examples and preferred examples of R²¹ are the same as the above-described specific examples and preferred examples of the alkyl group for R¹⁴.

The repeating unit (a1) contained in the resin (A) may be used either alone or in mixture of two or more thereof.

In the resin (A), the content of the repeating unit (a1) is preferably 50 mol % or more, more preferably 60 mol % to 97 mol %, and still more preferably 65 mol % to 90 mol % based on the entire repeating units of the resin (A). By setting the content to the lower limit or more, when used as an actinic ray-sensitive or radiation-sensitive resin composition, a pattern may be easily obtained, so that lithography characteristics such as CDU and circularity may be enhanced. Further, by setting the content to the upper limit or less, it is possible to make a balance with other repeating units.

(Repeating Unit (a2) Having a Non-Acid-Decomposable Aliphatic Hydrocarbon Group)

The resin (A) preferably further contains a repeating unit (a2) having a non-acid-decomposable aliphatic hydrocarbon group.

Here, “acid non-dissociable aliphatic cyclic group” refers to an aliphatic cyclic group which remains as it is in the repeating unit without being dissociated by the action of an acid when the acid is generated from the compound (B) by exposure.

In the repeating unit (a2) having a non-acid-decomposable aliphatic hydrocarbon group, a repeating unit having a polar group is referred to as a repeating unit (a3), and a repeating unit having no polar group such as an alcoholic hydroxyl group is referred to as a repeating unit (a4).

The repeating unit (a2) having a non-acid-decomposable aliphatic hydrocarbon group is preferably a repeating unit (a4) which refers to a repeating unit having no polar group such as an alcoholic hydroxyl group.

(Repeating Unit (a3) Having a Non-Acid-Decomposable Aliphatic Hydrocarbon Group Having a Polar Group)

The repeating unit (a3) is a repeating unit having a non-acid-decomposable aliphatic hydrocarbon group having a polar group. Further, the repeating unit (a3) is a repeating unit which does not correspond to the repeating units (a0) and (a1).

Examples of the polar group may include a hydroxyl group (such as an alcoholic hydroxyl group), a cyano group, a carboxyl group, and a fluorinated alcohol group (a hydroxyalkyl group in which a part of hydrogen atoms of an alkyl group is substituted with a fluorine atom).

Among those, a hydroxyl group or a carboxyl group is preferred, and a hydroxyl group is particularly preferred.

In the repeating unit (a3), the number of the polar groups bonded to the aliphatic hydrocarbon group is not particularly limited, but is preferably 1 to 3, and most preferably 1.

The aliphatic hydrocarbon group bonded with the polar group may be saturated or unsaturated, and is preferably saturated.

More specific examples of the aliphatic hydrocarbon group may include a straight or branched aliphatic hydrocarbon group, and an aliphatic hydrocarbon group containing a ring in its structure.

The “straight or branched aliphatic hydrocarbon group” has preferably 1 to 12 carbon atoms, more preferably 1 to 10 carbon atoms, still more preferably 1 to 8 carbon atoms, and yet more preferably 1 to 6 carbon atoms.

In the straight or branched aliphatic hydrocarbon group, some or all of hydrogen atoms may be substituted with substituents other than the polar groups. Examples of the substituent may include a fluorine atom, a fluorinated alkyl group having 1 to 5 carbon atoms which is substituted with a fluorine atom, and an oxygen atom (═O). Further, the straight or branched aliphatic hydrocarbon group may be intervened with a divalent group containing a heteroatom between carbon atoms.

When the aliphatic hydrocarbon group is straight or branched, the repeating unit (a3) is preferably a repeating unit represented by the following Formula (a3-1) or (a3-2).

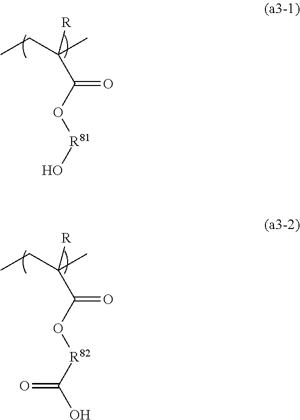

[In the formulas, R is the same as that described above, R⁸¹ is a straight or branched alkylene group, and R⁸² is an alkylene group which may be intervened by a divalent group containing a heteroatom.]

In Formula (a3-1), the alkylene group in R⁸¹ has preferably 1 to 12 carbon atoms, and more preferably 1 to 10 carbon atoms.

In Formula (a3-2), the alkylene group in R⁸² has preferably 1 to 12 carbon atoms, more preferably 1 to 10 carbon atoms, and particularly preferably 1 to 6 carbon atoms.

When the alkylene group is an alkylene group having 2 or more carbon atoms, a divalent group containing a heteroatom may be intervened between carbon atoms of the alkylene group.

R⁸² is particularly preferably an alkylene group which is not intervened with a divalent group containing a heteroatom, or an alkylene group which is intervened with a divalent group containing an oxygen atom as a heteroatom.

The alkylene group which is intervened with a divalent group containing an oxygen atom is preferably —(CH₂)f-O—C(═O)—(CH₂)g′- [in the formula, each of f and g′ independently represents an integer of 1 to 3].

Examples of the “aliphatic hydrocarbon group containing a ring in its structure” may include a cyclic aliphatic hydrocarbon group, and a group in which the cyclic aliphatic hydrocarbon group is bonded to an end of the above-described chained aliphatic hydrocarbon group or intervened in the middle of the chained aliphatic hydrocarbon group.

The cyclic aliphatic hydrocarbon group has preferably 3 to 30 carbon atoms. Further, the cyclic aliphatic hydrocarbon group may be monocyclic or polycyclic, and preferably polycyclic.

Specific examples of the cyclic aliphatic hydrocarbon group are suggested for a resin for a resist composition for ArF excimer laser, and may be suitably selected and used among those. For example, the monocyclic aliphatic hydrocarbon group is preferably a group formed by subtracting two or more hydrogen atoms from a monocycloalkane having 3 to 20 carbon atoms, and the monocycloalkane may be exemplified with cyclopentane or cyclohexane. The polycyclic aliphatic hydrocarbon group is preferably a group formed by subtracting two or more hydrogen atoms from polycycloalkane having 7 to 30 carbon atoms, and specific examples of the polycycloalkane may include adamantane, norbornane, isobornane, tricyclodecane, and tetracyclododecane.

In the cyclic aliphatic hydrocarbon group, some or all of hydrogen atoms may be substituted with substituents other than the polar groups. Examples of the substituent may include an alkyl group having 1 to 5 carbon atoms, a fluorine atom, a fluorinated alkyl group having 1 to 5 carbon atoms which is substituted with a fluorine atom, and oxygen atom (═O).

When the aliphatic hydrocarbon group contains a ring in its structure, the repeating unit (a3) is preferably a repeating unit represented by the following Formula (a3-3), (a3-4) or (a3-5).

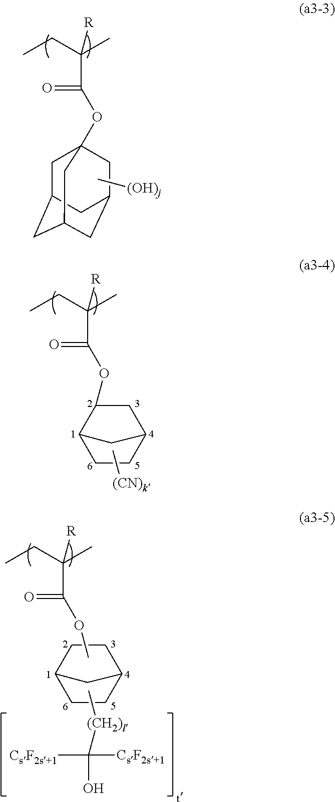

[In the formulas, R is the same as that described above, j is an integer of 1 to 3, k′ is an integer of 1 to 3, t′ is an integer of 1 to 3, l′ is an integer of 1 to 5, and s′ is an integer of 1 to 3.]

In Formula (a3-3), j is preferably 1 or 2, and more preferably 1. When j is 2, it is preferred that the hydroxyl groups are bonded at 3-position and 5-position of the adamantyl group. When j is 1, it is preferred that the hydroxyl group is bonded at 3-portion of the adamantly group.

In Formula (a3-4), k′ is preferably 1. It is preferred that the cyano group is bonded at 5-position or 6-position of the norbornyl group.

In Formula (a3-5), t′ is preferably 1. l′ is preferably 1. s′ is preferably 1.

In Formula (a3-5), it is preferred that the oxygen atom (—O—) of the carbonyloxy group is bonded at 2-position or 3-position of the norbornane ring. It is preferred that the fluorinated alcohol group is bonded at 5-position or 6-position of the norbornyl group.

The repeating unit (a3) contained in the resin (A) may be used either alone or in mixture of two or more thereof.

The repeating unit (a3) preferably has a repeating unit represented by any one of Formulas (a3-1) to (a3-5), and particularly preferably a repeating unit represented by Formula (a3-3).

In a resin (A), the content of the repeating unit (a3) is preferably 1 mol % to 40 mol %, more preferably 5 mol % to 35 mol %, and more preferably 5 mol % to 30 mol % based on the entire repeating units constituting the resin (A). By setting the content to the lower limit or more, an effect by inclusion of the repeating unit (a3) may be sufficiently obtained, and, by setting the content to the upper limit or less, it is possible to make a balance with other repeating units.

(Repeating Unit (a4))

The repeating unit (a4) is a repeating unit which does not contain a polar group such as an alcoholic hydroxyl group, among the non-acid-decomposable aliphatic cyclic groups.

The aliphatic cyclic group is not particularly limited as long as it is non-acid-decomposable, and many of those which have been conventionally known as those used in a resin component of a resist composition for ArF excimer laser or KrF excimer laser (preferably ArF excimer laser) may be used. The aliphatic cyclic group may be saturated or unsaturated, and preferably saturated. Specific examples thereof may include a group formed by subtracting one hydrogen atom from cycloalkane such as monocycloalkane or polycycloalkane as exemplified in the description of the aliphatic cyclic group in the repeating unit (a1).

The aliphatic cyclic group may be monocyclic or polycyclic, and is preferably polycyclic because of the excellent effect. Particularly, di- to tetra-cyclic group is preferred, and among those, at least one selected from the group consisting of a tricyclodecyl group, an adamantyl group, a tetercyclododecyl group, an isobornyl group and a nobornyl group is preferred in terms of easy industrial availability.

Specific examples of the non-acid-decomposable aliphatic cyclic group may include a monovalent aliphatic cyclic group in which a substituent (an atom or a group other than a hydrogen atom) is not bonded to a carbon atom binding with an atom (for example, —O— in —C(═O)—O—) adjacent to the aliphatic cyclic group. Specific examples thereof may include a group in which R¹⁴ in the groups represented by Formulas (1-1) to (1-9) exemplified in the description of the repeating unit (a1) is substituted with a hydrogen atom; and a group formed by subtracting a hydrogen atom from the tertiary carbon atom of the cycloalkane having a tertiary carbon atom formed only by the carbon atoms constituting the ring structure.

The aliphatic cyclic group may be bonded with a substituent. Examples of the substituent may include an alkyl group having 1 to 5 carbon atoms, a fluorine atom, and a fluorinated alkyl group.

The repeating unit (a4) is preferably a repeating unit represented by the following Formula (a4-0), and particularly preferably repeating units represented by the following Formulas (a4-1) to (a4-5).

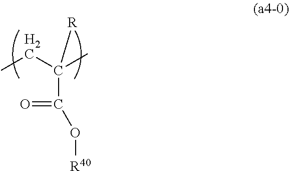

[In the formula, R is the same as that described above, and R⁴⁰ is a non-acid-decomposable aliphatic polycyclic group.]

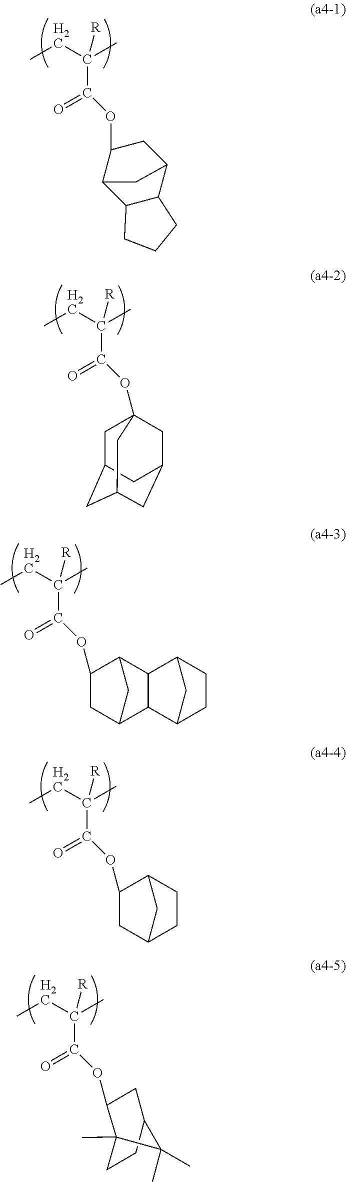

[In the formulas, R is the same as that described above.]

The repeating unit (a4) contained in the resin (A) may be used either alone or in mixture of two or more thereof.

When the repeating unit (a4) is contained in the resin (A), the content of the repeating unit (a4) in the resin (A) is preferably 5 mol % to 40 mol %, and more preferably 10 mol % to 35 mol % based on the entire repeating units constituting the resin (A).

The resin (A) may contain other repeating units other than the repeating units (a0) to (a4) within a range which does not impair the effect of the present invention.

The other repeating units are not particularly limited as long as they are not classified into the above-described repeating units (a0) to (a4), and many of those which have been conventionally known as those used in a resin component of a resist composition for ArF excimer laser or KrF excimer laser (preferably ArF excimer laser) may be used.

(Repeating Unit (b) Containing a Lactone-Containing Cyclic Group)

Further, the resin (A) may have a repeating unit (b) containing a lactone-containing cyclic group.

Here, the lactone-containing cyclic group represents a cyclic group containing a ring (a lactone ring) containing —O—C(O)— in its ring structure. When the lactone ring is counted as the first ring, in a case where only the lactone ring is contained, the group is referred to as a monocyclic group, and in a case where other ring structures are contained, it is referred to as a polycyclic group regardless of the structure. The lactone-containing group may be monocyclic or polycyclic.

Any lactone-containing cyclic group may be used in the repeating unit (b) without being particularly limited. Specific examples of the lactone-containing monocyclic group may include a group formed by subtracting one hydrogen atom from a 4- to 6-membered ring lactone, for example, a group formed by subtracting one hydrogen atom from β-propiolactone, a group formed by subtracting one hydrogen atom from γ-butyrolactone, and a group formed by subtracting one hydrogen atom from δ-valerolactone. Further, examples of the lactone-containing polycyclic group may include a group formed by subtracting one hydrogen atom from bicycloalkane, tricycloalkane, or teteracycloalkane having a lactone ring.

Examples of the repeating unit (b) may include a group in which R⁵ in Formula (a0-1) is substituted with a lactone-containing cyclic group, and more specifically, repeating units represented by the following Formulas (b-1) to (b-5).

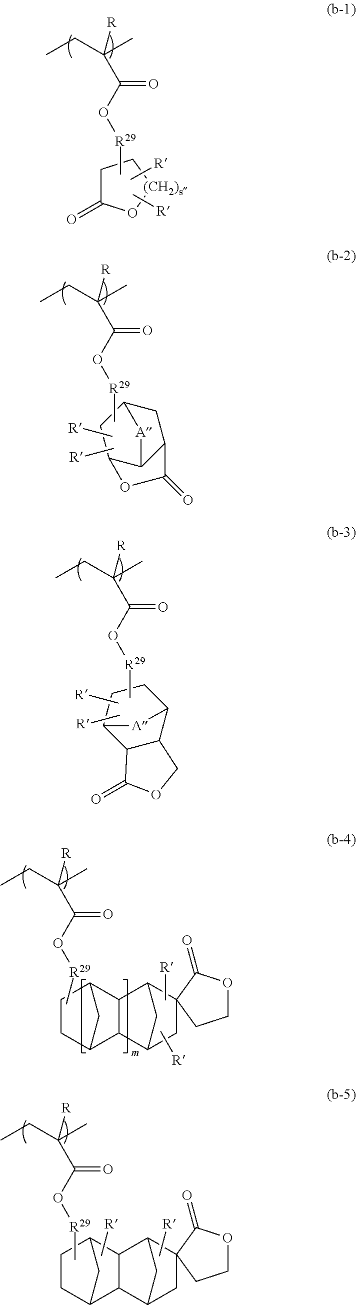

[In the formulas, R is a hydrogen atom, or an alkyl group; R′'s independently represents a hydrogen atom, an alkyl group having 1 to 5 carbon atoms, an alkoxy group having 1 to 5 carbon atoms or —COOR″, R″ is a hydrogen atom or an alkyl group; R²⁹ is a single bond or a divalent linking group, s″ is an integer of 0 to 2; A″ is an alkylene group having 1 to 5 carbon atoms which may contain an oxygen atom or a sulfur atom, an oxygen atom or a sulfur atom; and m is 0 or 1.]

R in Formulas (b-1) to (b-5) is the same as R in Formula (a0-1).

Examples of the alkyl group having 1 to 5 carbon atoms of R′ may include a methyl group, an ethyl group, a propyl group, a n-butyl group, and a tert-butyl group.

Examples of the alkoxy group having 1 to 5 carbon atoms of R′ may include a methoxy group, an ethoxy group, a n-propoxy group, an iso-propoxy group, a n-butoxy group, and a tert-butoxy group.

R′ is preferably a hydrogen atom in terms of easy industrial availability.

The alkyl group in R″ may be straight, branched, or cyclic.

When R″ is a straight or branched alkyl group, a group having 1 to 10 carbon atoms is preferred, and a group having 1 to 5 carbon atoms is more preferred.

When R″ is a cyclic alkyl group, a group having 3 to 15 carbon atoms is preferred, a group having 4 to 12 carbon atoms is more preferred, and a group having 5 to 10 carbon atoms is most preferred. Specific examples thereof may include a group formed by subtracting one or more hydrogen atoms from monocycloalkane or polycycloalkane such as bicycloalkane, tricycloalkane, or tetracycloalkane which may be substituted with a fluorine atom or a fluorinated alkyl group. Specific examples thereof may include a group formed by subtracting one or more hydrogen atoms from monocycloalkane such as cyclopentane or cyclohexane, or polycycloalkane such as adamantane, norbornane, isobornane, tricyclodecane, or tetracyclododecane.

A″ is preferably an alkylene group having 1 to 5 carbon atoms, an oxygen atom (—O—) or a sulfur atom (—S—), and more preferably an alkylene group having 1 to 5 carbon atoms or —O—. The alkylene group having 1 to 5 carbon atoms is more preferably a methylene group or a dimethylmethylene group, and most preferably a methylene group.

R²⁹ is the same as R²⁹ in Formula (a0-1).

In Formula (b-1), s″ is preferably 1 to 2.

Specific examples of the repeating units represented by Formulas (b-1) to (b-5) are shown below. In each formula below, R^{α} represents a hydrogen atom, a methyl group or a trifluoromethyl group.

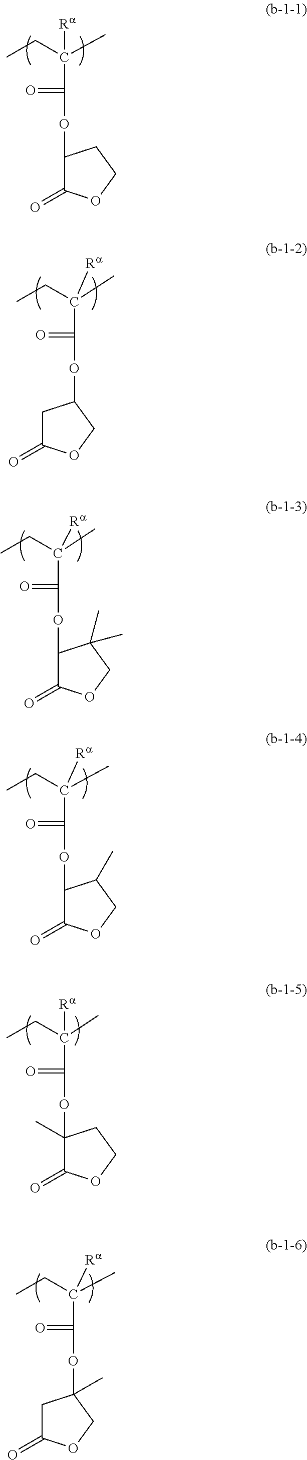

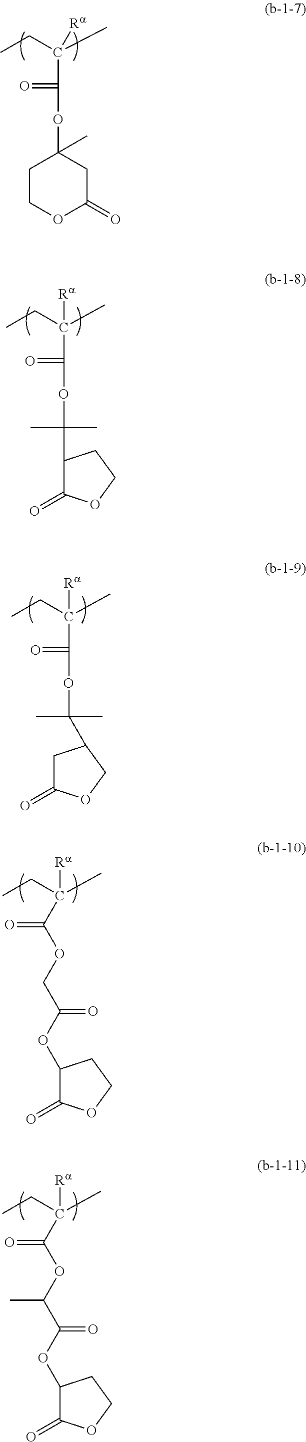

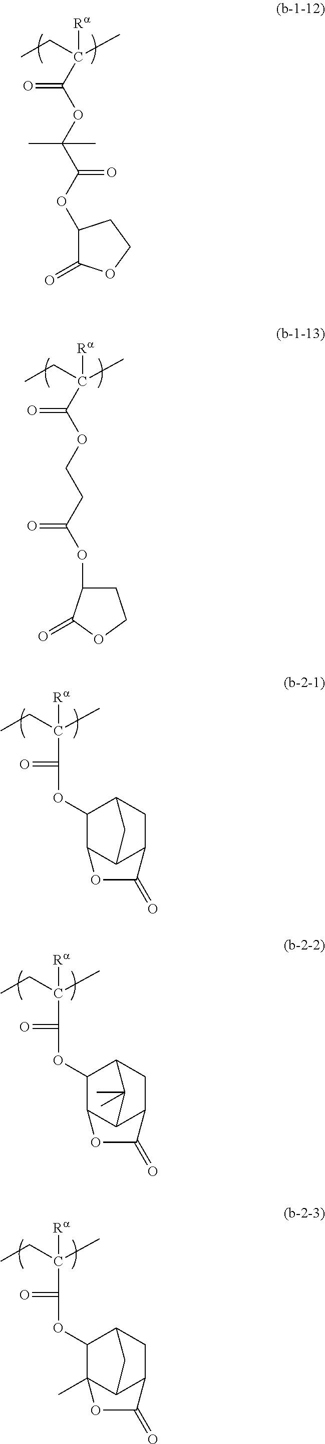

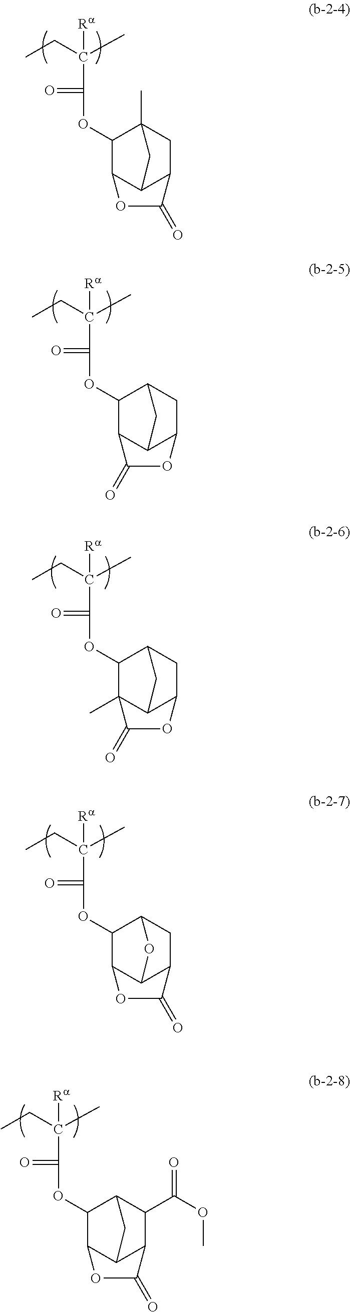

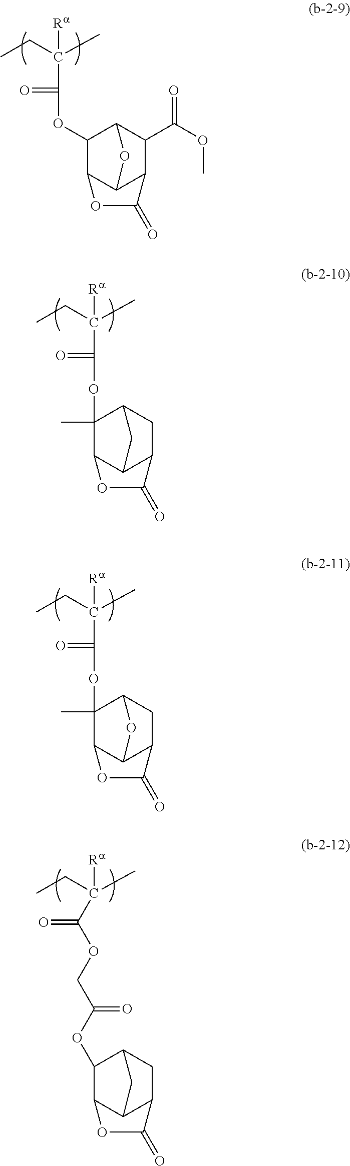

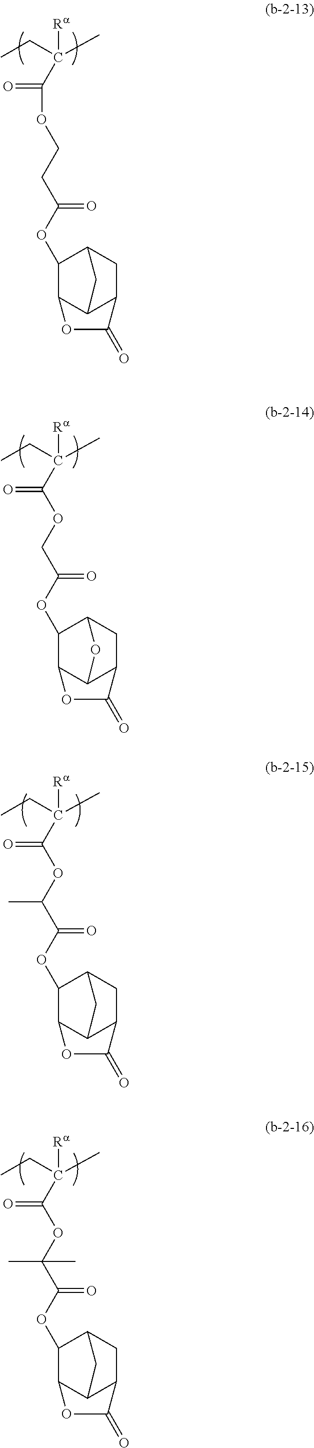

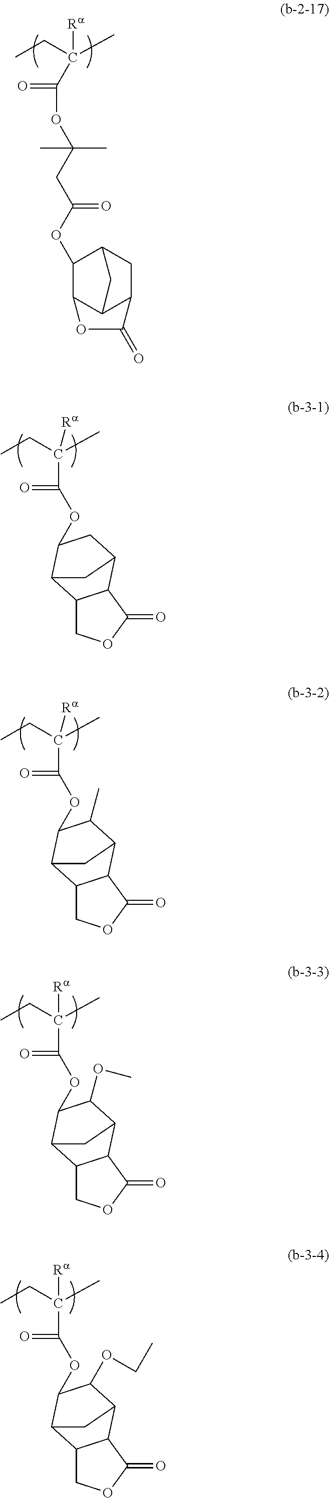

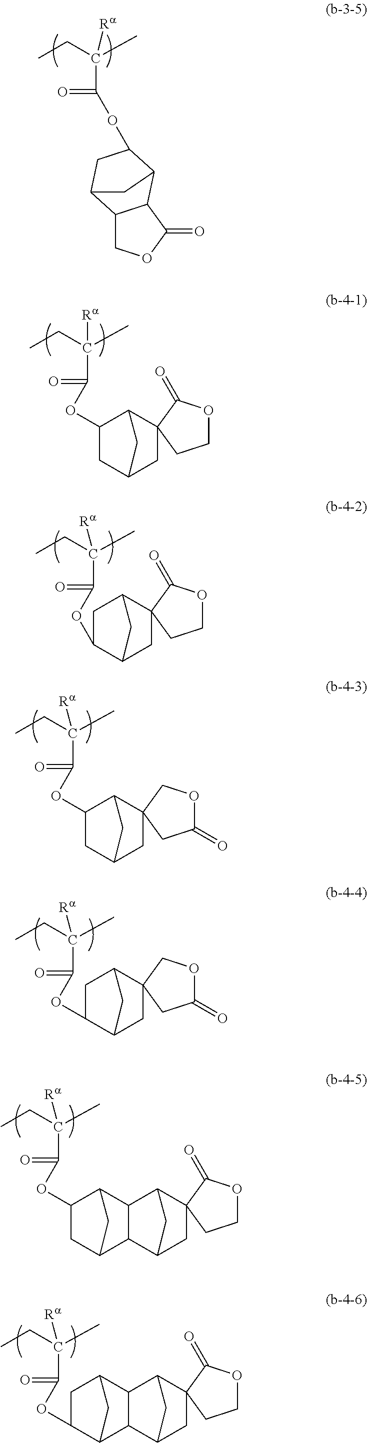

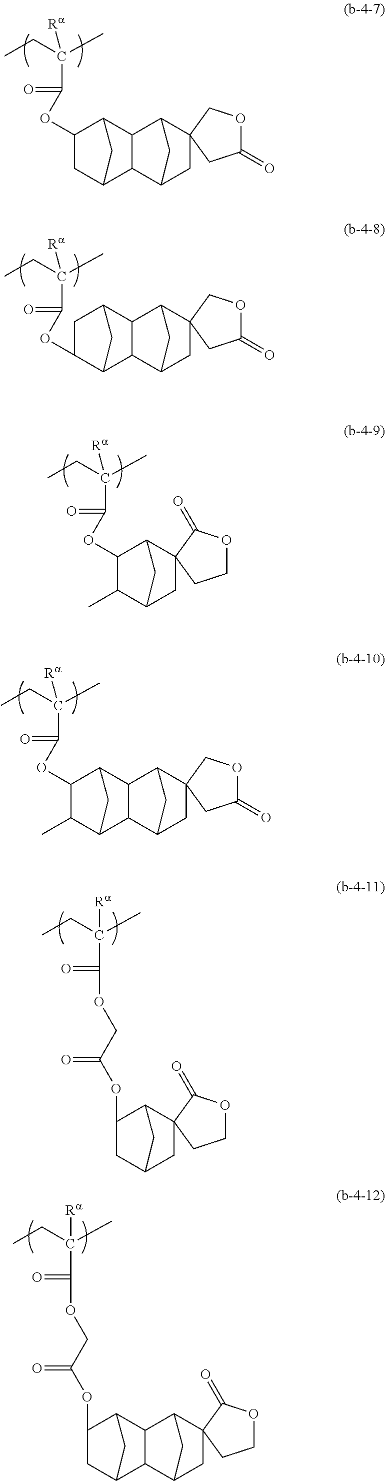

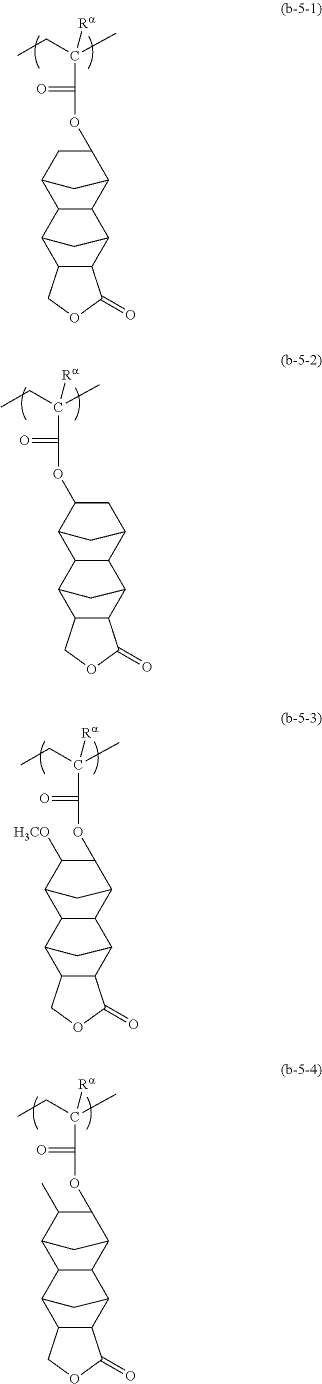

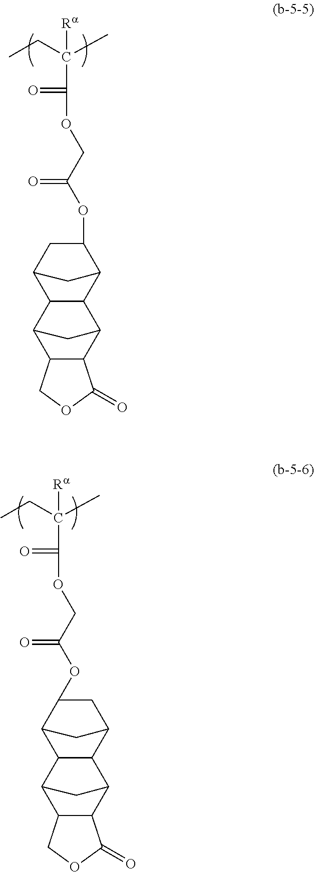

The repeating unit (b) is preferably at least one selected from the group consisting of the repeating units represented by Formulas (b-1) to (b-5), more preferably at least one selected from the group consisting of the repeating units represented by Formulas (b-1) to (b-3), and particularly preferably at least one selected from the group consisting of the repeating units represented by Formulas (b-1) and (b-2).

Among those, at least one selected from the group consisting of the repeating units represented by Formulas (b-1-1), (b-1-2), (b-2-1), (b-2-7), (b-2-12), (b-2-14), (b-3-1), and (b-3-5) are preferred.

The repeating unit (b) which may be contained in the resin (A) may be used either alone or in mixture of two or more thereof.

The resin (A) may or may not contain the repeating unit (b), but if contains, the content of the repeating unit (b) in the resin (A) is preferably 3 mol % to 30 mol %, more preferably 5 mol % to 25 mol %, and still more preferably 10 mol % to 20 mol % based on the sum of the entire repeating units constituting the resin (A). By setting the content to the lower limit or more, an effect by inclusion of the repeating unit (b) may be sufficiently obtained, and, by setting the content to the upper limit or less, it is possible to make a balance with other repeating units, so that lithography characteristics may be enhanced.

The resin (A) is preferably a copolymer having the repeating units (a1), (a0) and (a4).

The weight average molecular weight (Mw) of the resin (A) (in terms of polystyrene by a gel permeation chromatography (GPC)) is not particularly limited, but is preferably 1,000 to 50,000, more preferably 1,500 to 30,000, and still more preferably 2,000 to 25,000. If the weight average molecular weight is set to the upper limit or less in the range, the solubility in a resist solvent is sufficient for use as a resist, and the solubility in an organic developer is also excellent. Further, if the weight average molecular weight is set to the lower limit or more in the range, a dry etching resistance or a cross-sectional shape of a resist pattern is excellent.

Further, the polydispersity (Mw/Mn) of the resin (A) is not particularly limited, but is preferably 1.0 to 5.0, more preferably 1.0 to 3.0, and most preferably 1.0 to 2.5. Further, Mn denotes a number average molecular weight.

The resin (A) may be obtained by polymerizing monomers deriving each repeating unit, for example, by conventionally known radical polymerization using a radical polymerization initiator such as dimethyl-2,2-azobis(2-methylpropionate) or azobisisobutyronitrile.

The monomers deriving each repeating unit may be commercially available or prepared by a known method.

In the present invention, the resin (A) may be used either alone or in a mixture of two or more thereof.

The actinic ray-sensitive or radiation-sensitive resin composition of the present invention may contain a resin (A′) capable of decreasing the solubility in an organic developer by the action of an acid, which does not correspond to the resin (A), within a range which does not impair the effect of the present invention.

The resin (A′) is not particularly limited, and may be arbitrarily selected from many of those which have been conventionally known as those as a base resin for a chemical amplification positive type resist composition which has been conventionally used in a positive type development process using an alkali developer (for example, a base resin for ArF excimer laser or KrF excimer laser (preferably ArF excimer laser)). For example, the base resin for ArF excimer laser may be a resin which has the repeating unit (a1) as an essential repeating unit and optionally one or more among the repeating units (a2) to (a4). Further, as the resin (A′), a non-polymer (a low-molecular compound) having a molecular weight of 500 or more and less than 4,000 may be mixed thereto.

The resin (A′) may be used either alone or in a mixture of two or more thereof.

The content of the resin (A) in the actinic ray-sensitive or radiation-sensitive resin composition of the present invention may be adjusted depending on the resist film thickness to be formed.

<Compound (B) Capable of Generating an Acid upon Irradiation with an Actinic Ray or Radiation>

The compound (B) capable of generating an acid upon irradiation with an actinic ray or radiation (simply, also referred to as a compound (B) or an acid generator (B)) is not particularly limited, but any acid generator which has been suggested as an acid generator for chemical amplification resist may be used. As for such an acid generator, various kinds have been known, for example, an onium salt-based acid generator such as an iodonium salt or a sulfonium salt, an oxime sulfonate-based acid generator, a diazomethane-based acid generator such as bisalkyl- or bisarylsulfonyldiazomethanes, a nitrobenzylsulfonate-based acid generator, an iminosulfonate-based acid generator, and a disulfone-based acid generator.

As for the onium salt-based acid generator, for example, a compound represented by the following Formula (b-1) or (b-2) may be used.

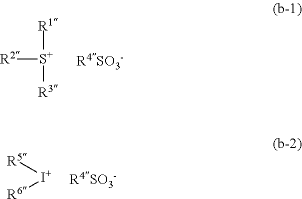

[In the formulas, each of R^{1″} to R^{3″}, R^{5″} to R^{6″} independently represents an aryl group or an alkyl group which may have a substitutent; any two of R^{1″} to R^{3″} in Formula (b-1) may be bonded to each other to form a ring together with the sulfur atom in the formula; R^{4″} represents an alkyl group, a halogenated alkyl group, an aryl group or an alkenyl group which may have a substitutent; at least one of R^{1″} to R^{3″} represents an aryl group, and at least one of R^{5″} to R^{6″} represents an aryl group.]

In Formula (b-1), each of R^{1″} to R^{3″} independently represents an aryl group or an alkyl group which may have a substitutent. Further, any two of R^{1″} to R^{3″} in Formula (b-1) may be bonded to each other to form a ring together with the sulfur atom in the formula.

Further, at least one of R^{1″} to R^{3″} represent an aryl group. It is preferred that two or more of R^{1″} to R^{3″} are an aryl group, and it is most preferred that all of R^{1″} to R^{3″} are an aryl group.

The aryl group of R^{1″} to R^{3″} is not particularly limited, and examples thereof may include an aryl group having 6 to 20 carbon atoms. The aryl group is preferably an aryl group having 6 to 10 carbon atoms because it may be synthesized at low costs. Specific examples thereof may include a phenyl group and a naphthyl group.

The aryl group may have a substituent. The expression “have a substituent” means that some or all of hydrogen atoms of the aryl group are substituted with substituents, and examples of the substituent may include an alkyl group, an alkoxy group, a halogen atom, a hydroxyl group, an alkoxyalkyloxy group, —O—R⁵⁰—C(═O)—(O)n-R⁵¹ [in the formula, R⁵⁰ is an alkylene group or a single bond, R⁵¹ is an acid-decomposable group or an acid-non-decomposable group, and n is 0 or 1].

The alkyl group with which a hydrogen atom of the aryl group may be substituted is preferably an alkyl group having 1 to 5 carbon atoms, and most preferably a methyl group, an ethyl group, a propyl group, a n-butyl group, and a tert-butyl group.

The alkoxy group with which a hydrogen atom of the aryl group may be substituted is preferably an alkoxy group having 1 to 5 carbon atoms, more preferably a methoxy group, an ethoxy group, a n-propoxy group, an iso-propoxy group, a n-butoxy group, and a tert-butoxy group, and most preferably a methoxy group and an ethoxy group.

The halogen atom with which a hydrogen atom of the aryl group may be substituted is preferably a fluorine atom.

The alkoxyalkyloxy group with which a hydrogen atom of the aryl group may be substituted is, for example, —O—C(R⁴⁷)(R⁴⁸)—O—R⁴⁹ [in the formula, each of R⁴⁷ and R⁴⁸ independently represents a hydrogen atom or a straight or branched alkyl group, R⁴⁹ is an alkyl group, and R⁴⁸ and R⁴⁹ may be bonded to each other to form one ring structure. However, at least one of R⁴⁷ and R⁴⁸ is a hydrogen atom].

In R⁴⁷ and R⁴⁸, the alkyl group preferably has 1 to 5 carbon atoms, and preferably an ethyl group and a methyl group, and most preferably a methyl group.

And, it is preferred that one of R⁴⁷ and R⁴⁸ is a hydrogen atom and the other is a hydrogen atom or a methyl group, and it is particularly preferred that both of R⁴⁷ and R⁴⁸ are a hydrogen atom.

The alkyl group of R⁴⁹ preferably has 1 to 15 carbon atoms, and may be straight, branched, or cyclic.

The straight or branched alkyl group in R⁴⁹ preferably has 1 to 5 carbon atoms, and examples thereof may include a methyl group, an ethyl group, a propyl group, a n-butyl group, and a tert-butyl group.

The cyclic alkyl group in R⁴⁹ has preferably 4 to 15 carbon atoms, more preferably 4 to 12 carbon atoms, and most preferably 5 to 10 carbon atoms. Specific examples thereof may include a group formed by subtracting one or more hydrogen atoms from monocycloalkane or polycycloalkane such as bicycloalkane, tricycloalkane, or tetracycloalkane which may or may not be substituted with an alkyl group having 1 to 5 carbon atoms, a fluorine atom or a fluorinated alkyl group. Examples of the monocycloalkane may include cyclopentane and cyclohexane. Examples of the polycycloalkane may include adamantane, norbornane, isobornane, tricyclodecane, and tetracyclododecane. Among those, a group formed by subtracting one or more hydrogen atoms from adamantine is preferred.

R⁴⁸ and R⁴⁹ may be bonded to each other to form one ring structure. In this case, a cyclic group is formed by R⁴⁸ and R⁴⁹, an oxygen atom to which R⁴⁹ is bonded, and a carbon atom to which the oxygen atom and R⁴⁸ are bonded. The cyclic group is preferably a 4- to 7-membered ring, and more preferably a 4- to 6-membered ring.

In —O—R⁵⁰—C(═O)—(O)n-R⁵¹ in which a hydrogen atom of the aryl group may be substituted, the alkylene group in R⁵⁰ is preferably a straight or branched alkylene group, and preferably has 1 to 5 carbon atoms. Examples of the alkylene group may include a methylene group, an ethylene group, a trimethylene group, a tetramethylene group, and a 1,1-dimethylethylene group.

The acid-decomposable group in R⁵ is not particularly limited as long as it is an organic group capable of dissociating by the action of an acid (an acid generated from the compound (B) during exposure), and examples thereof may include those as exemplified as the acid-decomposable group in the description of the repeating unit (a1). Among those, a tertiary alkyl ester is preferred.

Examples of the acid-non-decomposable group in R⁵¹ may include a straight alkyl group which may have a substituent, a branched alkyl group (excluding a tertiary alkyl group) which may have a substituent, and an acid-non-decomposable aliphatic cyclic group. Examples of the acid-non-decomposable aliphatic cyclic group may include those as exemplified in the description of the repeating unit (a4). Preferred examples of the acid-non-decomposable group may include a decyl group, a tricyclodecanyl group, an adamantyl group, a 1-(1-adamantyl)methyl group, a tetracyclododecanyl group, an isobornyl group, and a norbornyl group.

The alkyl group of R^{1″} to R^{3″} is not particularly limited, and examples thereof may include a straight, branched, or cyclic alkyl group having 1 to 10 carbon atoms. It is preferred to have 1 to 5 carbon atoms in that the resolution is excellent. Specific examples thereof may include a methyl group, an ethyl group, a n-propyl group, an isopropyl group, a n-butyl group, an isobutyl group, a n-pentyl group, a cyclopentyl group, a hexyl group, a cyclohexyl group, a nonyl group, and a decyl group, and preferred examples thereof may include a methyl group because the resolution is excellent and it may be synthesized at low costs.

The alkyl group may have a substituent. The expression “have a substituent” means that some or all of hydrogen atoms of the alkyl group are substituted with substituents, and examples of the substituent may include those as exemplified as a substituent which may be possessed by the aryl group.

Any two of R^{1″} to R^{3″} in Formula (b-1) may be bonded to each other to form a ring together with the sulfur atom in the formula. The ring may be saturated or unsaturated. Further, the ring may be monocyclic or polycyclic. For example, in a case where one or both of the two groups forming the ring are a cyclic group (a cyclic alkyl group or aryl group), when they are bonded, a polycyclic ring (condensed ring) is formed.

When two of R^{1″} to R^{3″} are bonded to form a ring, one ring containing the sulfur atom in the formula into the ring structure contains the sulfur atom to form preferably 3- to 10-membered ring, particularly preferably 5- to 7-membered ring.

Specific examples of the ring formed by two of R^{1″} to R^{3″} bonded to each other may include benzothiophene, dibenzothiophene, 9H-thioxanthene, thioxanthone, thianthrene, phenoxathiin, tetrahydrothiophenium, and tetrahydrothiopyranium.

When any two of R^{1″} to R^{3″} are bonded to each other to form a ring together with the sulfur atom in the formula, the remainder is preferably an aryl group.

For the cation moiety of the compound represented by Formula (b-1), specific examples of a case where all of R^{1″} to R^{3″} are a phenyl group which may have a substituent, that is, a case where the cation moiety has a triphenylsulfonium structure, may include cation moieties represented by the following Formulas (I-1-1) to (I-1-14).

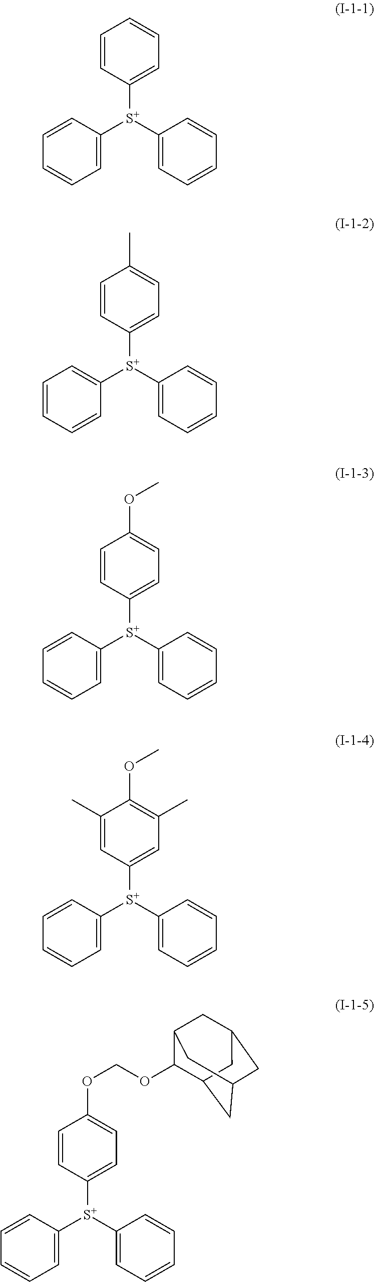 [SMILES: c1ccc([S+](c2ccccc2)c2ccccc2)cc1 ; Cc1ccc([S+](c2ccccc2)c2ccccc2)cc1 ; COc1ccc([S+](c2ccccc2)c2ccccc2)cc1 ; COc1c(C)cc([S+](c2ccccc2)c2ccccc2)cc1C ; c1ccc([S+](c2ccccc2)c2ccc(OCOC3C4CC5CC(C4)CC3C5)cc2)cc1]

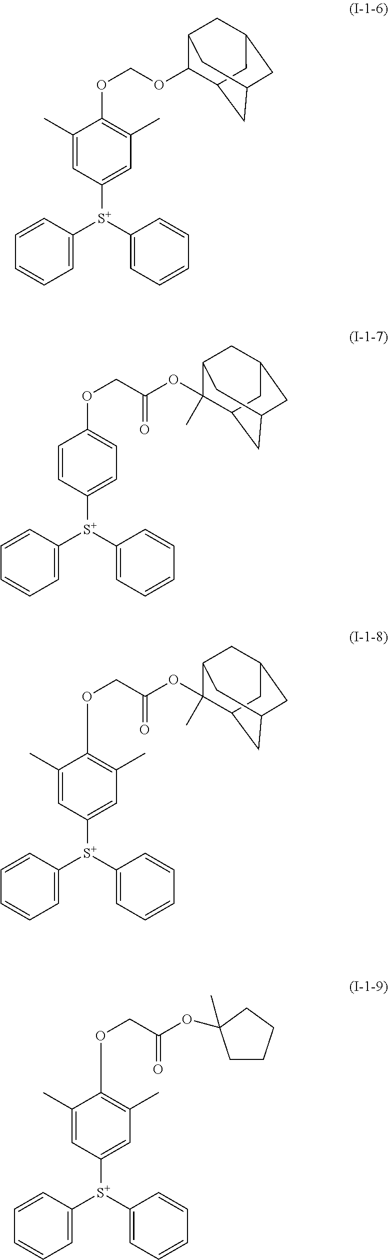 [SMILES: Cc1cc([S+](c2ccccc2)c2ccccc2)cc(C)c1OCOC1C2CC3CC(C2)CC1C3 ; CC1(OC(=O)COc2ccc([S+](c3ccccc3)c3ccccc3)cc2)C2CC3CC(C2)CC1C3 ; Cc1cc([S+](c2ccccc2)c2ccccc2)cc(C)c1OCC(=O)OC1(C)C2CC3CC(C2)CC1C3 ; Cc1cc([S+](c2ccccc2)c2ccccc2)cc(C)c1OCC(=O)OC1(C)CCCC1]

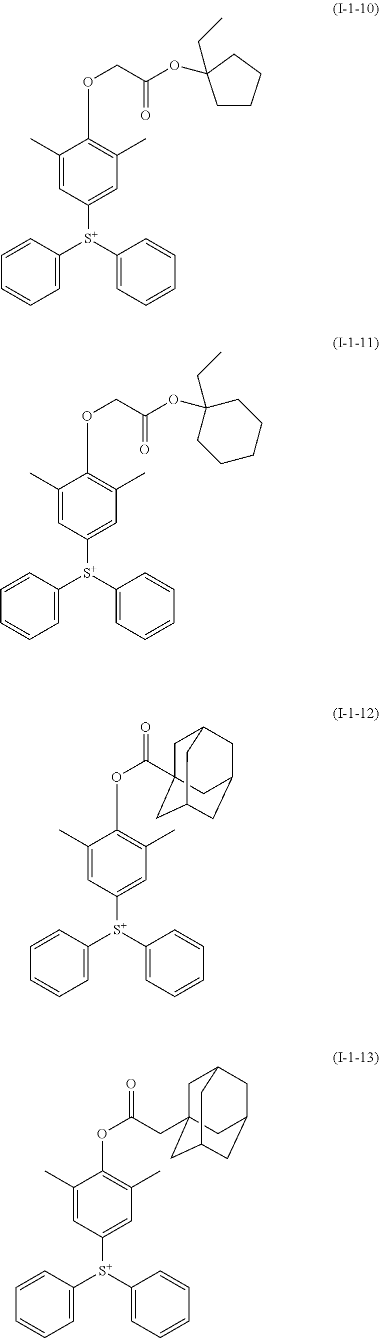 [SMILES: CCC1(OC(=O)COc2c(C)cc([S+](c3ccccc3)c3ccccc3)cc2C)CCCC1 ; CCC1(OC(=O)COc2c(C)cc([S+](c3ccccc3)c3ccccc3)cc2C)CCCCC1 ; Cc1cc([S+](c2ccccc2)c2ccccc2)cc(C)c1OC(=O)C12CC3CC(CC(C3)C1)C2 ; Cc1cc([S+](c2ccccc2)c2ccccc2)cc(C)c1OC(=O)CC12CC3CC(CC(C3)C1)C2]

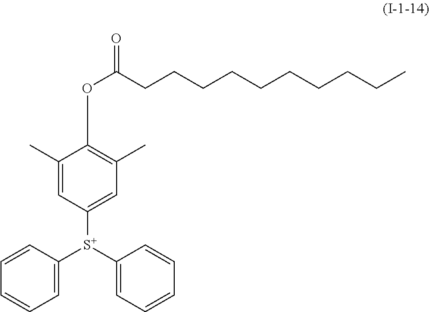 [SMILES: CCCCCCCCCCC(=O)Oc1c(C)cc([S+](c2ccccc2)c2ccccc2)cc1C]

Further, preferred examples thereof may include a moiety in which some or all of phenyl groups in the cation moiety are substituted with a naphthyl group which may have a substituent. Preferably, 1 or 2 of 3 phenyl groups are substituted with naphthyl groups.

Further, for the cation moiety of the compound represented by Formula (b-1), preferred specific examples of a case where any two of R^{1″} to R^{3″} are bonded to each other to form a ring together with the sulfur atom in the formula, may include cation moieties represented by the following Formulas (I-11-12) and (I-11-13).

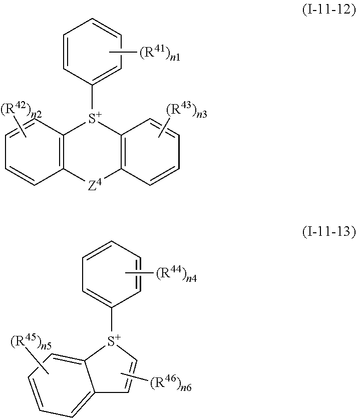

[In the formulas, Z⁴ is a single bond, a methylene group, a sulfur atom, an oxygen atom, a nitrogen atom, carbonyl group, —SO—, —SO₂—, —SO₃—, —COO—, —CONH— or —N(R^{N})— (R^{N} is an alkyl group having 1 to 5 carbon atoms); each of R⁴¹ to R⁴⁶ independently represents an alkyl group, an acetyl group, an alkoxy group, a carboxyl group, a hydroxyl group or a hydroxyalkyl group; each of n1 to n5 independently represents an integer of 0 to 3, n6 is an integer of 0 to 2.]

In Formulas (I-11-12) and (I-11-13), the alkyl group in R⁴¹ to R⁴⁶ is preferably an alkyl group having 1 to 5 carbon atoms, among those, more preferably a straight or branched alkyl group, and particularly preferably a methyl group, an ethyl group, a propyl group, an isopropyl group, a n-butyl group, or a tert-butyl group.

The alkoxy group is preferably an alkoxy group having 1 to 5 carbon atoms, among those, more preferably a straight or branched alkoxy group, and particularly preferably a methoxy group and an ethoxy group.

The hydroxyalkyl group is preferably a group in which one or more hydrogen atoms in the alkyl group are substituted with hydroxyl groups, and examples thereof may include a hydroxymethyl group, a hydroxyethyl group, and a hydroxypropyl group.

In a case where the symbols n1 to n6 denoted in R⁴¹ to R⁴⁶ are an integer of 2 or more, R⁴¹'s to R⁴⁶'s may be same or different.

n1 is preferably 0 to 2, more preferably 0 or 1, and still more preferably 0.

Each of n2 and n3 independently preferably represents 0 or 1, and more preferably 0.

n4 is preferably 0 to 2, and more preferably 0 or 1.

n5 is preferably 0 or 1, and more preferably 0.

n6 is preferably 0 or 1, and more preferably 1.

In Formulas (b-1) and (b-2), R^{4″} represents an alkyl group, a halogenated alkyl group, an aryl group, or an alkenyl group, which may have a substituent.

The alkyl group in R^{4″} may be straight, branched, or cyclic.

The straight or branched alkyl group has preferably 1 to 10 carbon atoms, more preferably 1 to 8 carbon atoms, and most preferably 1 to 4.

The cyclic alkyl group has preferably 4 to 15 carbon atoms, more preferably 4 to 10 carbon atoms, and most preferably 6 to 10 carbon atoms.

The halogenated alkyl group in R^{4″} may include a group in which some or all of hydrogen atoms of the straight, branched, or cyclic alkyl group are substituted with halogen atoms. Examples of the halogen atom may include a fluorine atom, a chlorine atom, a bromine atom, and an iodine atom, and preferably a fluorine atom.

In the halogenated alkyl group, the ratio of the number of the halogen atoms to the sum of the halogen atoms and the hydrogen atoms contained in the halogenated alkyl group (halogenation ratio (%)) is preferably 10% to 100%, more preferably 50% to 100%, and most preferably 100%. It is preferred that the strength of the acid increases, as the halogenation ratio increases.

The aryl group in R^{4″} is preferably an aryl group having 6 to 20 carbon atoms.

The alkenyl group in R^{4″} is preferably an alkenyl group having 2 to 10 carbon atoms.

In R^{4″}, the expression “may have a substituent” means that some or all of hydrogen atoms in the straight, branched, or cyclic alkyl group, a halogenated alkyl group, an aryl group, or an alkenyl group may be substituted with substituents (atoms or groups other than hydrogen atom).

The number of substituents in R^{4″} may be 1 or 2 or more.

Examples of the substituent may include a halogen atom, a heteroatom, an alkyl group, and a group represented by Formula: X-Q1- [in the formula, Q1 is a divalent linking group containing an oxygen atom, X is a hydrocarbon group having 3 to 30 carbon atoms, which may have a substituent].

Examples of the halogen atom and the alkyl group may include those as exemplified as the halogen atoms and the alkyl group for the halogenated alkyl group in R^{4″}.

Examples of the heteroatom may include an oxygen atom, a nitrogen atom, and a sulfur atom.

In a group represented by X-Q1-, Q1 is a divalent linking group containing an oxygen atom.

Q1 may contain an atom other than an oxygen atom. Examples of the atom other than an oxygen atom may include a carbon atom, a hydrogen atom, an oxygen atom, a sulfur atom, and a nitrogen atom.

Examples of the divalent linking group containing an oxygen atom may include a non-hydrocarbon-based oxygen atom-containing linking group such as an oxygen atom (ether bond; —O—), an ester bond (—C(═O)—O—), an amide bond (—C(═O)—NH—), a carbonyl group (—C(═O)—), and a carbonated bond (—O—C(═O)—O—); and a combination of the non-hydrocarbon-based oxygen atom-containing linking group and an alkylene group.

Examples of the combination may include —R⁹¹—O—, —R⁹²—O—C(═O)—, —C(═O)—O—R⁹³—, and —C(═O)—O—R⁹³—O—C(═O)— (in the formulas, each of R⁹¹ to R⁹³ independently represents an alkylene group).

The alkylene group in R⁹¹ to R⁹³ is preferably a straight or branched alkylene group, and the alkylene group has preferably 1 to 12 carbon atoms, more preferably 1 to 5 carbon atoms, and particularly preferably 1 to 3 carbon atoms.

Specific examples of the alkylene group may include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, —CH(CH₂CH₃)CH₂—, and —CH(CH₂CH₃)CH₂—; a trimethylene group (n-propylene group) [—CH₂CH₂CH₂—]; an alkyltrymethylene group such as —CH(CH₃)CH₂CH₂— and —CH₂CH(CH₃)CH₂—; a tetramethylene group [—CH₂CH₂CH₂CH₂—]; an alkyltetramethylene group such as —CH(CH₃)CH₂CH₂CH₂— and —CH₂CH(CH₃)CH₂CH₂—; and a pentamethylene group [—CH₂CH₂CH₂CH₂CH₂—].

Q1 is preferably a divalent linking group containing an ester bond or an ether bond, and among those, —R⁹¹—O—, —R⁹²—O—C(═O)—, —C(═O)—O—, —C(═O)—O—R⁹³— or C(═O)—O—R⁹³—O—C(═O)— is preferred.

In the group represented by X-Q1-, the hydrocarbon group of X may be an aromatic hydrocarbon group or an aliphatic hydrocarbon group.

The aromatic hydrocarbon group is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 12 carbon atoms. However, the number of carbon atoms does not include the number of carbon atoms of substituents.

Specific examples of the aromatic hydrocarbon group may include an aryl group formed by subtracting one hydrogen atom from an aromatic hydrocarbon ring such as a phenyl group, a biphenyl group, a fluorenyl group, a naphthyl group, an anthryl group, and a phenanthryl group; and an arylalkyl group such as a benzyl group, a phenethyl group, a 1-naphthylmethyl group, a 2-naphthylmethyl group, a 1-naphthylethyl group, and a 2-naphthylethyl group. The number of carbon atoms of the alkyl chain in the arylalkyl group is preferably 1 to 4, more preferably 1 to 2, and particularly 1.

The aromatic hydrocarbon group may have a substituent. For example, some of carbon atoms constituting the aromatic ring possessed by the aromatic hydrocarbon group may be substituted with a heteroatom, or a hydrogen atom bonded to the aromatic ring possessed by the aromatic hydrocarbon group may be substituted with a substituent.

Examples of the former may include a heteroaryl group in which some of carbon atoms constituting the ring of the aryl group is substituted with heteroatoms such as an oxygen atom, a sulfur atom, and a nitrogen atom, and a heteroarylalkyl group in which some of carbon atoms constituting the aromatic hydrocarbon ring of the arylalkyl group is substituted with the heteroatoms.

Examples of the substituent of the aromatic hydrocarbon group in the latter example may include an alkyl group, an alkoxy group, a halogen atom, a halogenated alkyl group, a hydroxyl group, and an oxygen atom (═O).

The alkyl group as a substituent of the aromatic hydrocarbon group is preferably an alkyl group having 1 to 5 carbon atoms, and most preferably a methyl group, an ethyl group, a propyl group, a n-butyl group, or a tert-butyl group.

The alkoxy group as a substituent of the aromatic hydrocarbon group is preferably an alkoxy group having 1 to 5 carbon atoms, more preferably a methoxy group, an ethoxy group, a n-propoxy group, an iso-propoxy group, a n-butoxy group, or a tert-butoxy group, and most preferably a methoxy group or an ethoxy group.

The halogen atom as a substituent of the aromatic hydrocarbon group may include a fluorine atom, a chlorine atom, a bromine atom, and an iodine atom, and preferably a fluorine atom.

The halogenated alkyl group as a substituent of the aromatic hydrocarbon group may include a group in which some or all of hydrogen atoms of the alkyl group are substituted with the halogen atoms.

The aliphatic hydrocarbon group in X may be a saturated aliphatic hydrocarbon group or an unsaturated aliphatic hydrocarbon group. Further, the aliphatic hydrocarbon group may be straight, branched, or cyclic.

In the aliphatic hydrocarbon group in X, some of carbon atoms constituting the aliphatic hydrocarbon group may be substituted with substituents containing a heteroatom, or some or all of hydrogen atoms constituting the aliphatic hydrocarbon group may be substituted with substituents containing a heteroatom.

The “heteroatom” in X is not particularly limited as long as it is an atom other than a carbon atom and a hydrogen atom, and examples thereof may include a halogen atom, an oxygen atom, a sulfur atom, and a nitrogen atom. Examples of the halogen atom may include a fluorine atom, a chlorine atom, an iodine atom, and a bromine atom.

The “substituent containing a heteroatom” (hereinafter, referred to as a heteroatom-containing substituent in some cases) may be constituted only with heteroatoms, or may be a group containing a group or atom other than the above-mentioned heteroatoms.

Examples of the heteroatom-containing substituent with which some of carbon atoms constituting the aliphatic hydrocarbon group may be substituted, may include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, and —S(═O)₂—O—. In a case of —NH—, the substituent (such as an alkyl group or an acyl group) with which the H may be substituted, has preferably 1 to 10 carbon atoms, more preferably 1 to 8 carbon atoms, and particularly preferably 1 to 5 carbon atoms.

When the aliphatic hydrocarbon group is cyclic, the substituent may be contained in the ring structure.

Examples of the heteroatom-containing substituent with which some or all of hydrogen atoms constituting the aliphatic hydrocarbon group may be substituted, may include a halogen atom, an alkoxy group, a hydroxyl group, —C(═O)—R₈₀ [R₈₀ is an alkyl group], —COOR₈₁ [R₈₁ is a hydrogen atom or an alkyl group], a halogenated alkyl group, a halogenated alkoxy group, an amino group, an amide group, a nitro group, an oxygen atom (═O), a sulfur atom, and a sulfonyl group (SO₂).

Examples of the halogen atom as the heteroatom-containing substituent may include a fluorine atom, a chlorine atom, a bromine atom, and an iodine atom, and is preferably a fluorine atom.

The alkyl group in the alkoxy group as the heteroatom-containing substituent may be straight, branched, or cyclic, in combination thereof. The number of carbon atoms is preferably 1 to 30. When the alkyl group is straight or branched, the number of carbon atoms is preferably 1 to 20, more preferably 1 to 17, still more preferably 1 to 15, and particularly preferably 1 to 10. Specific examples thereof may include the same as the specific examples of the straight or branched saturated hydrocarbon group to be exemplified later. When the alkyl group is cyclic (in a case of a cycloalkyl group), the number of carbon atoms is preferably 3 to 30, more preferably 3 to 20, still more preferably 3 to 15, particularly preferably 4 to 12, and most preferably 5 to 10. The alkyl group may be monocyclic or polycyclic. Specific examples thereof may include a group formed by subtracting one or more hydrogen atoms from monocycloalkane, and a group formed by subtracting one or more hydrogen atoms from polycycloalkane such as bicycloalkane, tricycloalkane, and tetracycloalkane. Specific examples of the monocycloalkane may include cyclopentane and cyclohexane. Further, specific examples of the polycycloalkane may include adamantane, norbornane, isobornane, tricyclodecane, and tetracyclododecane. In the cycloalkyl group, some or all of hydrogen atoms bonded to the ring may or may not be substituted with substituents such as a fluorine atom or a fluorinated alkyl group.

In —C(═O)—R₈₀ and —COOR⁸¹ as the heteroatom-containing substituent, examples of the alkyl group in R⁸⁰, R⁸¹ may include the same alkyl group as those exemplified as the alkyl group in the alkoxy group.

Examples of the alkyl group in the halogenated alkyl group as the heteroatom-containing substituent may include the same alkyl group as those exemplified as the alkyl group in the alkoxy group. The halogenated alkyl group is particularly preferably a fluorinated alkyl group.

Examples of the halogenated alkoxy group as the heteroatom-containing substituent may include a group in which some or all of hydrogen atoms of the alkoxy group are substituted with the halogen atom. The halogenated alkoxy group is preferably a fluorinated alkoxy group.

Examples of the hydroxyalkyl group as the heteroatom-containing substituent may include a group in which at least one hydrogen atom of the alkyl group exemplified as the alkyl group in the alkoxy group is substituted with a hydroxyl group. The number of hydroxyl groups possessed by the hydroxyalkyl group is preferably 1 to 3, and most preferably 1.

The aliphatic hydrocarbon group is preferably a straight or branched saturated hydrocarbon group, a straight or branched monovalent unsaturated hydrocarbon group, or a cyclic aliphatic hydrocarbon group (aliphatic cyclic group).

The straight saturated hydrocarbon group (alkyl group) has preferably 1 to 20 carbon atoms, more preferably 1 to 15 carbon atoms, and most preferably 1 to 10 carbon atoms. Specific examples thereof may include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an eicosyl group, a heneicosyl group, and a docodecyl group.

The branched saturated hydrocarbon group (alkyl group) has preferably 3 to 20 carbon atoms, more preferably 3 to 15 carbon atoms, and most preferably 3 to 10 carbon atoms. Specific examples thereof may include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

The unsaturated hydrocarbon group has preferably 2 to 10 carbon atoms, more preferably 2 to 5 carbon atoms, still more preferably 2 to 4 carbon atoms, and particularly preferably 3. Examples of the straight monovalent unsaturated hydrocarbon group may include a vinyl group, a propenyl group (allyl group), and a butynyl group. Examples of the branched monovalent unsaturated hydrocarbon group may include a 1-methylpropenyl group and a 2-methylpropenyl group. The unsaturated hydrocarbon group is particularly preferably a propenyl group.

The aliphatic cyclic group may be monocyclic or polycyclic. The number of carbon atoms is preferably 3 to 30, more preferably 5 to 30, still more preferably 5 to 20, particularly preferably 6 to 15, and most preferably 6 to 12.

Specific examples thereof may include a group formed by subtracting one or more hydrogen atoms from monocycloalkane; and a group formed by subtracting one or more hydrogen atoms from polycycloalkane such as bicycloalkane, tricycloalkane, or tetracycloalkane. More specific examples thereof may include a group formed by subtracting one or more hydrogen atoms from monocycloalkane such as cyclopentane or cyclohexane; and a group formed by subtracting one or more hydrogen atoms from polycycloalkane such as adamantane, norbornane, isobornane, tricyclodecane, or tetracyclododecane.

When the aliphatic cyclic group does not contain a substituent containing a heteroatom in its ring structure, the aliphatic cyclic group is preferably a polycyclic group, more preferably a group formed by subtracting one or more hydrogen atoms from polycycloalkane, and most preferably a group formed by subtracting one or more hydrogen atoms from adamantane.

When the aliphatic cyclic group contains a substituent containing a heteroatom in its ring structure, the substituent containing a heteroatom is preferably —O—, —C(═O)—O—, —S—, —S(═)₂—, or —S(═O)₂—O—. Specific examples of such an aliphatic cyclic group may include groups represented by the following Formulas (L1) to (L5), and (S1) to (S4).

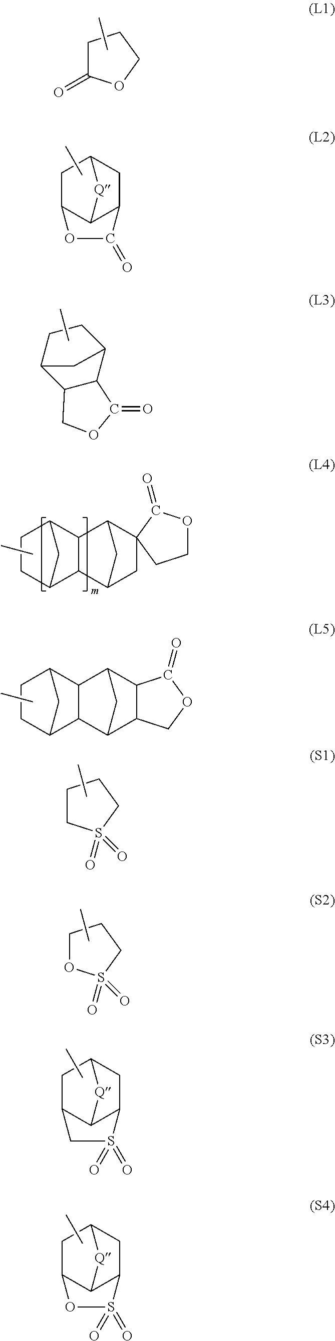

[In the formulas, Q″ is an alkylene group which may contain an oxygen atom or a sulfur atom, an oxygen atom, or a sulfur atom, and m is an integer of 0 or 1.]

In the formulas, the alkylene group in Q″ is preferably straight or branched, and the number of carbon atoms is preferably 1 to 5. Specific examples thereof may include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, and —CH(CH₂CH₃)CH₂—; a trimethylene group (n-propylene group) [—CH₂CH₂CH₂—]; an alkyltrymethylene group such as —CH(CH₃)CH₂CH₂— and —CH₂CH(CH₃)CH₂—; a tetramethylene group [—CH₂CH₂CH₂CH₂—]; an alkyltetramethylene group such as —CH(CH₃)CH₂CH₂CH₂— and —CH₂CH(CH₃)CH₂CH₂—; and a pentamethylene group [—CH₂CH₂CH₂CH₂CH₂—]. Among those, a methylene group or an alkylmethylene group is preferred, and a methylene group or —CH(CH₃)— or C(CH₃)₂— is particularly preferred.

The alkylene group may contain an oxygen atom (—O—) or a sulfur atom (—S—). Specific examples thereof may include a group intervened by —O— or —S— at an end of the alkylene group or between carbon atoms, for example, —O—R⁹⁴—, —S—R⁹⁵—, —R⁹⁶—OR⁹⁷—, and —R⁹⁸—S—R⁹⁹—. Here, each of R⁹⁴ to R⁹⁹ independently represents an alkylene group. Examples of the alkylene group may include the same alkylene group as those exemplified as the alkylene group in Q″. Among those, —O—CH₂—, —CH₂—O—CH₂—, —S—CH₂—, or —CH₂—S—CH₂— is preferred.

In the aliphatic cyclic group, some or all of the hydrogen atoms may be substituted with substituents. Examples of the substituent may include an alkyl group, a halogen atom, an alkoxy group, a hydroxyl group, —C(═O)—R⁸⁰ [R⁸⁰ is an alkyl group], —COOR⁸¹ [R⁸¹ is a hydrogen atom or an alkyl group], a halogenated alkyl group, a halogenated alkoxy group, an amino group, an amide group, a nitro group, an oxygen atom (═O), a sulfur atom, a sulfonyl group (SO₂).

Examples of the alkyl group as the substituent may include the same alkyl group as those exemplified as the alkyl group in the alkoxy group as the heteroatom-containing substituent.

The alkyl group is particularly preferably an alkyl group having 1 to 6 carbon atoms. Further, the alkyl group is preferably straight or branched, and specific examples thereof may include a methyl group, an ethyl group, a propyl group, an isopropyl group, a n-butyl group, an isobutyl group, a tert-butyl group, a pentyl group, an isopentyl group, a neopentyl group, and a hexyl group. Among those, a methyl group or ethyl group is preferred, and a methyl group is particularly preferred.

Examples of each of the halogen atom, the alkoxy group, —C(═O)—R⁸⁰, —COOR⁸¹, the halogenated alkyl group, and the halogenated alkoxy group as the substituent may include those as exemplified as the heteroatom-containing substituent with which some or all of the hydrogen atoms constituting the aliphatic hydrocarbon group may be substituted.

The substituent with which the hydrogen atom of the aliphatic cyclic group is substituted is preferably, among those, an alkyl group, an oxygen atom (═O), or a hydroxyl group.

The number of substituents possessed by the aliphatic cyclic group may be 1 or 2 or more. When a plurality of substituents is present, the substituents may be same or different.

X is preferably a cyclic group which may have a substituent. The cyclic group may be an aromatic hydrocarbon group which may have a substituent or an aliphatic cyclic group which may have a substituent, and is preferably an aliphatic cyclic group which may have a substituent.

The aromatic hydrocarbon group is preferably a naphthyl group which may have a substituent, or a phenyl group which may have a substituent.

The aliphatic cyclic group which may have a substituent is preferably a polycyclic aliphatic cyclic group which may have a substituent. The polycyclic aliphatic cyclic group is preferably a group formed by subtracting one or more hydrogen atoms from the polycycloalkane, or the groups represented by Formulas (L2) to (L5), and (S3) to (S4).

In Formula (b-2), each of R^{5″} and R^{6″} independently represents an aryl group or an alkyl group. At least one of R^{5″} and R^{6″} represents an aryl group. It is preferred that both of R^{5″} and R^{6″} are an aryl group.

Examples of the aryl group of R^{5″} and R^{6″} may include the same aryl group as that of R^{1″} to R^{3″}.

Examples of the alkyl group of R^{5″} and R^{6″} may include the same alkyl group as that of R^{1″} to R^{3″}.

Among those, it is most preferred that both of R^{5″} and R^{6″} are a phenyl group.

R^{4″} in Formula (b-2) may be the same as R^{4″} in Formula (b-1).

Specific examples of the onium salt-based acid generator represented by Formula (b-1) or (b-2) may include trifluoromethanesulfonate or nonafluorobutanesulfonate of diphenyliodonium; trifluoromethanesulfonate or nonafluorobutanesulfonate of bis(4-tert-butylphenyl)iodonium; trifluoromethanesulfonate of triphenylsulfonium, heptafluoropropanesulfonate thereof or nonafluorobutanesulfonate thereof; trifluoromethanesulfonate of tri(4-methylphenyl)sulfonium, heptafluoropropanesulfonate thereof or nonafluorobutanesulfonate thereof; trifluoromethanesulfonate of dimethyl(4-hydroxynaphthyl)sulfonium, heptafluoropropanesulfonate thereof or nonafluorobutanesulfonate thereof; trifluoromethanesulfonate of monophenyldimethylsulfonium, heptafluoropropanesulfonate thereof or nonafluorobutanesulfonate thereof; trifluoromethanesulfonate of diphenylmonomethylsulfonium, heptafluoropropanesulfonate thereof or nonafluorobutanesulfonate thereof; trifluoromethanesulfonate of (4-methylphenyl)diphenylsulfonium, heptafluoropropanesulfonate thereof or nonafluorobutanesulfonate thereof; trifluoromethanesulfonate of (4-methoxyphenyl)diphenylsulfonium, heptafluoropropanesulfonate thereof or nonafluorobutanesulfonate thereof; trifluoromethanesulfonate of tri(4-tert-butyl)phenylsulfonium, heptafluoropropanesulfonate thereof or nonafluorobutanesulfonate thereof; trifluoromethanesulfonate of diphenyl(1-(4-methoxy)naphthyl)sulfonium, heptafluoropropanesulfonate thereof or nonafluorobutanesulfonate thereof; trifluoromethanesulfonate of di(1-naphthyl)phenylsulfonium, heptafluoropropanesulfonate thereof or nonafluorobutanesulfonate thereof; trifluoromethanesulfonate of 1-phenyltetrahydrothiophenium, heptafluoropropanesulfonate thereof or nonafluorobutanesulfonate thereof; trifluoromethanesulfonate of 1-(4-methylphenyl)tetrahydrothiophenium, heptafluoropropanesulfonate thereof or nonafluorobutanesulfonate thereof; trifluoromethanesulfonate of 1-(3,5-dimethyl-4-hydroxyphenyl)tetrahydrothiophenium, heptafluoropropanesulfonate thereof or nonafluorobutanesulfonate thereof; trifluoromethanesulfonate of 1-(4-methoxynaphthalen-1-yl)tetrahydrothiophenium, heptafluoropropanesulfonate thereof or nonafluorobutanesulfonate thereof; trifluoromethanesulfonate of 1-(4-ethoxynaphthalen-1-yl)tetrahydrothiophenium, heptafluoropropanesulfonate thereof or nonafluorobutanesulfonate thereof; trifluoromethanesulfonate of 1-(4-n-butoxynaphthalen-1-yl)tetrahydrothiophenium, heptafluoropropanesulfonate thereof or nonafluorobutanesulfonate thereof; trifluoromethanesulfonate of 1-phenyltetrahydrothiopyranium, heptafluoropropanesulfonate thereof or nonafluorobutanesulfonate thereof; trifluoromethanesulfonate of 1-(4-hydroxyphenyl)tetrahydrothiopyranium, heptafluoropropanesulfonate thereof or nonafluorobutanesulfonate thereof; trifluoromethanesulfonate of 1-(3,5-dimethyl-4-hydroxyphenyl)tetrahydrothiopyranium, heptafluoropropanesulfonate thereof or nonafluorobutanesulfonate thereof; and trifluoromethanesulfonate of 1-(4-methylphenyl)tetrahydrothiopyranium, heptafluoropropanesulfonate thereof or nonafluorobutanesulfonate thereof.

Further, an onium salt in which the anion moiety of the onium salt is substituted with an alkylsulfonate such as methanesulfonate, n-propanesulfonate, n-butanesulfonate, n-octanesulfonate, 1-adamantanesulfonate, 2-norbornanesulfonate, d-camphor-10-sulfonate, benzenesulfonate, perfluorobenzenesulfonate, or p-toluenesulfonate, may be used.

Further, an onium salt in which the anion moiety of the onium salt is substituted with any one of anion moieties represented by the following Formulas (b1) to (b8), may also be used.

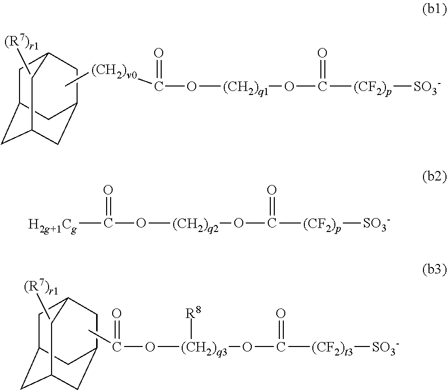

[In the formulas, p is an integer of 1 to 3, v0 is an integer of 0 to 3, each of q1 and q2 independently represents an integer of 1 to 5, q3 is an integer of 1 to 12, each of r1 to r2 independently represents an integer of 0 to 3, g is an integer of 1 to 20, t3 is an integer of 1 to 3, R⁷ is a substituent, and R⁸ is a hydrogen atom or an alkyl group.]

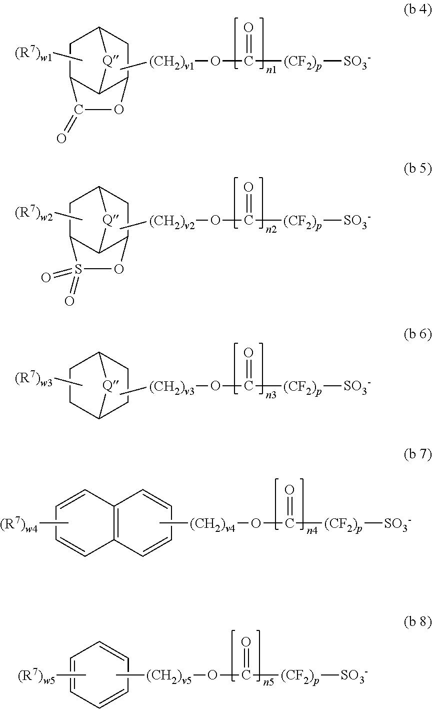

[In the formulas, p, R⁷, Q″ are the same as those described above, respectively, each of n1 to n5 independently represents 0 or 1, each of v1 to v5 independently represents an integer of 0 to 3, and each of w1 to w5 independently represents an integer of 0 to 3.]

Examples of the substituent of R⁷ may include an alkyl group and a heteroatom-containing substituent. Examples of the alkyl group may include the same alkyl group as exemplified as the substituent which may be possessed by the aromatic hydrocarbon group in the description of X. Further, examples of the heteroatom-containing substituent may include the same heteroatom-containing substituent as exemplified as the heteroatom-containing substituent with which some or all of the hydrogen atoms constituting the aliphatic hydrocarbon group may be substituted in the description of X.

In a case where the symbols (r1 to r2, and w1 to w5) denoted in R⁷ are an integer of 2 or more, R⁷'s in the compound may be same or different.

The alkyl group in R⁸ may have a substituent, and examples thereof may include the same alkyl group as that in R.

Each of r1 to r2, w1 to w5 is preferably an integer of 0 to 2, and more preferably 0 or 1.

v0 to v5 are preferably 0 to 2, and most preferably 0 or 1.

t3 is preferably 1 or 2, and most preferably 1.

q3 is preferably 1 to 5, more preferably 1 to 3, and most preferably 1.

Further, as the onium salt-based acid generator, an onium salt-based acid generator in which the anion moiety in Formula (b-1) or (b-2) is replaced with an anion moiety represented by the following Formula (b-3) or (b-4), may also be used (the cation moiety is the same as that of (b-1) or (b-2)).

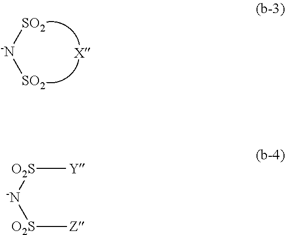

[In the formulas, X″ represents an alkylene group having 2 to 6 carbon atoms in which at least one hydrogen atom is substituted by a fluorine atom; each of Y″ and Z″ independently represents an alkyl group having 1 to 10 carbon atoms in which at least one hydrogen atom is substituted by a fluorine atom.]

X″ is hydrogen atom a straight or branched alkylene group in which at least one hydrogen atom is substituted by a fluorine atom, and the alkylene group has 2 to 6 carbon atoms, preferably 3 to 5 carbon atoms, and most preferably 3 carbon atoms.

Each of Y″ and Z″ independently represents a straight or branched alkyl group in which at least one hydrogen atom is substituted by a fluorine atom, and the alkyl group has 1 to 10 carbon atoms, preferably 1 to 7 carbon atoms, and more preferably 1 to 3 carbon atoms.

The number of carbon atoms of the alkylene group of X″, or the number of carbon atoms of the alkyl group of Y″ or Z″ is preferably as small as possible within the range of the number of carbon atoms for the reason that the solubility in a resist solvent is also excellent.

Further, in the alkylene group of X″ or the alkyl group of Y″ or Z″, the number of hydrogen atoms substituted with fluorine atoms is preferably as high as possible, because the strength of the acid becomes higher and the transparency with respect to a high energy light of 200 nm or less or electron beam is enhanced. The ratio of fluorine atoms in the alkylene group or the alkyl group, that is, the fluorination ratio is preferably 70% to 100%, more preferably 90% to 100%, and most preferably a perfluoroalkylene group or a perfluoroalkyl group in which all hydrogen atoms are substituted by fluorine atoms.

Further, in Formula (b-1) or (b-2), an onium salt-based acid generator in which the anion moiety (R^{4″}SO₃—) is substituted by R^{7″}—COO— [in the formula, R^{7″} is an alkyl group or a fluorinated alkyl group] may also be used (the cation moiety is the same as that of (b-1) or (b-2)).

R^{7″} may be the same as R^{4″}.

Specific examples of the ‘R^{7″}—COO—’ may include a trifluoroacetate ion, an acetate ion, and a 1-adamantanecarboxylate ion.

The compound (B) capable of generating an acid upon irradiation with an actinic ray or radiation is preferably a compound represented by the following Formula (b3′) or (b5′).

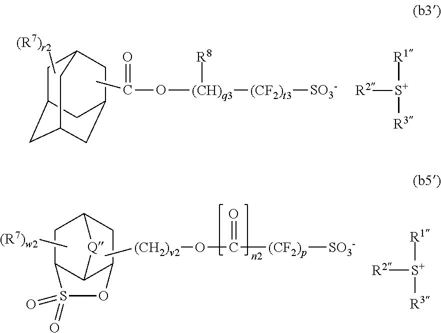

In Formulas (b3′) and (b5′), each of R^{1″} to R^{3″} independently represents an aryl group. Any two of R^{1″} to R^{3″} may be bonded to each other to form a ring together with the sulfur atom in the formula.

In Formula (b3′), q3 is an integer of 1 to 12, r2 is an integer of 0 to 3, t3 is an integer of 1 to 3, R⁷ is a substituent, and R⁸ is a hydrogen atom or an alkyl group.

In Formula (b5′), p is an integer of 1 to 3, R⁷ is a substituent, Q″ is an alkylene group which may contain an oxygen atom or a sulfur atom, an oxygen atom, or a sulfur atom, n2 is 0 or 1, v2 is an integer of 0 to 3, and w2 is an integer of 0 to 3.

The aryl group for R^{1″} to R^{3″} may have a substituent.

The alkyl group for R⁸ may have a substituent, and is preferably an alkyl group having 1 to 5 carbon atoms. Examples of the substituent may include a halogen atom.

As the compound (B) capable of generating an acid upon irradiation with an actinic ray or radiation, the acid generator may be used either alone or in combination of two or more thereof.

The content of the compound (B) capable of generating an acid upon irradiation with an actinic ray or radiation in the actinic ray-sensitive or radiation-sensitive resin composition is preferably 0.1 parts by mass to 30 parts by mass, more preferably 1 parts by mass to 25 parts by mass, and still more preferably 5 parts by mass to 20 parts by mass based on 100 parts by mass of the resin (A). By setting the content within the range, pattern formation is sufficiently performed. Further, it is preferred in that a uniform solution may be obtained and the storage stability becomes excellent.

<Hydrophobic Resin (F)>

Particularly when applied to liquid immersion exposure, the actinic ray-sensitive or radiation-sensitive resin composition imparts water repellency to a resist film and thus may have at least one of a fluorine atom and a silicon atom, and contain a hydrophobic resin (F) which is different from the resin (A). Accordingly, when the hydrophobic resin (F) is localized on the film top layer and the immersion medium is water, the static/dynamic contact angle of the resist film surface against water may be enhanced, thereby enhancing an immersion liquid follow-up property.

The fluorine atom and/or the silicon atom in hydrophobic resin (F) may be contained in the main chain of the resin, or may be contained in the side chain thereof.

When the hydrophobic resin (F) contains a fluorine atom, the hydrophobic resin (F) is preferably a resin having an alkyl group having a fluorine atom, a cycloalkyl group having a fluorine atom, or an aryl group having a fluorine atom as a partial structure having a fluorine atom.

The alkyl group (having preferably 1 to 10 carbon atoms, and more preferably 1 to 4 carbon atoms) having a fluorine atom is a straight chained or branched alkyl group in which at least one hydrogen atom is substituted by a fluorine atom, and may further have a substituent other than a fluorine atom.

The cycloalkyl group having a fluorine atom is a monocyclic or polycyclic cycloalkyl group in which at least one hydrogen atom is substituted by a fluorine atom, and may further have a substituent other than a fluorine atom.

The aryl group having a fluorine atom is an aryl group in which at least one hydrogen atom in an aryl group such as a phenyl group and a naphthyl group is substituted by a fluorine atom, and may further have a substituent other than a fluorine atom.

The hydrophobic resin (F) may further have at least one group selected from the following groups of (x) to (z).

(x) an acid group,

(y) a group having a lactone structure, an acid anhydride group, or an acid imide group,

(z) a group capable of decomposing by the action of an acid

Examples of the acid group (x) may include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group and the like.

Preferred examples of the acid group may include a fluorinated alcohol group (preferably, hexafluoroisopropanol), a sulfonimide group and a bis(alkylcarbonyl)methylene group.

The content of the repeating unit having the acid group (x) is preferably 1 mol % to 50 mol %, more preferably 3 mol % to 35 mol %, and still more preferably 5 mol % to 20 mol %, based on the entire repeating units in the hydrophobic resin (F).

As (y) the group having a lactone structure, the acid anhydride group or the acid imide group, a group having a lactone structure is particularly preferred.

Examples of the repeating unit containing these groups may include a repeating unit in which the group is directly bonded to the main chain of the resin, such as a repeating unit by an acrylic acid ester or a methacrylic acid ester. In addition, the repeating unit may be a repeating unit in which the group is bonded to the main chain of the resin through a linking group. Furthermore, the repeating unit may be introduced into the end of the resin by using a polymerization initiator or a chain transfer agent having the group at the time of polymerization.

The content of the repeating unit having a group having a lactone structure, an acid anhydride group or an acid imide group is preferably 1 mol % to 100 mol %, more preferably 3 mol % to 98 mol %, and still more preferably 5 mol % to 95 mol %, based on the entire repeating units in the hydrophobic resin (F).

Examples of the repeating unit having (z) a group capable of decomposing by the action of an acid in the hydrophobic resin (F) are the same as those of the repeating unit having an acid-decomposable group, which is exemplified in resin (A). The repeating unit having (z) a group capable of decomposing by the action of an acid may have at least one of a fluorine atom and a silicon atom. In the hydrophobic resin (F), the content of the repeating unit having (z) a group capable of decomposing by the action of an acid is preferably 1 mol % to 80 mol %, more preferably 10 mol % to 80 mol %, and still more preferably 20 mol % to 60 mol %, based on the entire repeating units in resin (F).

The weight average molecular weight of the hydrophobic resin (F) in terms of standard polystyrene is preferably 1,000 to 100,000, more preferably 1,000 to 50,000, and still more preferably 2,000 to 20,000.

Furthermore, the hydrophobic resin (F) may be used either alone or in combination of a plurality thereof.

The content of the hydrophobic resin (F) in the composition is preferably 0.01% by mass to 10% by mass, more preferably from 0.05% by mass to 8% by mass, and still more preferably from 0.1% by mass to 5% by mass, based on the total solid content in the composition.

Further, from the viewpoint of resolution, resist shape, side wall of resist pattern, and roughness, the molecular weight distribution (Mw/Mn, also referred to as polydispersity) is in a range of preferably 1 to 5, more preferably 1 to 3, and even more preferably 1 to 2.

Specific examples of the hydrophobic resin (F) may include the compounds (HR-1) to (HR-90) exemplified in [0314] to [0320] of Japanese Patent Laid-Open Publication No. 2011-197587, but not limited thereto.

<Basic Compound (D)>

In the present invention, the actinic ray-sensitive or radiation-sensitive resin composition may contain a basic compound (D) as an optional component.

The basic compound (D) is not particularly limited as long as it functions as an acid diffusion inhibitor, that is, a quencher which traps an acid generated from the compound (B) by exposure, and, since various compounds have already been suggested, any known compounds may be used.

As the basic compound (D), a low-molecular compound (non-polymer) is generally used. Examples of the basic compound (D) may include an amine such as an aliphatic amine and an aromatic amine, preferably an aliphatic amine, and particularly preferably a secondary aliphatic amine or a tertiary aliphatic amine. Here, the aliphatic amine refers to an amine having at least one aliphatic group, and the aliphatic group has preferably 1 to 20 carbon atoms.

Examples of the aliphatic amine may include amine (alkylamine or alkyl alcohol amine) or cyclic amine in which at least one hydrogen atom of ammonia NH₃ is substituted by an alkyl group or a hydroxyalkyl group having 20 or less carbon atoms.

Specific examples of the alkylamine and the alkyl alcohol amine may include monoalkylamine such as n-hexylamine, n-heptylamine, n-octylamine, n-nonylamine, and n-decylamine; dialkylamine such as diethylamine, di-n-propylamine, di-n-heptylamine, di-n-octylamine, and dicyclohexylamine; trialkylamine such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkyl alcohol amine such as diethanolamine, triethanolamine, diisopropanolamine, triisopropanolamine, di-n-octanolamine, tri-n-octanolamine, stearyl diethanolamine, and lauryl diethanolamine. Among those, trialkylamine and/or alkyl alcohol amine are preferred.

Example of the cyclic amine may include a heterocyclic compound containing a nitrogen atom as a heteroatom. The heterocyclic compound may be a monocyclic compound (aliphatic monocyclic amine) or a polycyclic compound (aliphatic polycyclic amine).

Specific examples of the aliphatic monocyclic amine may include piperidine and piperazine.

The aliphatic polycyclic amine has preferably 6 to 10 carbon atoms, and specific examples thereof may include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amine may include tris(2-methoxymethoxyethyl)amine, tris2-(2-methoxyethoxy)ethylamine, tris2-(2-methoxyethoxymethoxy)ethylamine, tris2-(1-methoxyethoxy)ethylamine, tris2-(1-ethoxyethoxy)ethylamine, tris2-(1-ethoxypropoxy)ethylamine, and tris[2-2-(2-hydroxyethoxy)ethoxyethylamine.

Examples of the aromatic amine may include aniline, N,N-dibutylaniline, pyridine, 4-dimethylaminopyridine, pyrrole, indole, pyrazole, imidazole or a derivative thereof, diphenylamine, triphenylamine, tribenzylamine, 2,6-diisopropylaniline, and 2,2′-dipyridyl, 4,4′-dipyridyl.

They may be used either alone or in combination of two or more thereof.

The basic compound (D) is generally used in a range of 0.01 parts by mass to 5.0 parts by mass based on 100 parts by mass of the resin (A). By setting within the range, resist pattern shape and post-exposure temporal stability are enhanced.

In the present invention, the actinic ray-sensitive or radiation-sensitive resin composition may contain at least one compound (E) (hereinafter, referred to as a component (E)) selected from the group consisting of organic carboxylic acid, and oxoacid of phosphorus and a derivative thereof, as an optional component, for the purpose of preventing sensitivity deterioration or enhancing resist pattern shape and post-exposure temporal stability.

Suitable examples of the organic carboxylic acid include acetic acid, malonic acid, citric acid, malic acid, succinic acid, benzoic acid, and salicylic acid.

Examples of the oxoacid of phosphorus may include phosphoric acid, phophonic acid, and phosphinic acid, and among those, phosphonic acid is particularly preferred.

Examples of the derivative of the oxoacid of phosphorus may include ester in which a hydrogen atom of the oxoacid is substituted by a hydrocarbon group, and examples of the hydrocarbon group may include an alkyl group having 1 to 5 carbon atoms, an aryl group having 6 to 15 carbon atoms.

Examples of the derivative of phosphoric acid may include phosphate ester such as di-n-butyl phosphate ester and diphenyl phosphate ester.

Examples of the derivative of phosphonic acid may include phosphonate ester such as dimethyl phosphonate ester, di-n-butyl phosphonate ester, phenyl phosphonate, diphenyl phosphonate ester, and dibenzyl phosphonate ester.

Examples of the derivative of phosphinic acid may include phosphinate ester such as phenyl phosphinate.

The component (E) may be used either alone or in combination of two or more thereof.

The component (E) is generally used in a range of 0.01 parts by mass to 5.0 parts by mass based on 100 parts by mass.

In the present invention, the actinic ray-sensitive or radiation-sensitive resin composition may further contain a miscible additive, for example, an additional resin for improving the performance of the resist film, a surfactant for enhancing coatability, a dissolution inhibitor, a plasticizer, a stabilizer, a coloring agent, an antihalation agent, and dye, as necessary.

When contained, the surfactant is preferably a fluorine-based and/or silicon-based surfactant.

Examples of the surfactant corresponding to these may include Megafac F176 and Megafac R08 manufactured by DIC Corporation, PF656 and PF6320 manufactured by OMNOVA Solutions Inc., Troysol S-366 manufactured by Troy Chemical Corporation, Fluorad FC430 manufactured by Sumitomo-3M Ltd., and Polysiloxane Polymer KP-341 manufactured by Shin-Etsu Chemical Co. Ltd.

Further, a surfactant other than the fluorine-based and/or silicon-based surfactant may be used. More specific examples thereof may include polyoxyethylene alkyl ethers and polyoxyethylene alkylaryl ethers.

Furthermore, any known surfactants may be suitably used. Examples of available surfactants may include surfactants described after [0273] of U.S. Patent Application Publication No. 2008/0248425A1.

The surfactant may be used either alone or in combination of two or more thereof.

The actinic ray-sensitive or radiation-sensitive resin composition of the present invention may or may not contain the surfactant, but when the composition contains the surfactant, the amount of surfactant used is preferably 0% by mass to 2% by mass, more preferably 0.0001% by mass to 2% by mass, and particularly preferably 0.0005% by mass to 1% by mass, based on the total amount of the actinic ray-sensitive or radiation-sensitive resin composition (total amount excluding the solvent).

Meanwhile, it is preferred that the amount of surfactant added is adjusted to 10 ppm or less, or no surfactant is contained. Accordingly, the surface localization of the hydrophobic resin is increased, and accordingly, the surface of the resist film may be made to be more hydrophobic, thereby enhancing the water follow-up property at the time of liquid immersion exposure.

The actinic ray-sensitive or radiation-sensitive resin composition of the present invention may be prepared by dissolving materials in an organic solvent (hereinafter, referred to as a component (S) in some cases).

The component (S) may be any component capable of dissolving each component to be used to obtain a uniform solution, and one or two or more kinds thereof may be suitably selected from conventionally known solvents for chemical amplification resist.

Examples thereof may include lactones such as γ-butyrolactone; ketones such as acetone, methyl ethyl ketone (MEK), cyclohexanone, methyl-n-penyl ketone, methyl isopentyl ketone, and 2-heptanone; polyhydric alcohols such as ethylene glycol, diethylene glycol, propylene glycol, and dipropylene glycol; derivatives of polyhydric alcohols of a compound having an ester bond such as ethylene glycol monoacetate, diethylene glycol monoacetate, propylene glycol monoacetate, or dipropylene glycol monoacetate, and a compound having an ether bond such as monophenyl ether or monoalkyl ether such as monomethyl ether, monoethyl ether, monopropyl ether, and monobutyl ether of a compound having the polyhydric alcohols or the ester bond [among those, propylene glycol monomethyl ether acetate (PGMEA) and propylene glycol monomethyl ether (PGME) are preferred]; cyclic ethers such as dioxane, or esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, and mesitylene; and dimethyl sulfoxide (DMSO).

These organic solvents may be used either alone or as a mixed solvent of two or more thereof.

Among those, PGMEA, PGME, γ-butyrolactone, cyclohexanone, and EL are preferred.

Further, a mixed solvent obtained by mixing PGMEA and a polar solvent is also preferred. The mixing ratio (mass ratio) may be determined properly in consideration of compatibility of PGMEA with the polar solvent, but is preferably in a range of 1:9 to 9:1, and more preferably 2:8 to 8:2.

More specifically, when EL is mixed as the polar solvent, a mass ratio of PGMEA:EL is preferably 1:9 to 9:1, and more preferably 2:8 to 8:2. Further, when PGME is mixed as the polar solvent, a mass ratio of PGMEA:PGME is preferably 1:9 to 9:1, more preferably 2:8 to 8:2, and still more preferably 3:7 to 7:3. Further, when PGME and cyclohexanone are mixed as the polar solvent, a mass ratio of PGMEA:(PGME+cyclohexanone) is preferably 1:9 to 9:1, more preferably 2:8 to 8:2, and still more preferably 3:7 to 7:3.

Further, as the component (S), in addition, a mixed solvent of at least one selected from PGMEA and EL, and γ-butyrolactone is also preferred. In this case, as a mixing ratio, the mass ratio of the former and the latter is preferably 70:30 to 95:5.

An amount of the component (S) used is not particularly limited, but may be suitably set to be in a concentration coatable to a substrate, depending on the thickness of the coating film. Generally, it is used such that the solid concentration of the actinic ray-sensitive or radiation-sensitive resin composition is within a range of 1% by mass to 20% by mass, and preferably 2% by mass to 15% by mass.

Further, the present invention also relates to a method of manufacturing an electronic device, including the aforementioned pattern forming method of the present invention, and an electronic device manufactured by this manufacturing method.

The electronic device of the present invention is suitably mounted on electric electronic devices (such as home appliances, OA media-related devices, optical devices and communication devices).

### EXAMPLES

Hereinafter, the present invention will be described in detail with reference to the Examples, but the present invention is not limited thereby.

<Acid-Decomposable Resin>

### Synthesis Example

### Synthesis of Resin A-1

Into a three-necked flask, 25.5 g of cyclohexanone was introduced and heated to 85° C. under nitrogen flow. To this, a solution obtained by dissolving 2.00 g, 5.13 g and 1.30 g of the following compounds (monomers) (in order from the left) and a polymerization initiator V-601 (manufactured by Wako Pure Chemical Industries, Ltd., 0.743 g) in 46 g of cyclohexanone was added dropwise over 6 hours. After the completion of the dropwise addition, the solution was further subjected to reaction 85° C. for 2 hours. The reaction solution was left to cool, then added dropwise to a mixed solution of 420 g of hexane and 180 g of ethyl acetate over 20 minutes, and filtered to obtain a precipitated powder, which was dried to obtain 8.0 g of the resin A-1. The polymer composition ratio (molar ratio) measured by ¹³C-NMR was 15/70/15. The weight average molecular weight (Mw) of the obtained resin A-1 was 7,900 in terms of standard polystyrene, and the polydispersity (Mw/Mn) thereof was 1.70.

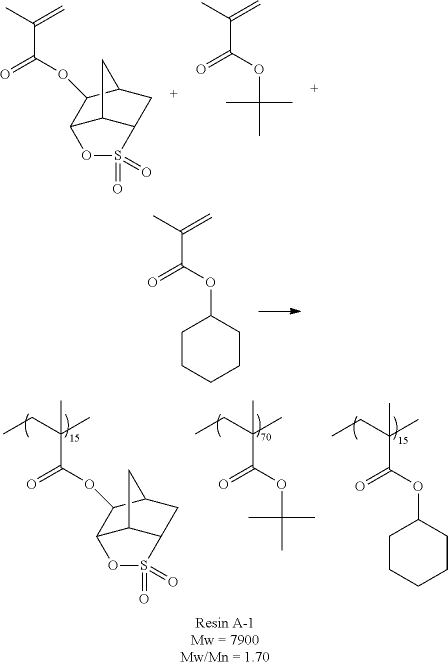

Resins A-2 to A-23 and comparative resins A′-1 and A′-2 were synthesized in the same manner as in Synthesis Example.

For the resins A-1 to A-23 and the comparative resins A′-1 and A′-2, a composition ratio (molar ratio) of each repeating unit, an molar average value of C log P values of the respective monomers corresponding to the respective repeating units except for the repeating unit (a0), a weight average molecular weight (Mw), and a polydispersity are shown in the following table. Further, the composition ratio (molar ratio) of each repeating unit, the weight average molecular weight (Mw) and the dispersity were calculated in the same manner as in the resin A-1.

For each resin, the molar average value of C log P values of the respective monomers corresponding to the respective repeating units except for the repeating unit (a0) was calculated as described above.

The C log P values of the monomers corresponding to the respective repeating units were calculated by ChemBioDraw 12.0.

TABLE 1

| | Unit | Molar | Unit | Molar | Unit | Molar | Unit | Molar |
|---|---|---|---|---|---|---|---|---|
| | (a0) | ratio (%) | (a0) | ratio (%) | (a1) | ratio (%) | (a1) | ratio (%) |
| Resin | | | | | | | | |
| A-1 | a0-3 | 15 | — | — | a1-1 | 70 | — | — |
| A-2 | a0-4 | 15 | — | — | a1-2 | 65 | — | — |
| A-3 | a0-5 | 10 | — | — | a1-3 | 65 | — | — |
| A-4 | a0-6 | 5 | — | — | a1-4 | 75 | — | — |
| A-5 | a0-3 | 15 | — | — | a1-5 | 65 | — | — |
| A-6 | a0-4 | 15 | — | — | a1-1 | 55 | — | — |
| A-7 | a0-5 | 10 | a0-3 | 5 | a1-7 | 50 | — | — |
| A-8 | a0-6 | 15 | — | — | a1-8 | 65 | — | — |
| A-9 | a0-3 | 15 | — | — | a1-9 | 20 | a1-5 | 45 |
| A-10 | a0-4 | 10 | a0-2 | 10 | a1-10 | 60 | — | — |
| A-11 | a0-5 | 10 | — | — | a1-11 | 65 | — | — |
| A-12 | a0-6 | 15 | — | — | a1-1 | 60 | a1-11 | 10 |
| A-13 | a0-3 | 5 | — | — | a1-2 | 65 | — | — |
| A-14 | a0-4 | 15 | — | — | a1-3 | 65 | — | — |
| A-15 | a0-5 | 15 | — | — | a1-4 | 65 | — | — |
| A-16 | a0-6 | 3 | — | — | a1-5 | 65 | — | — |
| A-17 | a0-3 | 20 | — | — | a1-6 | 65 | — | — |
| A-18 | a0-2 | 15 | — | — | a1-7 | 70 | — | — |
| A-19 | a0-1 | 15 | — | — | a1-8 | 65 | — | — |
| A-20 | a0-1 | 10 | — | — | a1-9 | 60 | — | — |
| A-21 | a0-1 | 15 | — | — | a1-10 | 65 | — | — |
| A-22 | a0-1 | 25 | — | — | a1-11 | 65 | — | — |
| A-23 | a0-1 | 35 | — | — | a1-6 | 55 | — | — |
| Comp. | | | | | | | | |
| Resin | | | | | | | | |
| A′-1 | a0-4 | 40 | — | — | a1-1 | 50 | — | — |
| A′-2 | a0-5 | 25 | — | — | a1-4 | 43 | — | — |

| | | | | | molar average of ClogP | | |
|---|---|---|---|---|---|---|---|
| | Unit | Molar | Unit | Molar | values of monomers of | | |
| | (a2) | ratio (%) | (b) | ratio (%) | units except for unit (a0) | Mw | Polydispersity |
| Resin | | | | | | | |
| A-1 | a2-1 | 15 | — | — | 2.48 | 7,900 | 1.70 |
| A-2 | a2-2 | 20 | — | — | 3.20 | 12,300 | 1.66 |
| A-3 | a2-3 | 25 | — | — | 3.41 | 15,000 | 1.73 |
| A-4 | a2-4 | 20 | — | — | 3.52 | 9,200 | 1.80 |
| A-5 | a2-5 | 20 | — | — | 3.58 | 11,000 | 1.69 |
| A-6 | a2-1 | 15 | a3-2 | 15 | 2.15 | 12,200 | 1.82 |
| A-7 | a2-2 | 35 | — | — | 4.23 | 9,700 | 1.75 |
| A-8 | a2-3 | 20 | — | — | 4.16 | 11,050 | 1.76 |
| A-9 | a2-4 | 20 | — | — | 4.26 | 8,000 | 1.60 |
| A-10 | a2-5 | 20 | — | — | 4.76 | 8,350 | 1.88 |
| A-11 | a2-1 | 25 | — | — | 5.30 | 9,200 | 1.90 |
| A-12 | a2-2 | 15 | — | — | 3.13 | 10,500 | 1.79 |
| A-13 | a2-3 | 20 | a3-2 | 10 | 2.81 | 18,200 | 1.82 |
| A-14 | a2-4 | 20 | — | — | 3.71 | 21,000 | 1.71 |
| A-15 | a2-5 | 20 | — | — | 3.17 | 6,300 | 1.88 |
| A-16 | a2-1 | 32 | — | — | 3.46 | 7,900 | 1.69 |
| A-17 | a2-2 | 15 | — | — | 3.77 | 10,050 | 1.75 |
| A-18 | a2-3 | 15 | — | — | 4.11 | 11,100 | 1.78 |
| A-19 | a2-4 | 20 | — | — | 4.48 | 20,000 | 1.81 |
| A-20 | a2-6 | 30 | — | — | 3.94 | 16,200 | 1.85 |
| A-21 | — | | a3-1 | 20 | 4.13 | 14,000 | 1.72 |
| A-22 | — | | a3-2 | 10 | 5.38 | 9,100 | 1.77 |
| A-23 | — | | a3-3 | 10 | 3.10 | 10,300 | 1.88 |
| Comp. | | | | | | | |
| Resin | | | | | | | |
| A′-1 | — | — | a3-3 | 10 | 1.96 | 9,600 | 1.71 |
| A′-2 | — | — | a3-2 | 32 | 1.97 | 10,700 | 1.90 |

The monomers corresponding to the structures of the respective repeating units with respect to the abbreviations in the table and the C log P values thereof are as follows.

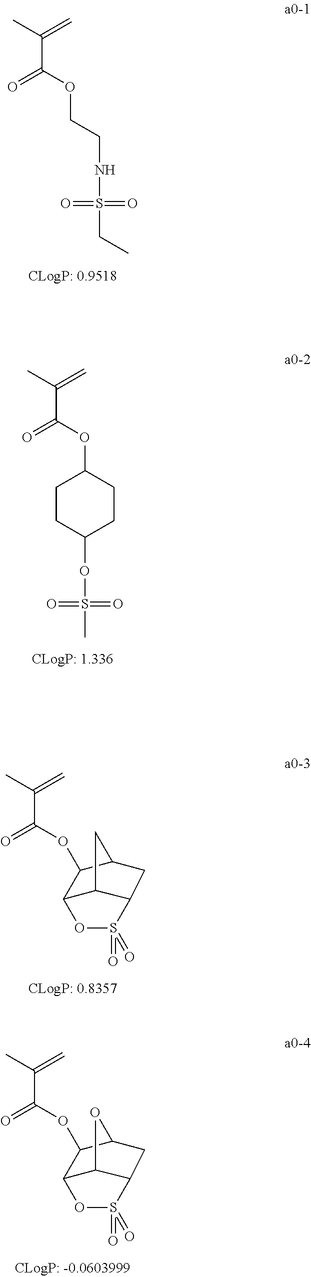

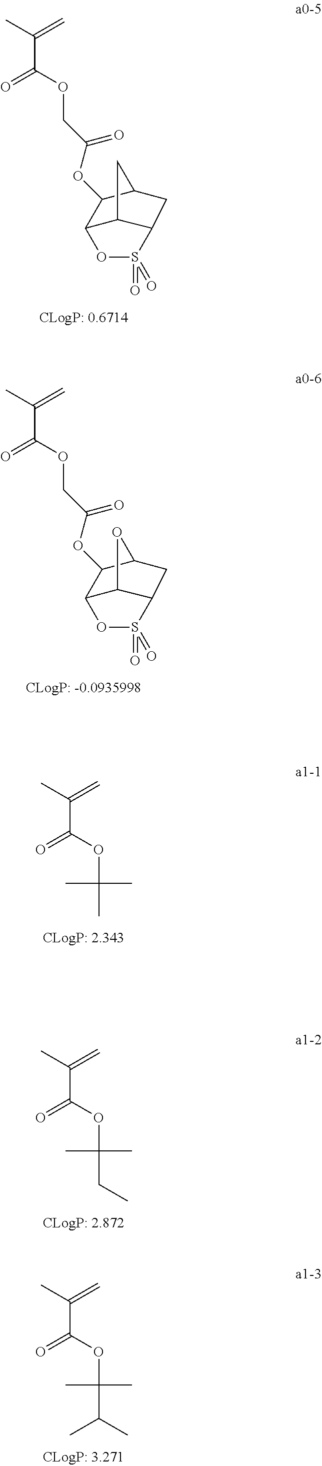

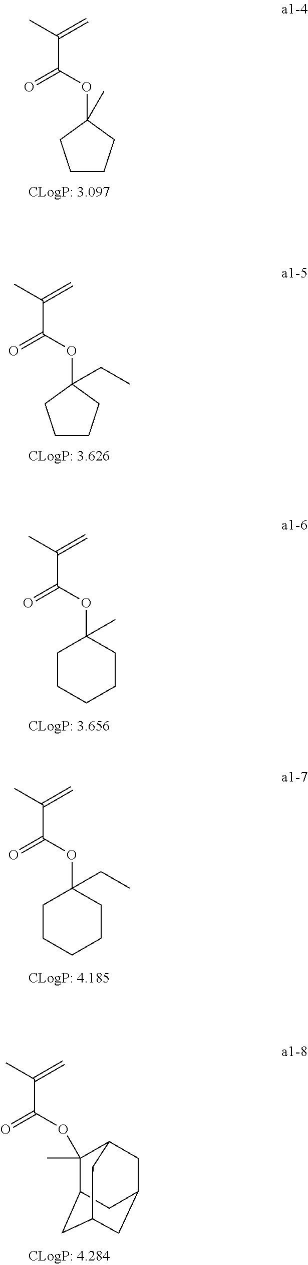

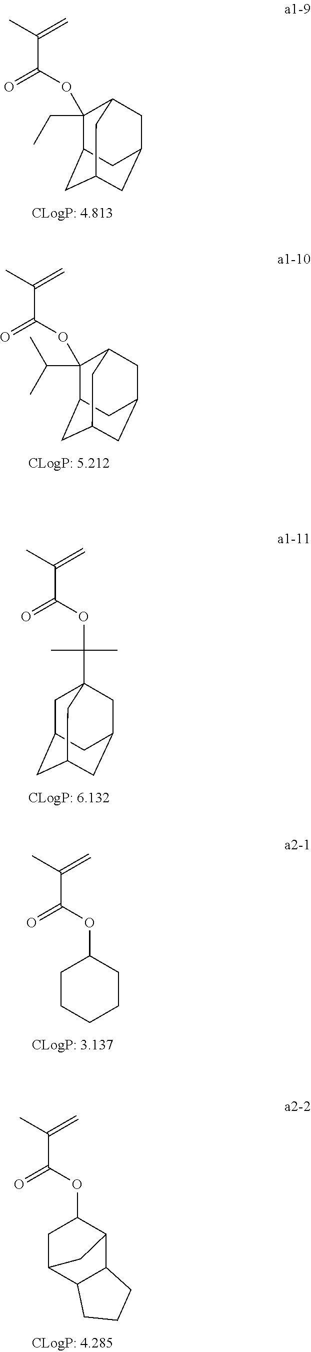

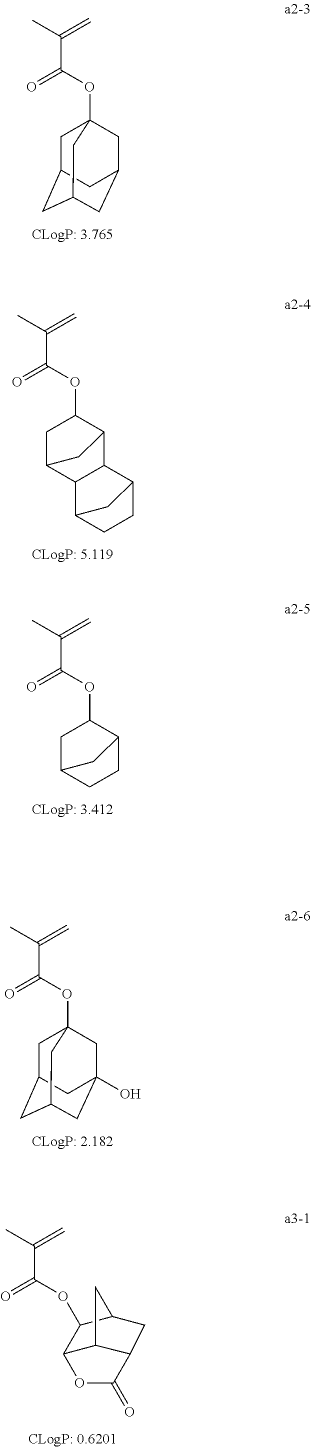

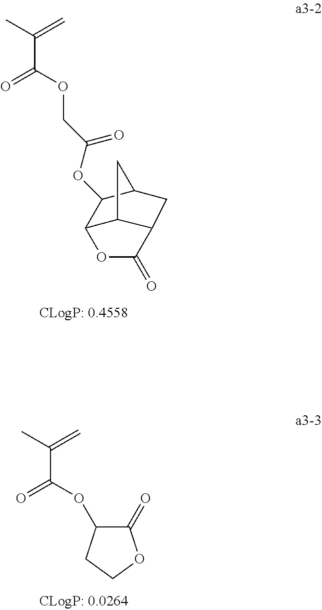

### Examples 1 to 38 and Comparative Examples 1 to 4

<Preparation of Resist>

Each component listed in Tables 2 and 3 below was dissolved in a solvent to prepare a solution having a solid content of 4% by mass for each, which was filtered through a polyethylene filter having a pore size of 0.05 μm to prepare an actinic ray-sensitive or radiation-sensitive resin composition. The actinic ray-sensitive or radiation-sensitive resin composition was evaluated by the following method, and the results were shown in Tables 2 and 3.

<Evaluation of Resist>

(Exposure Condition (1): ArF Liquid Immersion Exposure)

An organic antireflective film ARC29SR (manufactured by Nissan Chemical Industries, Ltd.) was applied on a silicon wafer and baked at 205° C. for 60 seconds to form an antireflection film having a film thickness of 98 nm. The actinic ray-sensitive or radiation-sensitive resin composition thus prepared was applied thereon and baked at 130° C. over 60 seconds to form a resist film having a film thickness of 120 nm. The wafer was subjected to exposure by using an ArF excimer laser liquid immersion scanner (manufactured by ASML Co., Ltd.; XT1700i, NA 1.20, C-Quad, outer sigma 0.981, inner sigma 0.895, XY deflection) through a halftone mask having a square arrangement in which a hole portion was 45 nm and a pitch between holes was 75 nm. As the liquid for liquid immersion, ultrapure water was used. Thereafter, heating (PEB: Post Exposure Bake) was performed at 105° C. for 60 seconds. Subsequently, the wafer was developed by puddling with butyl acetate for 30 seconds, and spin-dried to obtain a hole pattern having a hole diameter of 45 nm.

(Exposure Condition (2): ArF Dry Exposure)

An organic antireflective film ARC29SR (manufactured by Nissan Chemical Industries, Ltd.) was applied on a silicon wafer and baked at 205° C. for 60 seconds to form an antireflection film having a film thickness of 78 nm. The actinic ray-sensitive or radiation-sensitive resin composition thus prepared was applied thereon and baked at 130° C. over 60 seconds to form a resist film having a film thickness of 120 nm. The wafer was subjected to exposure by using an ArF excimer laser liquid immersion scanner (manufactured by ASML Co., Ltd.; PAS5500/1100, NA 0.75, Dipole, σo/σi=0.89/0.65) through a halftone mask having a square arrangement in which a hole portion was 75 nm and a pitch between holes was 90 nm. Thereafter, heating was performed at 100° C. for 60 seconds, and then, the wafer was developed by puddling with butyl acetate for 30 seconds, and spin-dried to obtain a hole pattern having a hole diameter of 75 nm.

(Evaluation of CDU)

[Uniformity of Local Pattern Dimension (Local CDU, nm)]

A hole size was observed by a critical dimension scanning electron microscope (SEM) (manufactured by Hitachi, Ltd., S-9380 II), and an optimal exposure amount (Eₒₚₜ)(mJ/cm²) at the time of resolving the hole pattern having a hole portion of 45 nm on average under the exposure condition (1) and an optimal exposure amount (Eₒₚₜ)(mJ/cm²) at the time of resolving the hole pattern having a hole portion of 75 nm on average under the exposure condition (2) were calculated. Within one shot exposed as the optimal exposure amount, in twenty sites having an interval of 1 μm therebetween, hole sizes at arbitrary 25 points in each site (that is, 500 points in total) were measured and a standard deviation thereof was obtained to calculate 3σ. The smaller the value was, the smaller the variation in dimension was, indicating that the performance was good.

(Evaluation of Circularity)

[(Circularity, nm)]

Within one shot exposed as the optimal exposure amount, in twenty sites having an interval of 1 μm therebetween, hole sizes at arbitrary 25 points in each site (that is, 500 points in total) were measured in a perfect circle approximation mode and a radius of the hole pattern was measured at 32 points per hole. A deviation (3σ) between the hole radius obtained from the measurement and the hole radius obtained by the perfect circle approximation was calculated, and an average value thereof was determined to calculate a circularity. The smaller the value was, the closer to a perfect circle the wafer was, indicating that the performance was good.

TABLE 2

| | Resin (A) | Acid | | Hydrophoic | | Basic | |
|---|---|---|---|---|---|---|---|
| Ex. | (10 g) | generator (B) | (g) | resin (F) | (g) | compound (D) | (g) |
| 1 | A-1 | B-3 | 1.0 | F-1 | 0.5 | DIA | 0.010 |
| 2 | A-2 | B-4/B-6 | 0.9/0.2 | F-2 | 0.2 | TEA | 0.010 |
| 3 | A-3 | B-1 | 0.8 | F-3 | 0.5 | DBA | 0.010 |
| 4 | A-4 | B-3 | 1.0 | F-4 | 0.3 | PBI | 0.015 |
| 5 | A-5 | B-2/B-1 | 1.0/0.2 | F-5 | 0.5 | PEA | 0.010 |
| 6 | A-6 | B-3 | 0.6 | F-1 | 0.2 | TPA | 0.010 |
| 7 | A-7 | B-1 | 0.7 | F-1 | 0.5 | DBA | 0.010 |
| 8 | A-8 | B-1 | 0.8 | F-2 | 0.4 | PBI | 0.015 |
| 9 | A-9/A-2(5 g/5 g) | B-1/B-3 | 1.0/0.1 | F-3 | 0.4 | PEA/TPA | 0.01/0.01 |
| 10 | A-10 | B-3 | 1.0 | F-4 | 0.5 | PBI | 0.015 |
| 11 | A-11 | B-2/B-5 | 1.1/0.2 | F-5 | 0.3 | TPA | 0.010 |
| 12 | A-12 | B-1/B-7 | 1.0/0.1 | F-3 | 0.1 | TPA | 0.015 |
| 13 | A-13 | B-1/B-6 | 0.9/0.1 | F-4 | 0.2 | TPA | 0.010 |
| 14 | A-14 | B-1/B-6 | 0.8/0.3 | F-5 | 0.5 | TPA | 0.015 |
| 15 | A-15/A-1(2 g/8 g) | B-1/B-6 | 0.7/0.2 | F-1 | 0.5 | TPA | 0.015 |
| 16 | A-16 | B-3 | 0.8 | F-1 | 0.5 | DBA | 0.010 |
| 17 | A-17 | B-4 | 1.1 | F-2 | 0.1 | PBI | 0.015 |
| 18 | A-17 | B-5 | 0.8 | F-1 | 0.2 | TPA | 0.015 |
| 19 | A-18 | B-7 | 0.9 | F-2 | 0.5 | PEA/TPA | 0.01/0.01 |
| 20 | A-19 | B-7 | 1.1 | F-2 | 0.5 | TPA | 0.015 |
| 21 | A-20 | B-8/B-5 | 0.7/0.2 | F-5 | 0.5 | TPA | 0.015 |
| 22 | A-21 | B-8 | 0.5 | F-3 | 0.4 | DBA | 0.010 |
| 23 | A-22 | B-5 | 0.9 | F-1 | 0.4 | PBI | 0.015 |
| 24 | A-23 | B-5 | 1.2 | F-2 | 0.5 | TPA | 0.010 |
| Comp. | Comparative | Acid | | Hydrophoic | | Basic | |
| Ex. | Resin (10 g) | generator (B) | (g) | resin (F) | (g) | compound (D) | (g) |
| 1 | A′-1 | B-7 | 1.0 | F-1 | 0.5 | DBA | 0.015 |
| 2 | A′-2 | B-8 | 0.9 | F-1 | 0.5 | DBA | 0.015 |
| | Compound (E) | Surfactant | | (mass | Exposure | CDU | Circularity |
| | (0.5 g) | (0.03 g) | Solvent | ratio) | condition | (nm) | (nm) |
| Ex. | | | | | | | |
| 1 | | W-1 | S-1 | (100) | (1) | 5.5 | 2.4 |
| 2 | | W-1 | S-1 | (100) | (1) | 5.3 | 2.1 |
| 3 | | W-3 | S-1 | (100) | (1) | 5.3 | 2.1 |
| 4 | E-1 | W-4 | S-1 | (100) | (1) | 5.1 | 1.9 |
| 5 | | W-3 | S-1 | (100) | (1) | 5.1 | 2.0 |
| 6 | | W-4 | S-1/S-4 | (95/5) | (1) | 5.6 | 2.4 |
| 7 | E-1 | W-3 | S-1/S-3 | (95/5) | (1) | 5.1 | 2.0 |
| 8 | | W-4 | S-1/S-5 | (80/20) | (1) | 5.0 | 2.0 |
| 9 | | W-1 | S-1/S-5 | (80/20) | (1) | 5.2 | 2.1 |
| 10 | E-1 | W-3 | S-1 | (100) | (1) | 5.1 | 2.0 |
| 11 | E-1 | W-4 | S-1/S-5 | (90/10) | (1) | 5.1 | 2.1 |
| 12 | | W-3 | S-1/S-4 | (95/5) | (1) | 5.3 | 2.2 |
| 13 | | W-3 | S-1/S-4 | (95/5) | (1) | 5.4 | 2.3 |
| 14 | E-1 | W-4 | S-1 | (100) | (1) | 5.0 | 2.0 |
| 15 | E-1 | W-3 | S-1/S-5 | (80/20) | (1) | 5.2 | 2.2 |
| 16 | | W-1 | S-1 | (100) | (1) | 5.3 | 2.2 |
| 17 | | W-4 | S-1/S-5 | (90/10) | (1) | 5.1 | 2.0 |
| 18 | E-1 | W-3 | S-1/S-2 | (95/5) | (1) | 5.8 | 3.0 |
| 19 | E-1 | W-4 | S-1/S-6 | (95/5) | (1) | 6.1 | 3.2 |
| 20 | | W-2 | S-1/S-7 | (95/5) | (1) | 6.2 | 3.7 |
| 21 | | W-3 | S-1 | (100) | (1) | 6.5 | 3.9 |
| 22 | | W-2 | S-1 | (100) | (1) | 6.9 | 4.1 |
| 23 | | W-3 | S-1 | (100) | (1) | 7.1 | 4.3 |
| 24 | | W-2 | S-1 | (100) | (1) | 7.3 | 4.5 |
| Comp. | | | | | | | |
| Ex. | | | | | | | |
| 1 | E-1 | W-2 | S-1 | (100) | (1) | 8.2 | 4.9 |
| 2 | | W-3 | S-2 | (100) | (1) | 8.9 | 5.0 |

TABLE 3

| | Resin (A) | Acid | | Basic | | Compound (E) |
|---|---|---|---|---|---|---|
| Ex. | (10 g) | generator (B) | (g) | compound (D) | (g) | (0.5 g) |
| 25 | A-1 | B-1/B-3 | 1.0/0.1 | DIA | 0.010 | |
| 26 | A-2 | B-3 | 1.0 | TEA | 0.010 | E-1 |
| 27 | A-7 | B-2/B-5 | 1.1/0.2 | PEA/TPA | 0.01/0.01 | |
| 28 | A-8 | B-1/B-7 | 1.0/0.1 | PBI | 0.015 | |
| 29 | A-9/A-2(5 g/5 g) | B-3 | 1.0 | TPA | 0.010 | |
| 30 | A-10 | B-2/B-1 | 1.0/0.2 | TPA | 0.015 | E-1 |
| 31 | A-17 | B-3 | 0.6 | DBA | 0.010 | |
| 32 | A-17 | B-5 | 0.8 | PBI | 0.010 | E-1 |
| 33 | A-18 | B-7 | 0.9 | PEA | 0.010 | E-1 |
| 34 | A-19 | B-7 | 1.1 | TPA | 0.010 | |
| 35 | A-20 | B-8/B-5 | 0.7/0.2 | TPA | 0.010 | E-1 |
| 36 | A-21 | B-8 | 0.5 | PEA | 0.010 | |
| 37 | A-22 | B-5 | 0.9 | TPA | 0.010 | |
| 38 | A-23 | B-5 | 1.2 | TPA | 0.010 | |
| Comp. | Comparative | Acid | | Basic | | Compound (E) |
| Ex. | Resin (10 g) | generator (B) | (g) | compound (D) | (g) | (0.5 g) |
| 3 | A-1 | B-7 | 2.1 | DBA | 0.015 | E-1 |
| 4 | A-2 | B-8 | 1.2 | DBA | 0.010 | |
| | Surfactant | | (mass | Exposure | CDU | Circularity |
| | (0.03 g) | Solvent | ratio) | condition | (nm) | (nm) |
| Ex. | | | | | | |
| 25 | W-1 | S-1 | (100) | (2) | 7.4 | 3.5 |
| 26 | W-1 | S-1/S-4 | (95/5) | (2) | 7.3 | 3.4 |
| 27 | W-1 | S-1/S-5 | (80/20) | (1) | 7.1 | 3.2 |
| 28 | W-3 | S-1 | (100) | (1) | 7.0 | 3.0 |
| 29 | W-4 | S-1/S-5 | (90/10) | (1) | 7.2 | 3.1 |
| 30 | W-3 | S-1/S-4 | (95/5) | (1) | 6.9 | 3.1 |
| 31 | W-2 | S-1/S-3 | (95/5) | (2) | 7.1 | 3.0 |
| 32 | W-3 | S-1/S-5 | (80/20) | (2) | 7.4 | 3.7 |
| 33 | W-4 | S-1 | (100) | (2) | 7.5 | 3.9 |
| 34 | W-2 | S-1 | (100) | (2) | 7.7 | 4.1 |
| 35 | W-3 | S-1/S-2 | (95/5) | (2) | 8.0 | 4.3 |
| 36 | W-4 | S-1/S-6 | (95/5) | (2) | 8.5 | 4.6 |
| 37 | W-3 | S-1 | (100) | (2) | 8.6 | 4.8 |
| 38 | W-2 | S-1 | (100) | (2) | 9.2 | 5.1 |
| Comp. | | | | | | |
| Ex. | | | | | | |
| 3 | W-2 | S-1 | (100) | (2) | 10.0 | 7.0 |
| 4 | W-3 | S-1 | (100) | (2) | 11.3 | 7.5 |

The abbreviations in the tables are as follows.

[Acid Generator (B)]

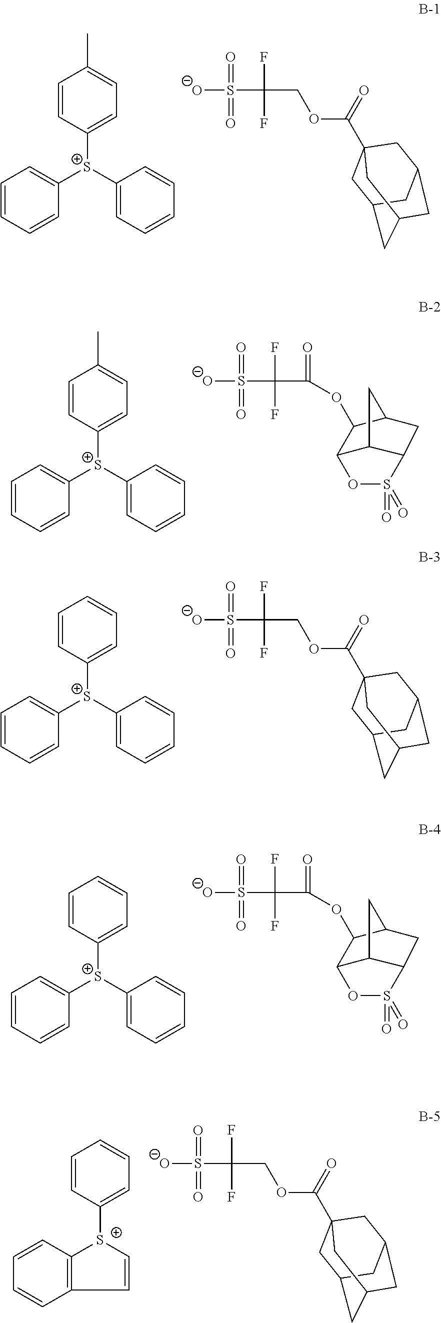

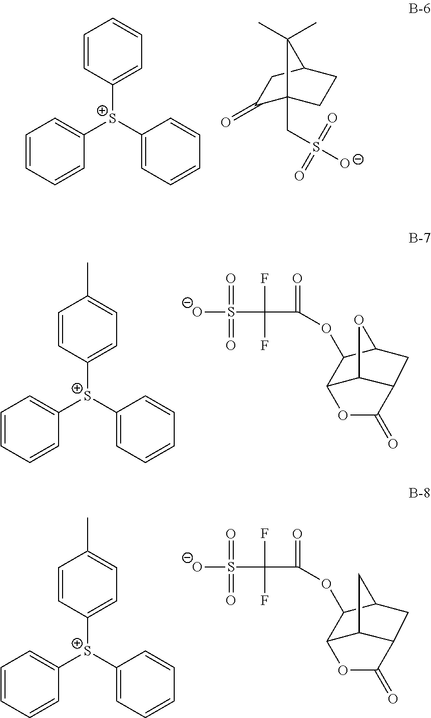 [SMILES: c1ccc([S+](c2ccccc2)c2ccccc2)cc1 ; CC1(C)C2CCC1(CS(=O)(=O)[O-])C(=O)C2 ; Cc1ccc([S+](c2ccccc2)c2ccccc2)cc1 ; O=C1OC2C(OC(=O)C(F)(F)S(=O)(=O)[O-])C3CC1C2O3 ; Cc1ccc([S+](c2ccccc2)c2ccccc2)cc1 ; O=C1OC2C3CC(CC13)C2OC(=O)C(F)(F)S(=O)(=O)[O-]]

[Hydrophobic Resin (F)]

In the following structures, the composition ratio of each repeating unit is a molar ratio.

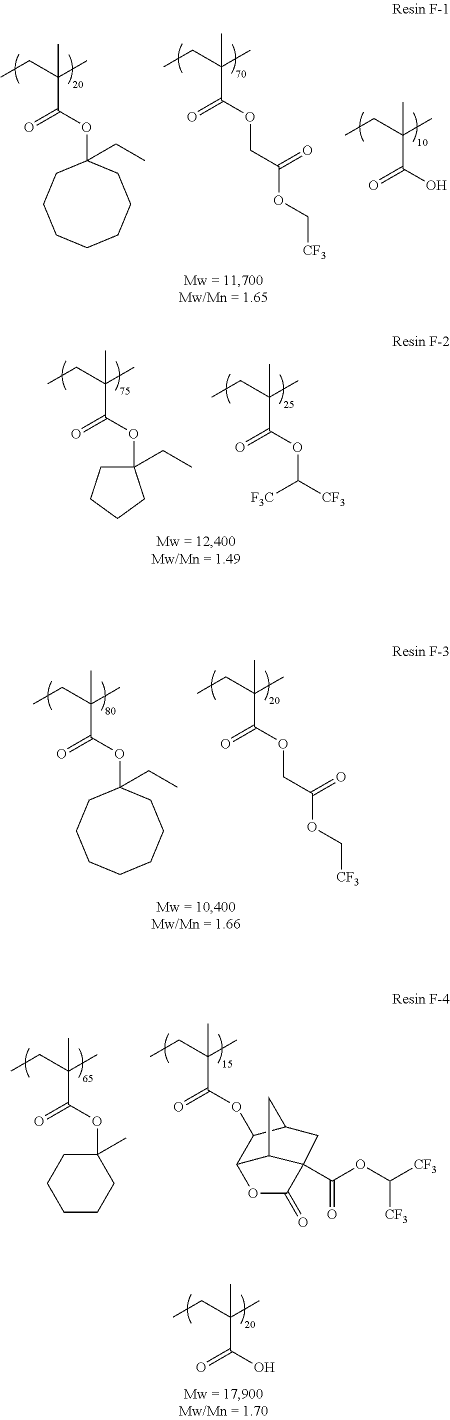

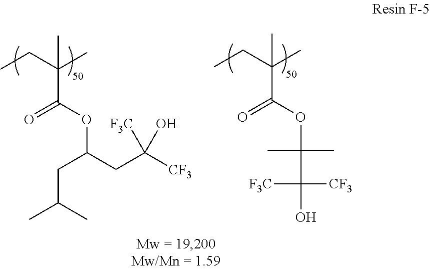

[Basic Compound (D)]

DIA: 2,6-diisopropylaniline

TEA: triethanolamine

DBA: N,N-dibutylaniline

PBI: 2-phenylbenzimidazole

PEA: N-phenyldiethanolamine

TPA: tri-n-pentylamine

[Compound (E)]

E-1: Salicylic acid

[Surfactant]

W-1: Megafac F176 (manufactured by DIC Corporation) (fluorine-based)

W-2: Megafac R08 (manufactured by DIC Corporation) (fluorine- and silicon-based)

W-3: PF6320 (manufactured by OMNOVA Solutions Inc.) (fluorine-based)

W-4: Troysol S-366 (manufactured by Troy Chemical Corporation)

[Solvent]

S-1: propylene glycol monomethyl ether acetate (PGMEA; 1-methoxy-2-acetoxypropane)

S-2: 2-heptanone

S-3: cyclohexanone

S-4: γ-butyrolactone

S-5: propylene glycol monomethyl ether (PGME; 1-methoxy-2-propanol)

S-6: ethyl lactate

S-7: propylene carbonate

As is clear from Tables 2 and 3 shown above, in Comparative Examples 1 to 4 which used a resin having a molar average of C log P values of the respective monomers corresponding to the respective repeating units except for the repeating unit (a0) of less than 2.0, it is understood that the evaluation values of the local CDU and the circularity are high, indicating that the local CDU and the circularity are inferior.

Meanwhile, in Examples 1 to 38 which used a resin having a molar average of C log P values of the respective monomers corresponding to the respective repeating units except for the repeating unit (a0) of 2.0 or more, it is understood that the evaluation values of the local CDU and the circularity are low, indicating that the local CDU and the circularity are excellent.

The pattern forming method of the present invention may be suitably used in a lithography process in manufacturing various semiconductor devices or electronic devices such as a recording medium.

What is claimed is:

1. A pattern forming method comprising:
(a) forming a film from an actinic ray-sensitive or radiation-sensitive resin composition containing:
(A) a resin containing a repeating unit (a0) having a —SO₂— group and a repeating unit (a1) having a group which decomposes by the action of an acid to generate a polar group, in which a molar average of C log P values of the respective monomers corresponding to repeating units except for the repeating unit (a0) is 2.0 or more; and
(B) a compound capable of generating an acid upon irradiation with an actinic ray or radiation;
(b) exposing the film; and
(c) developing the film exposed by using a developer including an organic solvent to form a negative pattern.

2. The pattern forming method according to claim 1,
wherein a content of the repeating unit (a1) having a group which decomposes by the action of an acid to generate a polar group is 50 mol % or more based on total repeating units of the resin (A).

3. The pattern forming method according to claim 1,
wherein a content of the repeating unit (a0) having a —SO₂— group is 1 to 20 mol % based on total repeating units of the resin (A).

4. The pattern forming method according to claim 1,
wherein the resin (A) further contains a repeating unit (a2) having a non-acid-decomposable aliphatic hydrocarbon group.

5. The pattern forming method according to claim 4,
wherein the repeating unit (a2) is a repeating unit having no alcoholic hydroxyl group.

6. The pattern forming method according to claim 1,
wherein the compound (B) capable of generating an acid upon irradiation with an actinic ray or radiation is represented by Formula (b3′) or (b5′): 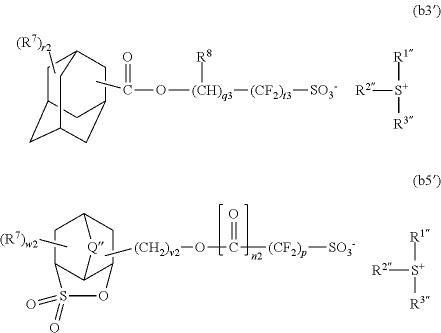
wherein, in Formulas (b3′) and (b5′), each of R^{1″} to R^{3″} independently represents an aryl group, and any two of R^{1″} to R^{3″} may be bonded to each other to form a ring together with a sulfur atom in the formulas (b3′) and (b5′),
in Formula (b3′), q3 is an integer of 1 to 12, r2 is an integer of 0 to 3, t3 is an integer of 1 to 3, R⁷ is a substituent, and R⁸ is a hydrogen atom or an alkyl group, and
in Formula (b5′), p is an integer of 1 to 3, R⁷ is a substituent, Q″ is an alkylene group which may contain an oxygen atom or a sulfur atom, an oxygen atom, or a sulfur atom, n2 is 0 or 1, v2 is an integer of 0 to 3, and w2 is an integer of 0 to 3.

7. The pattern forming method according to claim 1,
wherein the repeating unit (a0) is a repeating unit having a —SO₂—O— group.

8. The pattern forming method according to claim 7,
wherein the repeating unit (a0) is a repeating unit having a cyclic group containing a —SO₂—O— group.

9. An actinic ray-sensitive or radiation-sensitive resin composition, comprising:
(A) a resin containing a repeating unit (a0) having a —SO₂— group and a repeating unit (a1) having a group which decomposes by the action of an acid to generate a polar group, in which a molar average of C log P values of the respective monomers corresponding to repeating units except for the repeating unit (a0) is 2.0 or more; and
(B) a compound capable of generating an acid upon irradiation with an actinic ray or radiation.

10. The actinic ray-sensitive or radiation-sensitive resin composition according to claim 9,
wherein a content of the repeating unit (a1) having a group which decomposes by the action of an acid to generate a polar group is 50 mol % or more based on total repeating units of the resin (A).

11. The actinic ray-sensitive or radiation-sensitive resin composition according to claim 9,
wherein a content of the repeating unit (a0) having a —SO₂— group is 1 to 20 mol % based on total repeating units of the resin (A).

12. The actinic ray-sensitive or radiation-sensitive resin composition according to claim 9,
wherein the resin (A) further contains a repeating unit (a2) having a non-acid-decomposable aliphatic hydrocarbon group.

13. The actinic ray-sensitive or radiation-sensitive resin composition according to claim 12,
wherein the repeating unit (a2) is a repeating unit having no alcoholic hydroxyl group.

14. The actinic ray-sensitive or radiation-sensitive resin composition according to claim 9,
wherein the compound (B) capable of generating an acid upon irradiation with an actinic ray or radiation is represented by Formula (b3′) or (b5′): 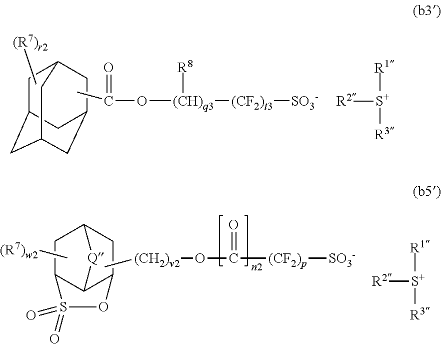
wherein, in Formulas (b3′) and (b5′), each of R^{1″} to R^{3″} independently represents an aryl group, and any two of R^{1″} to R^{3″} may be bonded to each other to form a ring together with a sulfur atom in the formulas (b3′) and (b5′),
in Formula (b3′), q3 is an integer of 1 to 12, r2 is an integer of 0 to 3, t3 is an integer of 1 to 3, R⁷ is a substituent, and R⁸ is a hydrogen atom or an alkyl group, and
in Formula (b5′), p is an integer of 1 to 3, R⁷ is a substituent, Q″ is an alkylene group which may contain an oxygen atom or a sulfur atom, an oxygen atom, or a sulfur atom, n2 is 0 or 1, v2 is an integer of 0 to 3, and w2 is an integer of 0 to 3.

15. The actinic ray-sensitive or radiation-sensitive resin composition according to claim 9,
wherein the repeating unit (a0) is a repeating unit having a —SO₂—O— group.

16. The actinic ray-sensitive or radiation-sensitive resin composition according to claim 15,
wherein the repeating unit (a0) is a repeating unit having a cyclic group containing a —SO₂—O— group.

17. A resist film formed from the actinic ray-sensitive or radiation-sensitive resin composition according to claim 9.

18. A method of manufacturing an electronic device comprising the pattern forming method according to claim 1.
